(19) United States
(12) Patent Application Publication
(10) Pub. No.: US 2026/0068524 A1
(43) Pub. Date: Mar. 5, 2026

(54) LIGHT-EMITTING DEVICE AND ELECTRONIC DEVICE

(71) Applicant: Samsung Display Co., LTD., Yongin-si (KR)

(72) Inventors: Hak Choong LEE, Yongin-si (KR); Seung Cheol KIM, Yongin-si (KR); Yi Seul KIM, Yongin-si (KR); Ka Young LEE, Yongin-si (KR); Jong Won LEE, Yongin-si (KR); Chang Min LEE, Yongin-si (KR)

(73) Assignee: Samsung Display Co., LTD., Yongin-si (KR)

(21) Appl. No.: 19/195,983

(22) Filed: May 1, 2025

(30) Foreign Application Priority Data
Sep. 4, 2024 (KR) 10-2024-0120035

(51) Int. Cl. H10K 85/60; H10K 50/17; H10K 102/00

(52) U.S. Cl. CPC H10K 85/6572; H10K 85/615; H10K 50/171; H10K 2102/351

(57) ABSTRACT

Embodiments provide a light-emitting device and an electronic device including the light-emitting device. The light-emitting device includes a first electrode, a hole transfer region on the first electrode, an emission layer on the hole transfer region, an electron transfer region on the emission layer, and a second electrode on the electron transfer region. The second electron transfer region includes an electron transport layer, a first electron injection layer on the electron transport layer, and a second electron injection layer on the first electron injection layer. The first electron injection layer includes an organic host and a first metal dopant, and the second electron injection layer includes an inorganic metal compound having a band gap greater than or equal to about 2.8 eV.

### CROSS-REFERENCE TO RELATED APPLICATION(S)

This application claims priority to and benefits of Korean Patent Application No. 10-2024-0120035 under 35 U.S.C. § 119, filed on Sep. 4, 2024, in the Korean Intellectual Property Office, the entire contents of which are incorporated herein by reference.

### BACKGROUND

### 1. Technical Field

The disclosure of this patent application relates to a light-emitting device and an electronic device including the light-emitting device.

### 2. Description of the Related Art

An organic light emitting device is a self-emissive device that has improved viewing angle and contrast properties, along with a high response speed and high luminance.

The organic light emitting device may include an emission layer disposed between a first electrode and a second electrode. A hole transferred from the first electrode and an electron transferred from the second electrode may recombine in the emission layer to generate an exciton. Light is emitted as the exciton transitions from an excited state to a ground state.

Materials for a light-emitting device that are capable of implementing a low operating voltage, high luminous efficiency, and an extended life-span are being developed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An embodiment provides a light-emitting device having improved light-emitting property and reliability.

An embodiment provides an electronic device including the light-emitting device.

According to an embodiment, a light-emitting device may include a first electrode, a hole transfer region on the first electrode, an emission layer on the hole transfer region, an electron transfer region on the emission layer, and a second electrode on the electron transfer region, wherein the electron transfer region may include an electron transport layer, a first electron injection layer on the electron transport layer, and a second electron injection layer on the first electron injection layer. The first electron injection layer may include an organic host and a first metal dopant, and the second electron injection layer may include an inorganic metal compound having a band gap greater than or equal to about 2.8 eV.

In an embodiment, the organic host may include a compound represented by Chemical Formula A or Chemical Formula B.

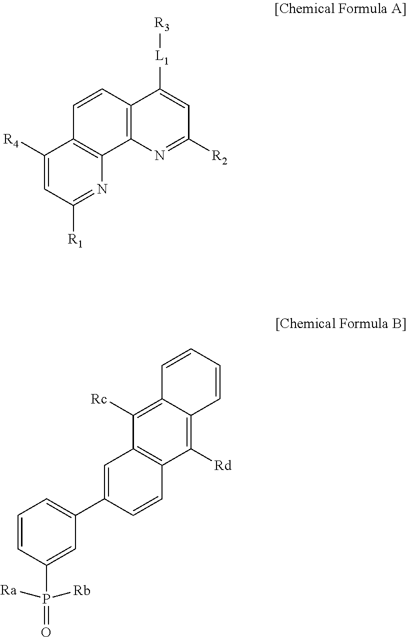

In Chemical Formula A, L₁ may be a direct linkage, or a substituted or unsubstituted phenylene group; R₁ and R₂ may each independently be a hydrogen atom, a substituted or unsubstituted methyl group, or a substituted or unsubstituted phenyl group; and R₃ and R₄ may each independently be a hydrogen atom, a substituted or unsubstituted C₆-C₃₀ aryl group, or a substituted or unsubstituted C₂-C₃₀ heteroaryl group. In Chemical Formula B, Rₐ and R_{b} may each independently be a substituted or unsubstituted C₁-C₂₀ alkyl group, or a substituted or unsubstituted C₆-C₃₀ aryl group; and R_{c} and R_{d} may each independently be a substituted or unsubstituted C₆-C₃₀ aryl group.

In an embodiment, Chemical Formula A may be represented by Chemical Formula A-1 or Chemical Formula A-2.

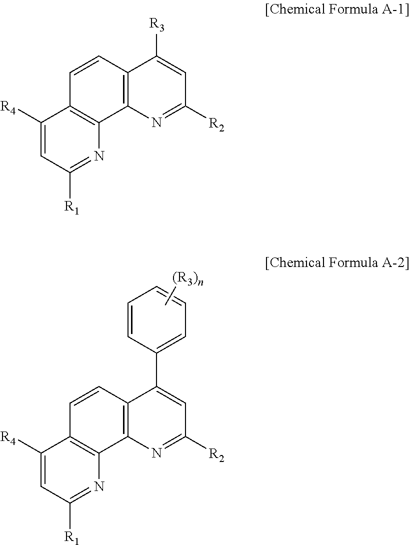

In Chemical Formulae A-1 and A-2, R₁ and R₂ may each independently be a hydrogen atom, a substituted or unsubstituted methyl group, or a substituted or unsubstituted phenyl group; and R₃ and R₄ may each independently be a hydrogen atom, a substituted or unsubstituted C₆-C₃₀ aryl group, or a substituted or unsubstituted C₂-C₃₀ heteroaryl group. In Chemical Formula A-2, n may be an integer from 0 to 5.

In an embodiment, in Chemical Formula A-2, R₃ may be a group represented by one of S1 to S25:

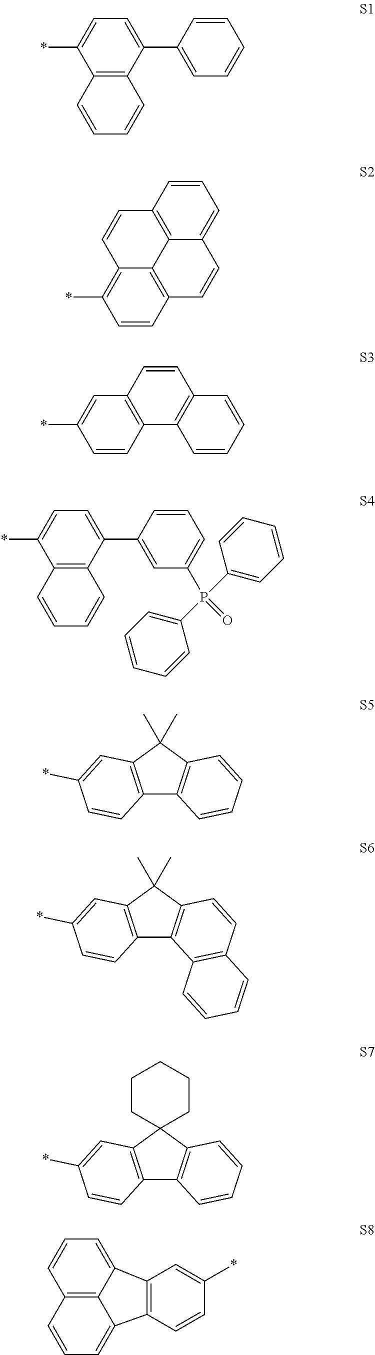

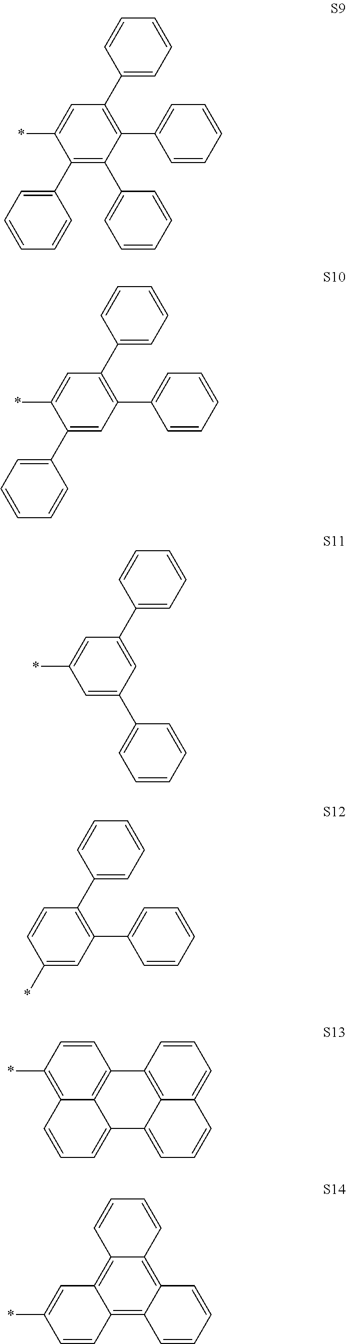

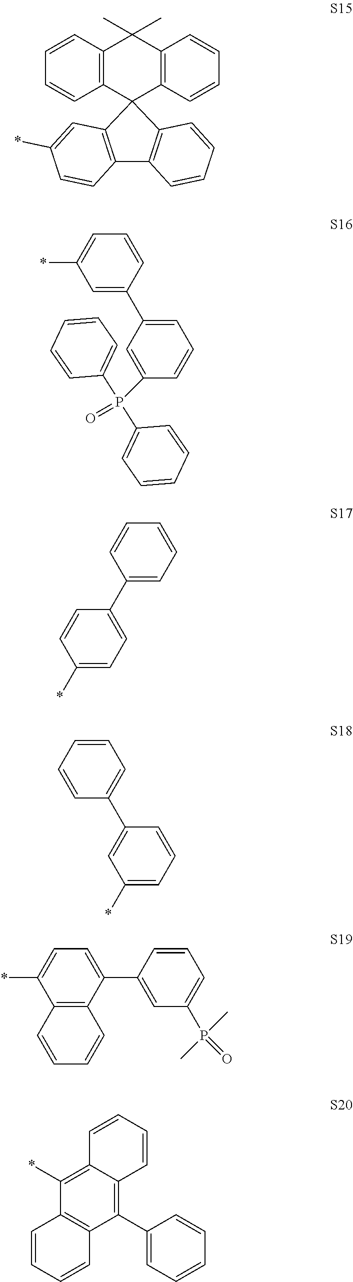

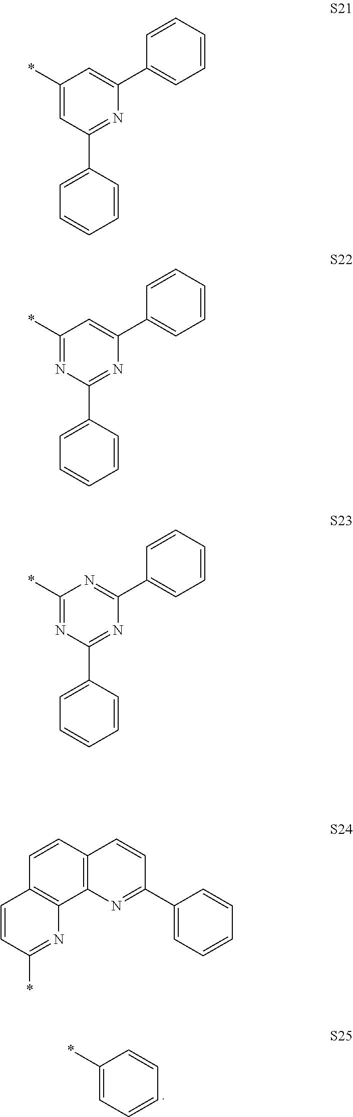 [SMILES: *c1cc(-c2ccccc2)nc(-c2ccccc2)c1 ; *c1cc(-c2ccccc2)nc(-c2ccccc2)n1 ; *c1nc(-c2ccccc2)nc(-c2ccccc2)n1 ; *c1ccc2ccc3ccc(-c4ccccc4)nc3c2n1 ; *c1ccccc1]

In an embodiment, the organic host may include at least one compound selected from Compound Group 1:

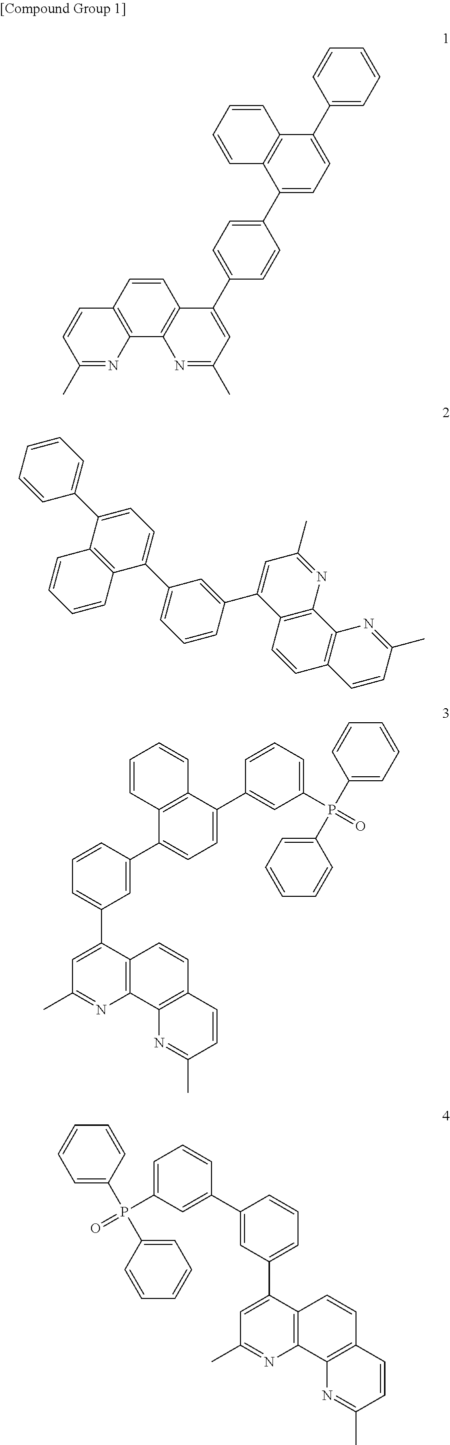

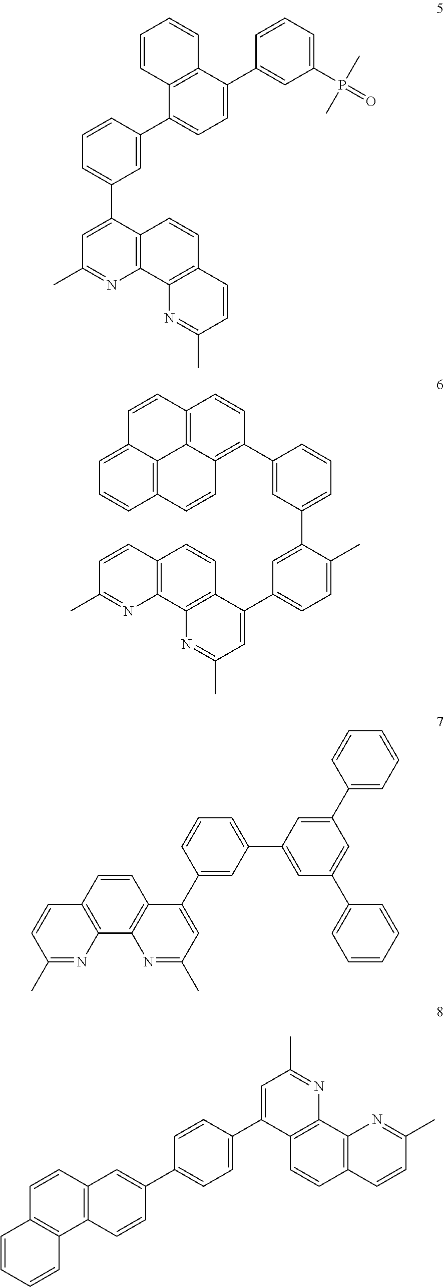

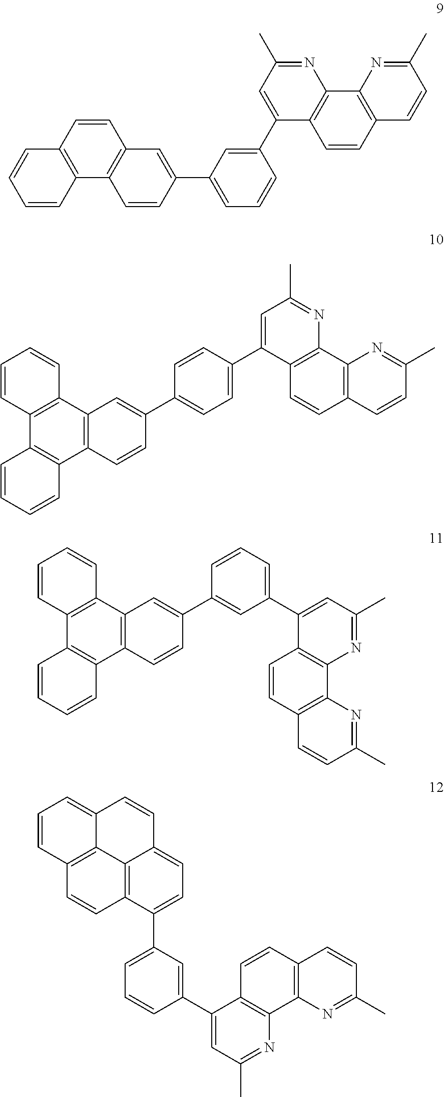 [SMILES: Cc1ccc2ccc3c(-c4cccc(-c5ccc6c(ccc7ccccc76)c5)c4)cc(C)nc3c2n1 ; Cc1ccc2ccc3c(-c4ccc(-c5ccc6c7ccccc7c7ccccc7c6c5)cc4)cc(C)nc3c2n1 ; Cc1ccc2ccc3c(-c4cccc(-c5ccc6c7ccccc7c7ccccc7c6c5)c4)cc(C)nc3c2n1 ; Cc1ccc2ccc3c(-c4cccc(-c5ccc6ccc7cccc8ccc5c6c78)c4)cc(C)nc3c2n1]

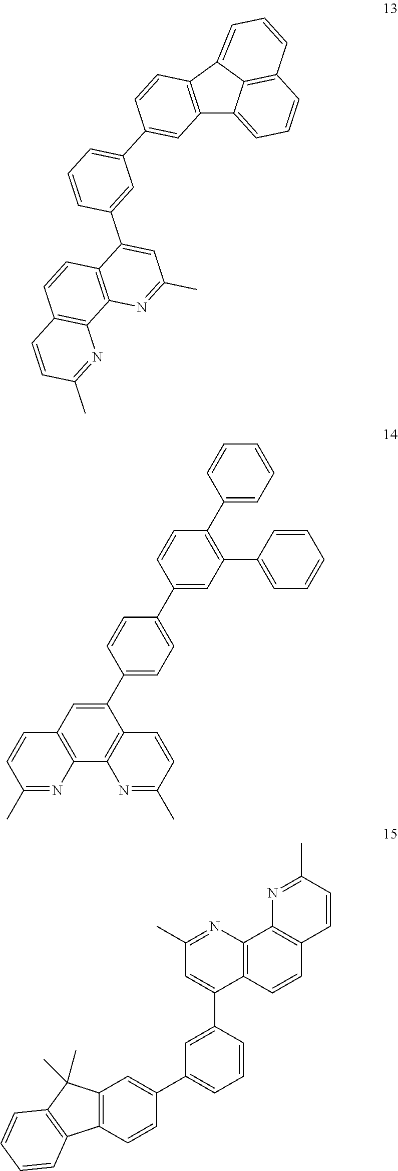 [SMILES: Cc1ccc2ccc3c(-c4cccc(-c5ccc6c(c5)-c5cccc7cccc-6c57)c4)cc(C)nc3c2n1 ; Cc1ccc2cc(-c3ccc(-c4ccc(-c5ccccc5)c(-c5ccccc5)c4)cc3)c3ccc(C)nc3c2n1 ; Cc1ccc2ccc3c(-c4cccc(-c5ccc6c(c5)C(C)(C)c5ccccc5-6)c4)cc(C)nc3c2n1]

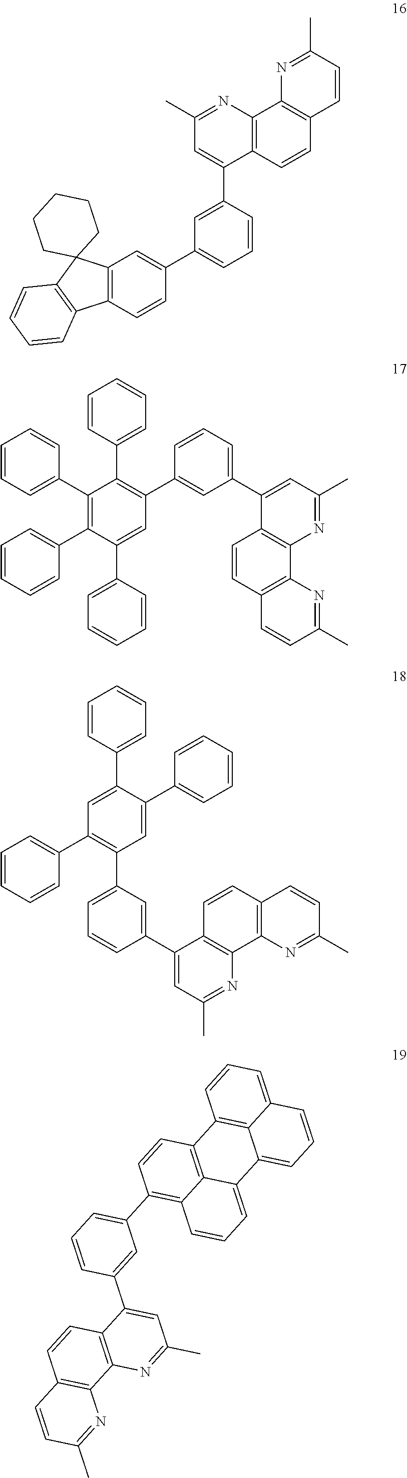

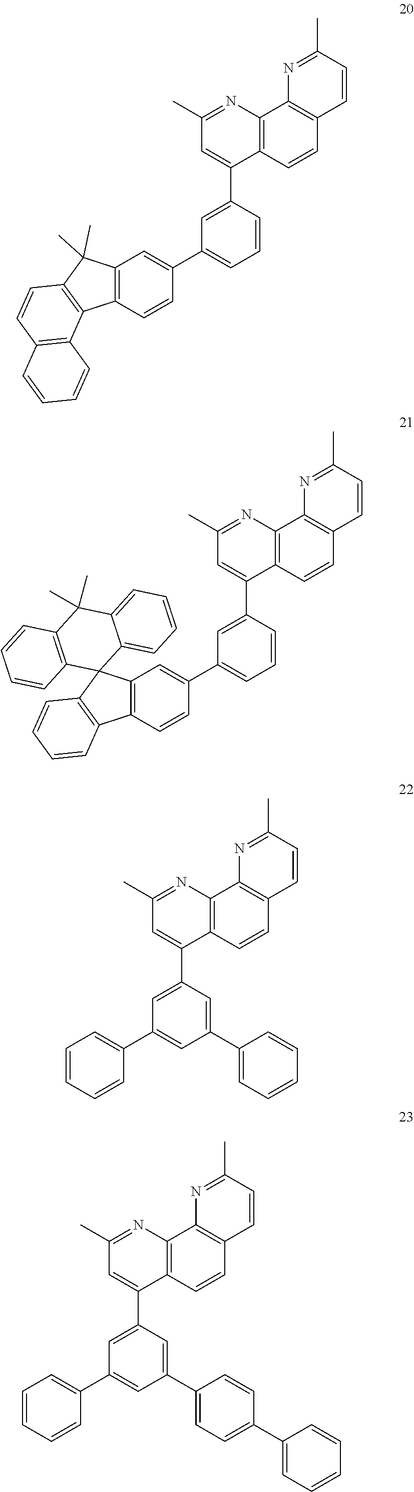 [SMILES: Cc1ccc2ccc3c(-c4cccc(-c5ccc6c(c5)C(C)(C)c5ccc7ccccc7c5-6)c4)cc(C)nc3c2n1 ; Cc1ccc2ccc3c(-c4cccc(-c5ccc6c(c5)C5(c7ccccc7-6)c6ccccc6C(C)(C)c6ccccc65)c4)cc(C)nc3c2n1 ; Cc1ccc2ccc3c(-c4cc(-c5ccccc5)cc(-c5ccccc5)c4)cc(C)nc3c2n1 ; Cc1ccc2ccc3c(-c4cc(-c5ccccc5)cc(-c5ccc(-c6ccccc6)cc5)c4)cc(C)nc3c2n1]

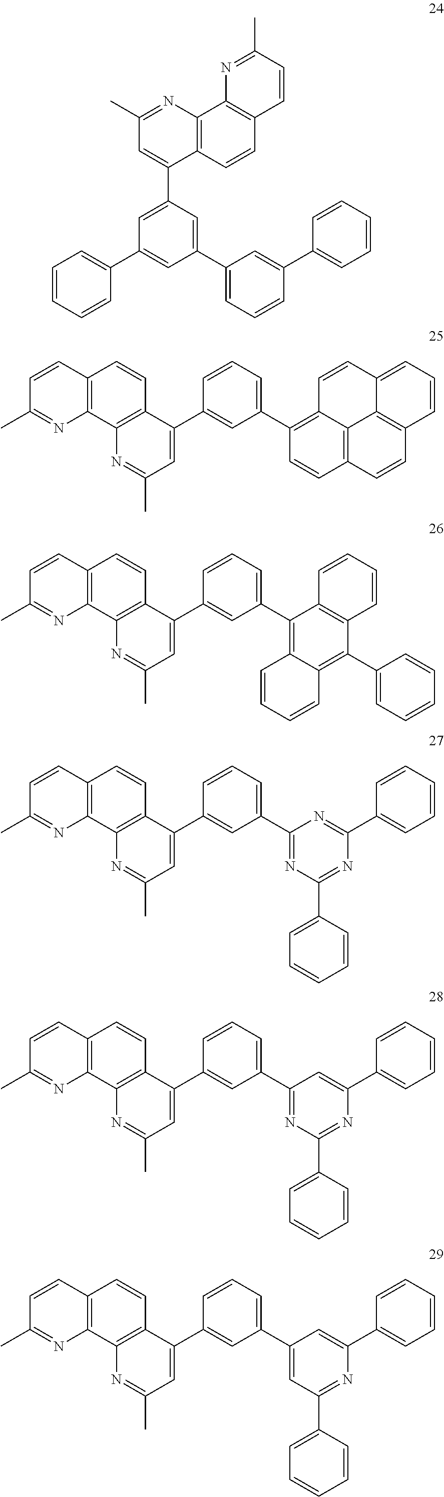

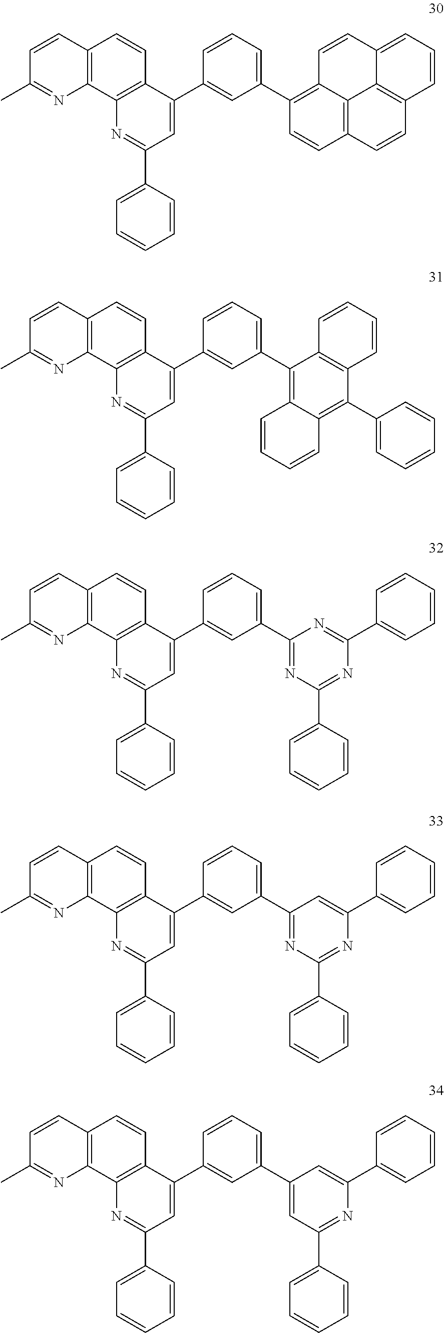 [SMILES: Cc1ccc2ccc3c(-c4cccc(-c5ccc6ccc7cccc8ccc5c6c78)c4)cc(-c4ccccc4)nc3c2n1 ; Cc1ccc2ccc3c(-c4cccc(-c5c6ccccc6c(-c6ccccc6)c6ccccc56)c4)cc(-c4ccccc4)nc3c2n1 ; Cc1ccc2ccc3c(-c4cccc(-c5nc(-c6ccccc6)nc(-c6ccccc6)n5)c4)cc(-c4ccccc4)nc3c2n1 ; Cc1ccc2ccc3c(-c4cccc(-c5cc(-c6ccccc6)nc(-c6ccccc6)n5)c4)cc(-c4ccccc4)nc3c2n1 ; Cc1ccc2ccc3c(-c4cccc(-c5cc(-c6ccccc6)nc(-c6ccccc6)c5)c4)cc(-c4ccccc4)nc3c2n1]

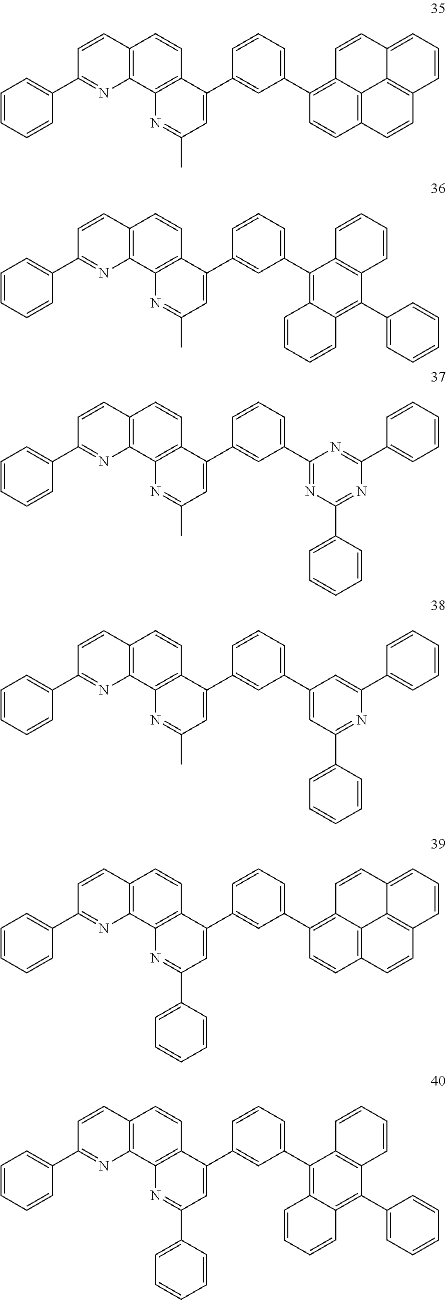

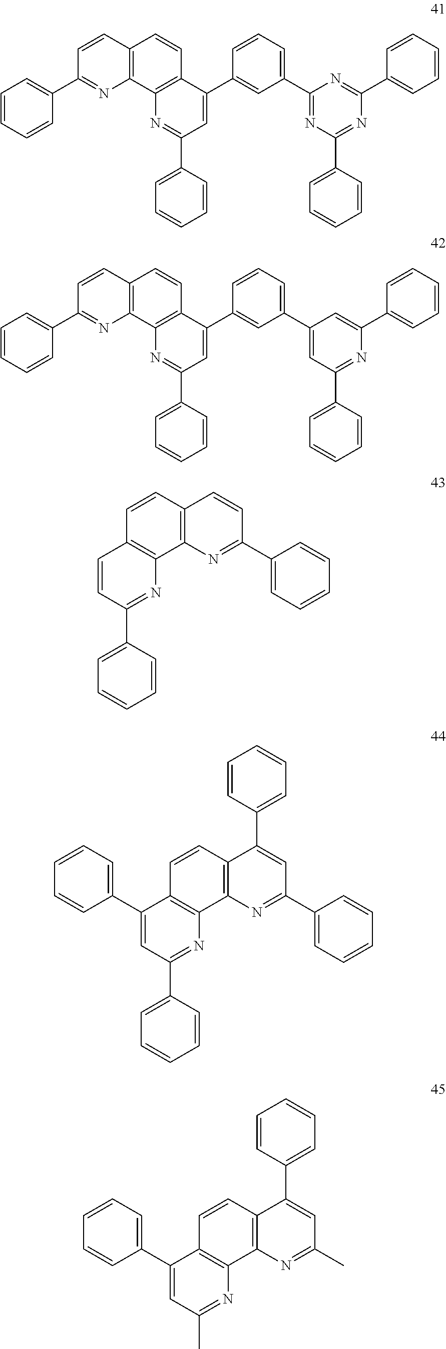

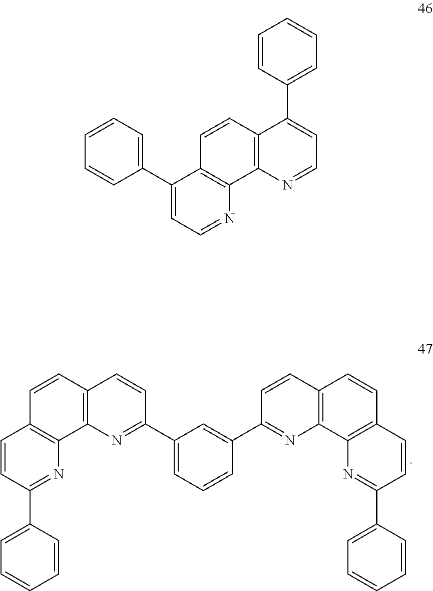 [SMILES: c1ccc(-c2ccnc3c2ccc2c(-c4ccccc4)ccnc23)cc1 ; c1ccc(-c2ccc3ccc4ccc(-c5cccc(-c6ccc7ccc8ccc(-c9ccccc9)nc8c7n6)c5)nc4c3n2)cc1]

In an embodiment. Chemical Formula B may be represented by Chemical Formula B-1 or Chemical Formula B-2:

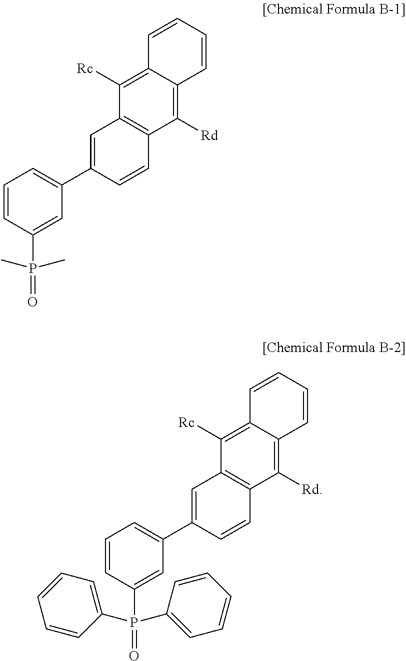

In Chemical Formulae B-1 and B-2, R_{c} and Rₐ may each independently be a substituted or unsubstituted C₆-C₃₀ aryl group.

In an embodiment, in Chemical Formula B, R_{c} and Rₐ may each independently be a group represented by one of T1 to T4:

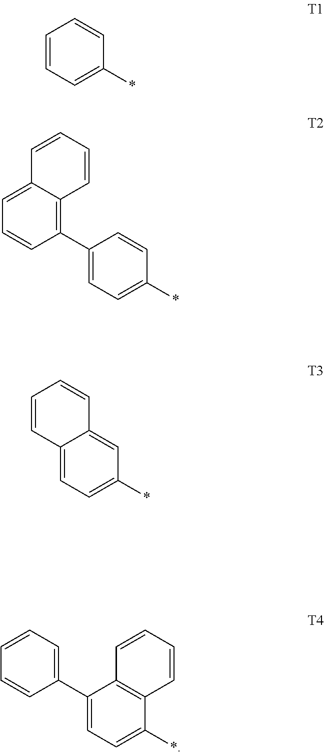

In an embodiment, the organic host may include at least one compound selected from Compound Group 2:

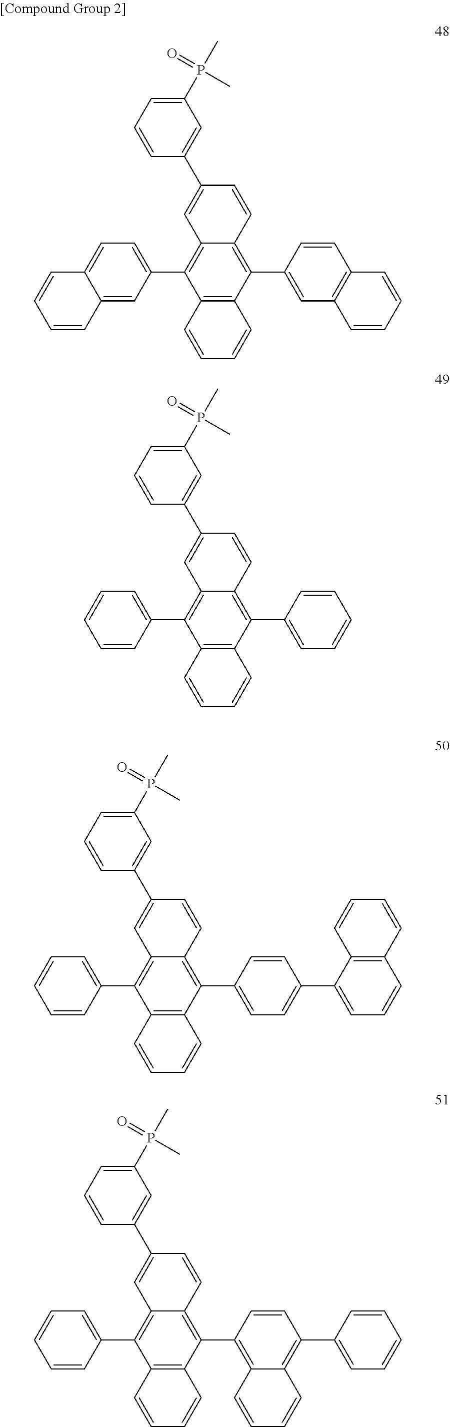

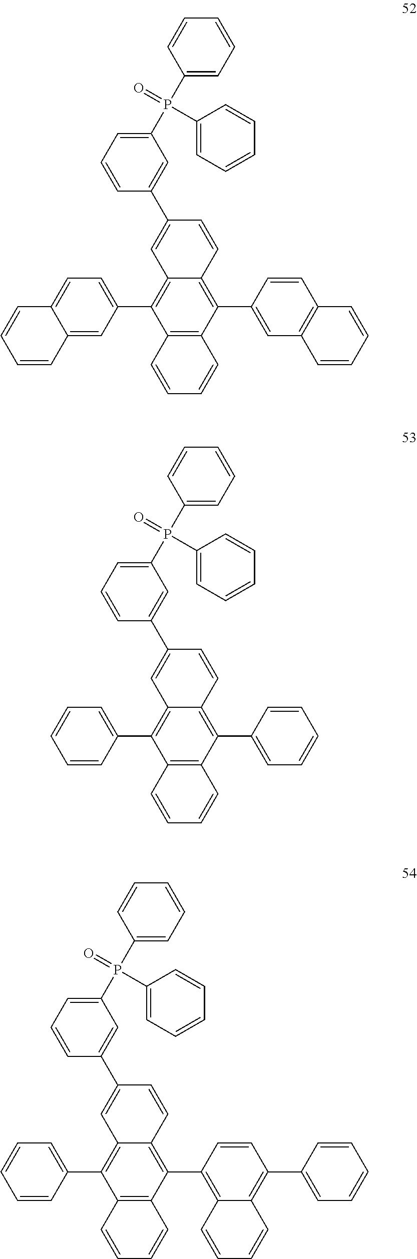 [SMILES: O=P(c1ccccc1)(c1ccccc1)c1cccc(-c2ccc3c(-c4ccc5ccccc5c4)c4ccccc4c(-c4ccc5ccccc5c4)c3c2)c1 ; O=P(c1ccccc1)(c1ccccc1)c1cccc(-c2ccc3c(-c4ccccc4)c4ccccc4c(-c4ccccc4)c3c2)c1 ; O=P(c1ccccc1)(c1ccccc1)c1cccc(-c2ccc3c(-c4ccc(-c5ccccc5)c5ccccc45)c4ccccc4c(-c4ccccc4)c3c2)c1]

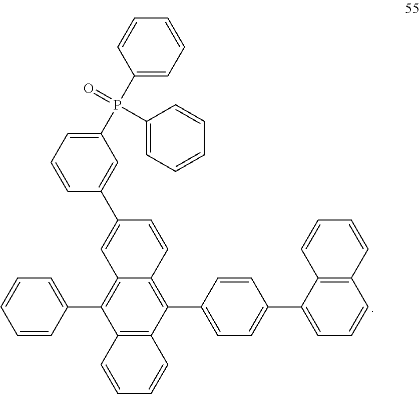 [SMILES: O=P(c1ccccc1)(c1ccccc1)c1cccc(-c2ccc3c(-c4ccc(-c5cccc6ccccc56)cc4)c4ccccc4c(-c4ccccc4)c3c2)c1]

In an embodiment, the inorganic metal compound may include at least one of a metal halide, a metal oxide, a metal nitride, and a metal sulfide.

In an embodiment, the inorganic metal compound may include at least one of LiI, NaI, KI, RbI, CsI, LiF, NaF, KF, RbF, CsF, Li₂O, Na₂O, Rb₂O, Cs₂O, ZnO, MoO₃, MgO, CaO, Al₂O₃, SiO₂, Li₃N, Na₃N, K₃N, Rb₃N, Si₃N₄, and ZnS.

In an embodiment, the second electron injection layer may directly contact the second electrode.

In an embodiment, an absolute value of a difference between a lowest unoccupied molecular orbital (LUMO) energy level of the organic host doped with the first metal dopant and an energy level of a work function of the second electrode may be less than or equal to about 0.2 eV.

In an embodiment, a binding energy of the organic host and the first metal dopant may be greater than or equal to about 2.0 eV.

In an embodiment, the first metal dopant may include at least one of Ag, Bi, Mg, Li, Yb, Cu, La, Pr, Nd, Pm, Sm, Eu, Gd, Tb, Dy, Ho, Er, Tm, and Lu.

In an embodiment, a volume ratio of the first metal dopant to a total volume of the organic host and the first metal dopant in the first electron injection layer may be in a range of about 0.1 vol % to about 10 vol %.

In an embodiment, the second electron injection layer may further include a second metal dopant.

In an embodiment, the second metal dopant may include at least one of Ag, Bi, Mg, Li, Yb, Cu, La, Pr, Nd, Pm, Sm, Eu, Gd, Tb, Dy, Ho, Er, Tm, and Lu.

In an embodiment, a thickness of the first electron injection layer may be in a range of about 10 Å to about 50 Å; and a thickness of the second electron injection layer may be in a range of about 1 Å to about 20 Å.

According to an embodiment, an electronic device may include the light-emitting device.

In an embodiment, the electronic device may be a display device, a billboard, a signboard, a light source, a lighting device, a laptop computer, a desktop computer, a mobile phone, an electronic book, an electronic dictionary, an electronic notebook, a medical diagnostic device, a biometric sensor, a display for an automobile, a display for an aircraft, a display for a ship, or a display for a train.

A light-emitting device according to embodiments may have improved light-emitting efficiency and may have a reduced driving voltage.

Even when the light-emitting device according to embodiments is driven for a long period in a high-temperature environment, pixel shrinkage may be suppressed. Accordingly, driving stability of the light-emitting device may be improved.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIGS. 1 to 5 are each a schematic cross-sectional view of a light-emitting device according to an embodiment.

FIG. 6 is a schematic cross-sectional view of a display device according to an embodiment.

FIG. 7 is a schematic cross-sectional view of a display device according to an embodiment.

FIG. 8 is a schematic cross-sectional view of a stack construction of a light-emitting structure in a display device according to an embodiment.

FIG. 9 is a schematic cross-sectional view of a display device according to an embodiment.

FIG. 10 is a schematic cross-sectional view of a display device according to an embodiment.

FIG. 11 is an exploded perspective view of an electronic device according to an embodiment.

FIG. 12 is a schematic diagram of a vehicle in which an electronic device is disposed according to an embodiment.

FIG. 13 is a graph of transmittances of a light-emitting device according to Example 1, Comparative Example 1, and Comparative Example 2.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (for example, the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

According to embodiments of the disclosure, a light-emitting device may include a first electron injection layer that includes an organic-inorganic hybrid material and a second electron injection layer that includes an inorganic material. According to embodiments of the disclosure, an electronic device may include the light-emitting device.

### Definitions of Terms

In the specification, “the number of carbon atoms a to b”, “Ca-Cb”, and “Ca to Cb” may describe a group in which the number of carbon atoms is in a range from a to b.

In the specification, the term “substituted or unsubstituted” may describe a group that is substituted or unsubstituted with at least one substituent selected from the group consisting of, e.g., a deuterium atom, a halogen atom, a cyano group, a nitro group, an amino group, a silyl group, an oxy group, a thio group, a sulfinyl group, a sulfonyl group, a carbonyl group, an ester group, a boron group, a phosphine oxide group, a phosphine sulfide group, an alkyl group (e.g., a C₁-C₆₀, C₁-C₁₀ alkyl group), an alkenyl group (e.g., a C₂-C₆₀, C₂-C₁₀ alkenyl group), an alkynyl group (e.g., a C₂-C₆₀, C₂-C₁₀ alkynyl group), an alkoxy group (e.g., a C₁-C₆₀, C₁-C₁₀ alkoxy group), a hydrocarbon ring group, an aryl group (e.g., a C₆-C₆₀ aryl group), and a heterocyclic group (e.g., a C₁-C₆₀ heterocyclic group). For example, the term “substituted alkyl group” may describe a group in which at least one hydrogen atom in an alkyl group is substituted with the at least one substituent as described above, such that the substituent is bonded to a carbon atom of the alkyl group.

In embodiments, the substituent may include a combination of substituents selected from the groups described above. For example, at least one hydrogen atom in the alkyl group, the aryl group, etc., included as a substituent may itself be substituted with a deuterium atom, a halogen atom, a cyano group, a nitro group, an amino group, a silyl group, an oxy group, a thio group, a sulfinyl group, a sulfonyl group, a carbonyl group, an ester group, a boron group, a phosphine oxide group, a phosphine sulfide group, an alkyl group, an alkenyl group, an alkynyl group, a hydrocarbon ring group, an aryl group, a heterocyclic group, or any combination thereof.

In the substituents described above, a multivalent substituent such as an amino group, a phosphine sulfide group, a phosphine oxide group, a sulfinyl group, a sulfonyl group, an oxy group, a carbonyl group, an ester group, etc., may each independently be substituted with a C₁-C₁₀ alkyl group, a C₁-C₁₀ alkenyl group, a C₁-C₁₀ alkynyl group, or a C₆-C₁₀ aryl group.

In the specification, for the term “substituted or unsubstituted Cₐ-C_{b} Y group”, the range of a to b refers to the number of carbon atoms in an unsubstituted Y group, and may not include the number of carbon atoms of a substituent.

In the specification, an alkyl group may be a monovalent hydrocarbon group in which one hydrogen atom is removed from a linear or branched hydrocarbon group. Examples of an alkyl group may include a methyl group, an ethyl group, a propyl group, a sec-butyl group, a tert-butyl group, an iso-butyl group, a pentyl group, a neopentyl group, a 2-ethyl butyl group, a 3,3-dimethyl butyl group, a hexyl group, a heptyl group, an octyl group, etc.

In the specification, an alkylene group may be a divalent hydrocarbon group in which two hydrogen atoms are removed from a linear or branched hydrocarbon group.

In the specification, an alkenyl group may have a same skeleton as that of an alkyl group, and may be a monovalent hydrocarbon group that includes at least one carbon-carbon double bond. In the specification, an alkenylene group may be a divalent hydrocarbon group in which one hydrogen atom is further removed from an alkenyl group.

In the specification, an alkynyl group may have a same skeleton as that of an alkyl group, and may be a monovalent hydrocarbon group that includes at least one carbon-carbon triple bond. In the specification, an alkynylene group may be a divalent hydrocarbon group in which one hydrogen atom is further removed from an alkynyl group.

In the specification, an aryl group may be a monovalent hydrocarbon group in which one hydrogen atom is removed from a hydrocarbon group having an aromatic structure. The definition of an aryl group may also encompass a group in which multiple aromatic rings are directly connected, such as a biphenyl group. Examples of an aryl group may include, e.g., a phenyl group, a naphthyl group, an anthracenyl group, a phenanthrenyl group, a pyrenyl group, a fluorenyl group, a tetracenyl group, a biphenyl group, a terphenyl group, a quaterphenyl group, a chrysenyl group, etc.

In the specification, a group in which two or more aryl rings are condensed to each other or linked to each other by an alicyclic hydrocarbon ring, such as a fluorenyl group, can be encompassed in the definition of an aryl group.

For example, a biphenyl group may be interpreted as an aryl group or it may be interpreted as a phenyl group that is substituted with a phenyl group.

In the specification, an arylene group may be a divalent hydrocarbon group in which two hydrogen atoms are removed from an aryl group.

In the specification, a heteroaryl group may be a monovalent group having an aromatic structure that includes at least one heteroatom such as B, O, P, S, and Si as a ring-forming atom. In the specification, a heteroarylene group may be a divalent group having an aromatic structure that includes at least one heteroatom such as B, O, P, S, and Si as a ring-forming atom. When a heteroaryl group or a heteroarylene group includes two or more heteroatoms, the two or more heteroatoms may be the same as or different from each other.

In the specification, a group in which two or more aryl rings are condensed or linked to a non-aromatic heterocyclic ring, such as a carbazole group, can also be encompassed in the definition of a heteroaryl group.

In the specification, the term “cyclic group” may encompass a monocyclic group or a polycyclic group, and may also encompass an alicyclic ring or an aromatic ring.

In the specification, the term “polycyclic group” may be a group in which two or more rings are connected to each other or condensed to each other through one or more atoms. For example, a polycyclic structure may include a bicyclic structure through a bridge carbon, a spiro structure, a fused structure, etc.

In the specification, the term “condensed group” or “condensed ring structure” may each refer to a group in which two or more adjacent rings share two or more atoms among the above-described polycyclic structures. Examples of a condensed ring structure may include naphthalene, anthracene, phenanthrene, fluorene, pyrene, benzopyrene, pentacene, polyacene, helicene, etc.

In the specification, the term “carbocyclic group (e.g., C₃-C₆₀ carbocyclic group)” may be a cyclic group in which carbon atoms are the only ring-forming atoms. In the specification, a heterocyclic group (e.g., a C₁-C₆₀ heterocyclic group) may be a cyclic group that includes at least one heteroatom as a ring-forming atom, in addition to carbon atoms.

In the specification, a carbocyclic group and a heterocyclic group may each independently be a monocyclic group that consists of one ring or a polycyclic group in which two or more rings are condensed with each other.

### [Light-Emitting Device]

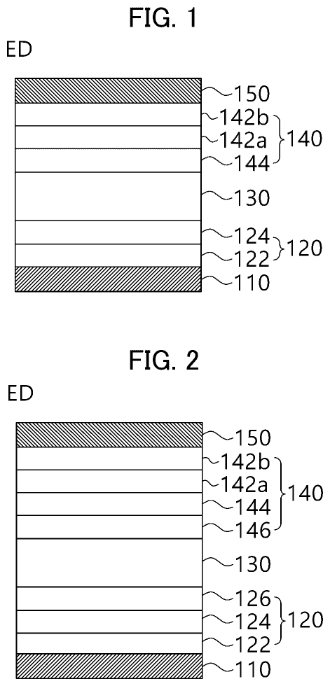

FIGS. 1 to 5 are each a schematic cross-sectional view of a light-emitting device according to embodiments.

Referring to FIG. 1, a light-emitting device ED may include a first electrode 110 and a second electrode 150, and a hole transfer region 120, an emission layer 130, and an electron transfer region 140 disposed between the first electrode 110 and the second electrode 150.

The first electrode 110 may be an anode or a cathode. In embodiments, the first electrode 110 may be an anode, and may serve as a pixel electrode. In case that the first electrode 110 is an anode, the first electrode 110 may include a conductive material with a high work function that promotes hole injection.

In an embodiment, the first electrode 110 may be a transmissive electrode. The first electrode 110 may include a transparent conductive oxide such as indium tin oxide (ITO), indium zinc oxide (IZO), zinc oxide (ZnO), indium tin oxide (ITZO), etc.

In an embodiment, the first electrode 110 may be a translucent electrode or a reflective electrode. The first electrode 110 may include at least one of Ag, Mg, Cu, Al, Pt, Pd, Au, Ni, Nd, Ir, Cr, Li, Ca, LiF, Mo, Ti, W, In, Sn, Zn, and an alloy containing at least two thereof. For example, the first electrode 110 may include Li, Ca, LiF/Ca (a stacked structure of LiF and Ca), LiF/Al (a stacked structure of LiF and Al), a mixture of Ag and Mg, etc.

The first electrode 110 may have a single-layered structure or a multi-layered structure. For example, the first electrode 110 may have a triple-layered structure of ITO/Ag/ITO.

A thickness of the first electrode 110 may be in a range of about 700 Å to about 10,000 Å. For example, the thickness of the first electrode 110 may be in a range of about 1,000 Å to about 3,000 Å.

The second electrode 150 may be a cathode or an anode. In embodiments, the second electrode 150 may serve as an electron injection electrode or as a cathode. The second electrode 150 may include a material having a low work function, such as a metal, an alloy, an electrically conductive compound, etc.

For example, the second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, etc. The second electrode 150 may include one of the aforementioned materials, or any combination thereof.

The second electrode 150 may be a transmissive electrode, a translucent electrode, or a reflective electrode. The second electrode 150 may have a single-layered structure or a multi-layered structure.

The emission layer 130 may further include a host material. For example, the emission layer 130 may further include a host material of the related art, such as an anthracene derivative, a pyrene derivative, a fluoranthene derivative, a chrysene derivative, a dihydrobenzanthracene derivative, a triphenylene derivative, etc.

In embodiments, the emission layer 130 may include, e.g., a host material represented by Chemical Formula FH. For example, the compound represented by Chemical Formula FH may be used as a fluorescent host material.

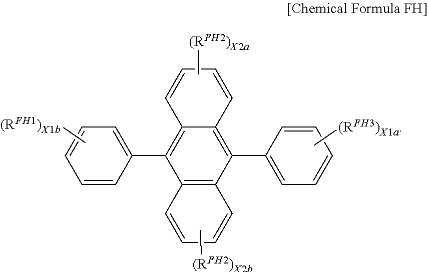

In Chemical Formula FH, R^{FH1} to R^{FH4} may each independently be a hydrogen atom, a deuterium atom, a halogen atom, a substituted or unsubstituted silyl group, a substituted or unsubstituted thio group, a substituted or unsubstituted oxy group, a substituted or unsubstituted C₁-C₁₀ alkyl group, a substituted or unsubstituted C₂-C₁₀ alkenyl group, a substituted or unsubstituted C₆-C₃₀ aryl group, a substituted or unsubstituted C₆-C₃₀ heteroaryl group, or a cyclic group formed through any combination thereof. In an embodiment, in Chemical Formula FH, at least one of R^{FH1} to R^{FH4} may form a condensed ring with a bonded benzene ring.

In Chemical Formula FH, x1a and x1b may each independently be an integer from 0 to 5, and x2a and x2b may each independently be an integer from 0 to 4. When x1a, x1b, x2a, and x2b are each 2 or more, two or more of each of R^{FH1} to R^{FH4} may be the same as each other or different from each other.

In embodiments, the emission layer 130 may include, e.g., a host material represented by Chemical Formula PH. For example, the compound represented by Chemical Formula PH may be used as a phosphorescent host material.

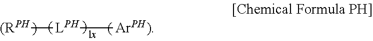

In Chemical Formula PH, RPH may be a substituted or unsubstituted carbazole group; L^{PH} may be a direct linkage, a substituted or unsubstituted C₆-C₃₀ arylene group, or a substituted or unsubstituted C₂-C₃₀ heteroarylene group; and Ar^{PH} may be a substituted or unsubstituted C₆-C₃₀ aryl group, or a substituted or unsubstituted C₂-C₃₀ heteroaryl group.

As described above in the definitions of terms, the term “C₆-C₃₀ aryl group” may encompass a group in which multiple aryl rings are condensed or bonded through a cyclic group (e.g., an alicyclic hydrocarbon ring). For example, a C₆-C₃₀ aryl group may be a fluorenyl group.

As described above in the definitions of terms, the term “C₂-C₃₀ heteroaryl group” may encompass a group in which multiple aryl rings are condensed or bonded through a heterocyclic ring. For example, a C₂-C₃₀ heteroaryl group may be a carbazole group, a dibenzofuran group, a dibenzothiophene group, etc. In an embodiment, a C₂-C₃₀ heteroaryl group may be a group in which multiple aryl rings are condensed or bonded to each other through the same or different heterocyclic rings.

In an embodiment, a substituent included in Ar^{PH} may be a silyl group represented by —Si(R^{sa})(R^{sb})(R^{sc}); and R^{sa}, R^{sb}, and R^{sc} may each independently be hydrogen, a halogen, a hydroxyl group, a C₁-C₆₀ alkyl group, a C₁-C₆₀ alkoxy group, a C₆-C₆₀ aryl group, or a C₂-C₃₀ heteroaryl group, wherein at least one of R^{sa}, R^{sb}, and R^{sc} may each independently be a C₆-C₆₀ aryl group or a C₂-C₃₀ heteroaryl group. For example, R^{sa}, R^{sb} and R^{sc} may each independently be a C₆-C₆₀ aryl group or a C₂-C₃₀ heteroaryl group.

In Chemical Formula PH, 1x may be an integer from 0 to 10. When 1x is 2 or more, two or more of L^{PH} may be the same as each other or different from each other.

The emission layer 130 may include, e.g., BCPDS (bis(4-(9H-carbazol-9-yl)phenyl)diphenylsilane), POPCPA ((4-(1-(4-(diphenylamino)phenyl)cyclohexyl)phenyl)diphenyl-phosphine oxide), DPEPO (bis[2-(diphenylphosphino)phenyl]ether oxide), mCBP (3,3′-di(9H-carbazol-9-yl)-1,1′-biphenyl), CBP (4,4′-bis(N-carbazolyl)-1,1′-biphenyl), mCP (1,3-bis(carbazol-9-yl)benzene), PPF (2,8-bis(diphenylphosphoryl)dibenzo[b,d]furan), TCTA (4,4′, 4″-tris(carbazol-9-yl)-triphenylamine), TPBi (1,3,5-tris(1-phenyl-1H-benzo[d]imidazole-2-yl)benzene), Alq3 (tris(8-hydroxyquinolino)aluminum), ADN (9,10-di(naphthalene-2-yl) anthracene), TBADN (2-tert-butyl-9,10-di(naphth-2-yl) anthracene), DSA (distyrylarylene), CDBP (4,4′-bis(9-carbazolyl)-2,2′-dimethyl-biphenyl), MADN (2-methyl-9,10-bis(naphthalen-2-yl) anthracene), CP1 (hexaphenyl cyclotriphosphazene), UGH2 (1,4-bis(triphenylsilyl)benzene), DPSiO3 (hexaphenylcyclotrisiloxane), DPSiO4 (octaphenylcyclotetrasiloxane), etc., as a host material.

In an embodiment, in the emission layer 130, the host may include one of the materials as described above, or any combination thereof.

The emission layer 130 may further include a dopant.

In embodiments, the emission layer 130 may include a dopant represented by Chemical Formula FD. For example, the compound represented by Chemical Formula FD may be used as a fluorescent dopant.

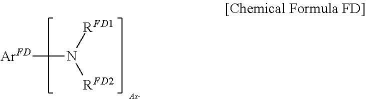

In Chemical Formula FD, Ar^{FD}, R^{FD1}, and R^{FD2} may each independently be a substituted or unsubstituted C₃-C₆₀ carbocyclic group, or a substituted or unsubstituted C₁-C₆₀ heterocyclic group. In Chemical Formula FD, Ax may be an integer from 1 to 6.

In embodiments, Ar^{FD} may include a condensed ring structure in which three or more aryl rings or benzene rings are condensed together (e.g., an anthracene group, a chrysene group, a pyrene group, etc.).

In embodiments, the emission layer 130 may include a phosphorescent dopant. The phosphorescent dopant may include an organometallic compound that includes a central metal and at least one ligand bonded to the central metal via a coordinate bond. The central metal may include, e.g., a transition metal, and the ligand may include, e.g., a monodentate ligand, a bidentate ligand, a tridentate ligand, a tetradentate ligand, a pentadentate ligand, a hexadentate ligand, or any combination thereof.

In embodiments, the phosphorescent dopant may include, e.g., a compound represented by Chemical Formula PD.

M(Ld¹)_{dx1}(L_{d}²)_{dx2} [Chemical Formula PD]

In Chemical Formula PD, M may be a transition metal atom, e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), ruthenium (Ru), copper (Cu), or thulium (Tm).

In Chemical Formula PD, L_{d}¹ may be a ligand represented by Chemical Formula LD1:

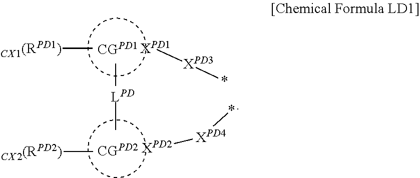

In Chemical Formula LD1, X^{PD1} and X^{PD2} may each independently be Cor N.

In an embodiment, one of X^{PD1} and X^{PD2} may be C and the other of X^{PD1} and X^{PD2} may be N. In an embodiment, X^{PD1} and X^{PD2} may each be N.

In Chemical Formula LD1, CG^{PD1} and CG^{PD2} may each independently be a substituted or unsubstituted C₃-C₆₀ carbocyclic group, or a substituted or unsubstituted C₁-C₆₀ heterocyclic group.

For example, CG^{PD1} and CG^{PD2} may each independently be a pyrrole group, a pyrazole group, an imidazole group, a triazole group, an oxazole group, an isoxazole group, a thiazole group, an isothiazole group, an oxadiazole group or a thiadiazole group, a benzene group, a pyridine group, a pyrimidine group, a naphthalene group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, a naphthobenzosilole group, a dinaphthofuran group, a dinaphthothiophene group, a dibenzocarbazole group, a dibenzofluorene group, a dinaphthosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenzosilole group, an azadinapthofuran group, an azadinapthothiophene group, an azadibenzocarbazole group, an azadibenzofluorene group, or an azadinapthosilole group.

In Chemical Formula LD1, L^{PD} may be a single bond, a substituted or unsubstituted methylene group, a substituted or unsubstituted ethylene group, *—O—*′, *—S—*′, *—C(═O)—*′, *—N(R^{PD3})—*′, *—C(R^{PD4})═*′, or *═C(R^{PD5})—*′.

In Chemical Formula LD1, X^{PD3} and X^{PD4} may each independently be a chemical bond, O, S, N(R^{PD6}), B(R^{PD7}), P(R^{PD8}), C(R^{PD8})(R^{PD9}), or Si(R^{PD10})(R^{PD11}). The chemical bond may be, e.g., a covalent bond or a coordinate bond.

In Chemical Formula LD1, R^{PD1} and R^{PD2} may each independently be hydrogen, deuterium, —F, —Cl, —Br, —I, —OH, —CN, —NO₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀) heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryl aryloxy group, a substituted or unsubstituted C₆-C₆₀ aryl arylthio group, a substituted or unsubstituted C₈-C₆₀ condensed polycyclic group, a substituted or unsubstituted silyl group, a substituted or unsubstituted amine group, a substituted or unsubstituted aniline group, —B(R^{PD12})(R^{PD13}), —C(═O)(R^{PD14}), —S(═O)₂(R^{PD15}), or —P(═O)(R^{PD16})(R^{PD17}). The silyl group may be represented by —Si(R^{sa})(R^{sb})(R^{sc}), as explained above.

In Chemical Formula LD1, R^{PD3} to R^{PD17} may each independently be hydrogen, deuterium, —F, —Cl, —Br, —I, —OH, —CN, —NO₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryl aryloxy group, a substituted or unsubstituted C₆-C₆₀ aryl arylthio group, or a substituted or unsubstituted C₈-C₆₀ condensed polycyclic group.

In Chemical Formula LD1, cx1 and cx2 may each independently be an integer from 0 to 10. When at least one of cx1 and cx2 is 2 or more, two or more of R^{PD1} or two or more of R^{PD2} may be the same as each other or different from each other.

In Chemical Formula LD1, the symbols —* and —*′ each represent a binding site where the ligand represented by Chemical Formula LD1 bonds to M.

In Chemical Formula PD, dx1 may be an integer from 1 to 3. When dx1 is 2 or 3, two or three of L_{d}¹ may be the same as each other or different from each other. Among two or three of Ld¹, CG^{PD1} and/or CG^{PD2} that are adjacent to each other may be connected to each other through a connecting group such as L^{PD1}, L^{PD2}, etc. The connecting group such as L^{PD1}, L^{PD2}, etc., may each independently be the same as defined in connection with L^{PD}.

In Chemical Formula PD, L_{d}² may be an organic ligand. L_{d}² may include, e.g., a halogen group, CO, NO, CS, picolinate, acetate, oxalate, a diketone group, an isonitrile group, isothiocyanato-N, thiosulphato-S, an alkyl phosphine, phenylphosphine, an aryl phosphine, phosphine oxide, phosphite, or any combination thereof.

In Chemical Formula PD, dx2 may be an integer from 1 to 4. When dx2 is 2 or more, two or more of L_{d}² may be the same as each other or different from each other.

In embodiments, the emission layer 130 may include a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene(DPAVB), N-(4-((E)-2-(6-((E)-4-(diphenylamino)styryl) naphthalen-2-yl)vinyl)phenyl)-N-phenylbenzenamine (NBDAVBi), etc.), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino) pyrene), etc.), etc., as a fluorescent dopant material.

The emission layer 130 may include a metal complex that includes iridium (Ir), platinum (Pt), osmium (Os), gold (Au), titanium (Ti), zirconium (Zr), hafnium (Hf), europium (Eu), terbium (Tb), or thulium (Tm) as a phosphorescent dopant, in addition to the materials described above. For example, FIrpic (iridium(III) bis(4,6-difluorophenylpyridinato-N,C2′)picolinate), FIr6 (bis(2,4-difluorophenylpyridinato)-tetrakis(1-pyrazolyl) borate iridium (III)), PtOEP (platinum octaethyl porphyrin), etc., may be used as a phosphorescent dopant.

In embodiments, the emission layer 130 may include a boron-containing dopant represented by Chemical Formula BD:

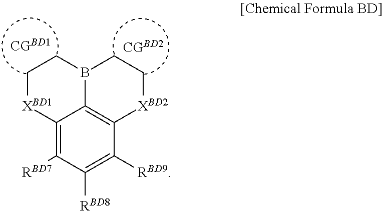

In Chemical Formula BD, X^{BD1} and X^{BD2} may each independently be N(R^{BD1}), P(R^{BD2}), C(R^{BD3})(R^{BD4}), Si(R^{BD5})(R^{BD6}), S, or O. In an embodiment, X^{BD1} and X^{BD2} may each independently be N(R^{BD1}). In Chemical Formula BD, R^{BD1} to R^{BD6} may each independently be hydrogen, deuterium, a substituted or unsubstituted C₁-C₂₀ alkyl group, a substituted or unsubstituted C₆-C₃₀ aryl group, or a substituted or unsubstituted C₂-C₃₀ heteroaryl group. In Chemical Formula BD, R^{BD7}, R^{BD8}, and R^{BD9} may each independently be hydrogen, deuterium, halogen, a cyano group, a substituted or unsubstituted amine group, a substituted or unsubstituted boryl group, a substituted or unsubstituted oxy group, a substituted or unsubstituted thio group, a substituted or unsubstituted C₁-C₂₀ alkyl group, a substituted or unsubstituted C₆-C₃₀ aryl group, or a substituted or unsubstituted C₂-C₃₀ heteroaryl group, or bonded to an adjacent group to form a ring.

In Chemical Formula BD, CG^{BD1} and CG^{BD2} represent a cyclic group, and CG^{BD1} and CG^{BD2} may each independently be a substituted or unsubstituted C₃-C₆₀ carbocyclic group, or a substituted or unsubstituted C₁-C₆₀ heterocyclic group. In embodiments, CG^{BD1} and CG^{BD2} may each independently be a substituted or unsubstituted C₆-C₃₀ aryl group, or a substituted or unsubstituted C₂-C₃₀ heteroaryl group.

In an embodiment, CG^{BD1} and CG^{BD2} may each independently be a substituted or unsubstituted benzene ring. For example, the boron-containing dopant may serve as a thermally activated delayed fluorescence (TADF) dopant.

In an embodiment, one of CG^{BD1} and CG^{BD2} may be a non-condensed aryl group or a non-condensed heteroaryl group, and the other of CG^{BD1} and CG^{BD2} may be a condensed polycyclic aryl group or a condensed polycyclic heteroaryl group. For example, the boron-containing dopant may serve as a fluorescent dopant.

In an embodiment, the emission layer 130 may include one of the dopant materials as described above, or any combination thereof.

In embodiments, the emission layer 130 may include two or more host materials. For example, the emission layer 130 may include a hole transporting host and an electron transporting host. For example, the emission layer 130 may include a hole transporting host, an electron transporting host, a photosensitive agent, and a dopant. In embodiments, the hole transporting host and the electron transporting host may form an exciplex, and energy may be transferred from the exciplex to the photosensitive agent and from the photosensitive agent to the dopant, thereby inducing light emission.

Non-limiting examples of the hole transporting host may include a compound represented by Chemical Formula HT as described below. Non-limiting examples of the electron transporting host may include a compound represented by Chemical Formula ET as described below.

In embodiments, the emission layer 130 may include quantum dots. A quantum dot may include a Group II-VI compound, a Group III-VI compound, a Group I-III-VI compound, a Group III-V group compound, a Group III-II-V group compound, a Group IV-VI compound, a Group IV element, a Group IV compound, or any combination thereof.

The quantum dot may include a core that includes a compound as described above, and a shell surrounding the core. The shell may include an inorganic oxide or a semiconductor compound. Examples of a semiconductor compound may include CdS, CdSe, CdTe, ZnS, ZnSe, ZnTe, ZnSe, ZnTeS, GaAs, GaP, GaSb, HgS, HgSe, HgTe, InAs, InP, InGaP, InSb, AlAs, AlP, AlSb, etc.

In embodiments, a color of light from a quantum dot may be adjusted according to a particle size of the quantum dot. The quantum dot may be a blue quantum dot, a red quantum dot, or a green quantum dot.

The hole transfer region 120 may be formed between the first electrode 110 and the emission layer 130. The hole transfer region 120 may have a single-layered structure or a multi-layered structure that includes different materials.

The hole transfer region 120 may include a hole injection layer, a hole transport layer, and/or an electron blocking layer, and may further include an auxiliary emission layer.

In embodiments, as illustrated in FIG. 1, the hole transfer region 120 may include a hole injection layer 122 and a hole transport layer 124, stacked from the first electrode 110.

In embodiments, as illustrated in FIG. 2, the hole transfer region 120 may include a hole injection layer 122, a hole transport layer 124, and an electron blocking layer 126, stacked from the first electrode 110. The electron blocking layer 126 may block electrons from the electron transfer region 140 to the hole transfer region 120. Accordingly, the generation of excitons in the emission layer 130 may be increased, and light-emission efficiency may be further increased.

In an embodiment, the hole transfer region 120 may include a compound represented by Chemical Formula HT:

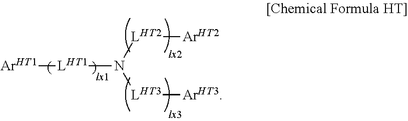

In Chemical Formula HT, L^{HT1}, L^{HT2}, and L^{HT3} may each independently be a direct linkage, a substituted or unsubstituted C₆-C₃₀ arylene group, or a substituted or unsubstituted C₂-C₃₀ heteroarylene group.

In Chemical Formula HT, 1×1 to 1×3 may each independently be an integer from 0 to 10. When 1×1, 1×2, or 1×3 is 2 or more, two or more of each of L^{HT3}, L^{HT1}, or L^{HT2}, respectively, may be directly connected by, e.g., carbon atoms (e.g., sp2 carbons) of each aryl ring, to form a substituted or unsubstituted C₆-C₃₀ arylene group, or a substituted or unsubstituted C₂-C₃₀ heteroarylene group.

In Chemical Formula HT, Ar^{HT1} and Ar^{HT2} may each independently be a substituted or unsubstituted C₆-C₃₀ aryl group, or a substituted or unsubstituted C₂-C₃₀ heteroaryl group. In Chemical Formula HT, Ar^{HT3} may be a substituted or unsubstituted C₆-C₃₀ aryl group.

In an embodiment, the compound represented by Chemical Formula HT may be a monoamine compound. In an embodiment, the compound represented by Chemical Formula HT may be a diamine compound in which at least one of Ar^{HT1} to Ar^{HT3} includes an amine group as a substituent.

In embodiments, the compound represented by Chemical Formula HT may be a carbazole-based compound in which at least one of Ar^{HT1} and Ar^{HT2} includes a substituted or unsubstituted carbazole group. In embodiments, the compound represented by Chemical Formula HT may be a fluorene-based compound in which at least one of Ar^{HT1} and Ar^{HT2} includes a substituted or unsubstituted fluorene group.

In embodiments, two adjacent groups among Ar^{HT1} to Ar^{HT3} may be condensed together to form a ring.

In an embodiment, the hole transfer region 120 may include, for example, m-MTDATA (4,4′, 4″-[tris(3-methylphenyl)phenylamino]triphenylamine), TDATA (4,4′4″-tris(N,N-diphenylamino)triphenylamine), 2-TNATA (4,4′, 4″-tris[N (2-naphthyl)-N-phenylamino]-triphenylamine), NPB(N,N′-di(naphthalene-1-yl)-N,N′-diphenyl-benzidine), TPD (N,N′-bis(3-methylphenyl)-N,N′-diphenyl-[1,l′-biphenyl]-4,4′-diamine), Spiro-TPD, Spiro-NPB, DNTPD (N1,N′″-([1,l′-biphenyl]-4,4′-diyl)bis(N1-phenyl-N4,N4-di-m-tolylbenzene-1,4-diamine), TAPC(4,4′-cyclohexylidene bis[N, N-bis(4-methylphenyl)benzenamine]), HMTPD (4,4′-bis[N,N′-(3-tolyl)amino]-3,3′-dimethylbiphenyl), TCTA (4,4′, 4″-tris(N-carbazolyl)triphenylamine), PANI/DBSA (polyaniline/dodecylbenzenesulfonic acid), PEDOT/PSS (poly(3,4-ethylenedioxythiophene)/poly(4-styrenesulfonate)), PANI/CSA (Polyaniline/Camphor sulfonicacid), PANI/PSS (polyaniline/poly(4-styrenesulfonate)), a phthalocyanine compound, a carbazole compound (N-phenylcarbazole, polyvinylcarbazole, etc.), a fluorene compound, etc. The hole transfer region 120 may include one of the hole transfer materials described above, or any combination thereof.

The hole transfer materials described above may be included in at least one of the hole injection layer 122, the hole transport layer 124, and the electron blocking layer 126.

The hole transfer region 120 may further include a charge generating material. The charge generating material may be a dopant material such as a p-dopant, so that conductivity of the hole transfer region 120 may be improved.

Examples of dopant materials may include: a halogenated metal compound such as LiF, NaCl, CsF, RbCl, RbI, CuI, and KI; a quinone derivative such as TCNQ (tetracyanoquinodimethane), F4-TCNQ (2,3,5,6-tetrafluoro-7,7,8,8-tetracyanoquinodimethane), etc.; a cyano-containing compound such as HATCN (dipyrazino[2,3-f: 2′, 3′-h]quinoxaline-2,3,6,7, 10, 11-hexacarbonitrile), NDP9 (4-[[2,3-bis[cyano-(4-cyano-2,3,5,6-tetrafluorophenyl)methylidene]cyclopropylidene]-cyanomethyl]-2,3,5,6-tetrafluorobenzonitrile), etc.; a tungsten (W) oxide; a molybdenum (Mo) oxide; etc. The hole transfer region 120 may include one of the dopant materials described above, or any combination thereof.

A thickness of the hole transfer region 120 may be in a range of about 100 Å to about 10,000 Å. For example, the thickness of the hole transfer region 120 may be in a range of about 100 Å to about 1,500 Å.

When the hole transfer region 120 includes a hole injection layer 122 or a hole transport layer 124, a thickness of the hole injection layer 122 may be in a range from about 100 Å to about 9,000 Å, and a thickness of the hole transport layer 124 may be in a range from 50 Å to about 2,000 Å. For example, the thickness of the hole injection layer 122 may be in a range of about 100 Å to about 3,000 Å. For example, the thickness of the hole injection layer 122 may be in a range of about 100 Å to about 1,000 Å. For example, the thickness of the hole transport layer 124 may be in a range of about 100 Å to about 1,500 Å. For example, the thickness of the hole transport layer 124 may be in a range of about 100 Å to about 1,000 Å. For example, the thickness of the hole transport layer 124 may be in a range of about 100 Å to about 600 Å.

Within any of the thickness ranges described above, hole transfer properties may be enhanced even at a low voltage operation, and a life-span of the device may be further improved.

Each layer of the hole transfer region 120 may be formed by a process such as a vacuum deposition, a spin coating, an inkjet printing, a laser printing, a casting, a laser thermal transfer, etc.

The electron transfer region 140 may be between the second electrode 150 and the emission layer 130. The electron transfer region 140 may have a single-layered structure or a multi-layered structure including different materials.

The electron transfer region 140 may include an electron injection layer, an electron transport layer, and/or a hole blocking layer, and may further include an auxiliary emission layer.

In embodiments, as illustrated in FIG. 1, the electron transfer region 140 may include a second electron injection layer 142b, a first electron injection layer 142a, and an electron transport layer 144, stacked from the second electrode 150 to the emission layer 130.

The first electron injection layer 142a may include an organic host and a first metal dopant. The first metal dopant may include a metal material, and the organic host may include an organic compound.

The first metal dopant may be doped into the organic host to reduce a lowest unoccupied molecular orbital (LUMO) energy level of the organic host. The first metal dopant may be doped into the organic host to reduce the LUMO energy level of the organic host, thereby reducing a difference of a work function energy level of the second electrode 150.

In an embodiment, the first metal dopant may include Ag, Bi, Mg, Li, Yb, Cu, La, Pr, Nd, Pm, Sm, Eu, Gd, Tb, Dy, Ho, Er, Tm, or Lu. For example, the first metal dopant may include Li, Yb, or Bi. However, embodiments are not limited thereto, and any metal material capable of lowering the LUMO energy level of the organic host material included in the first electron injection layer 142a may be used without any specific limitation.

In an embodiment, the organic host may include a compound represented by Chemical Formula A or Chemical Formula B:

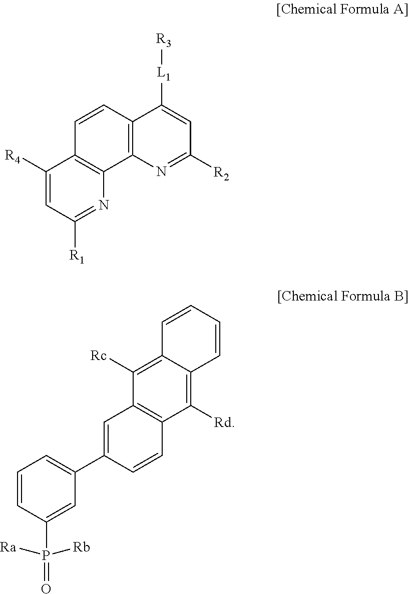

In Chemical Formula A, L₁ may be a direct linkage, or a substituted or unsubstituted phenylene group. R₃ may be bonded to a core structure of Chemical Formula A via L₁. When L₁ is a direct linkage, R₃ may be directly bonded to the core structure of Chemical Formula A. When L₁ is a substituted or unsubstituted phenylene group, R₃ may be bonded to the core structure of Chemical Formula A via the substituted or unsubstituted phenylene group.

In Chemical Formula A, R₁ and R₂ may each independently be a hydrogen atom, a substituted or unsubstituted methyl group, or a substituted or unsubstituted phenyl group. R₁ and R₂ may be the same as each other or different from each other.

In Chemical Formula A, R₃ and R₄ may each independently be a hydrogen atom, a substituted or unsubstituted C₆-C₃₀ aryl group, or a substituted or unsubstituted C₂-C₃₀ heteroaryl group. R₃ and R₄ may be the same as each other or different from each other.

In Chemical Formula B, Rₐ and R_{b} may each independently be a substituted or unsubstituted C₁-C₂₀ alkyl group, or a substituted or unsubstituted C₆-C₃₀ aryl group. Rₐ and R_{b} may be the same as each other or different from each other.

In Chemical Formula B, R_{c} and Rₐ may each independently be a substituted or unsubstituted C₆-C₃₀ aryl group. R_{c} and Rₐ may be the same as each other or different from each other.

In an embodiment, Chemical Formula A may be represented by Chemical Formula A-1 or Chemical Formula A-2. Chemical Formula A-1 represents a case where L₁ is a direct linkage, and Chemical Formula A-2 represents a case where L₁ is an unsubstituted phenylene group.

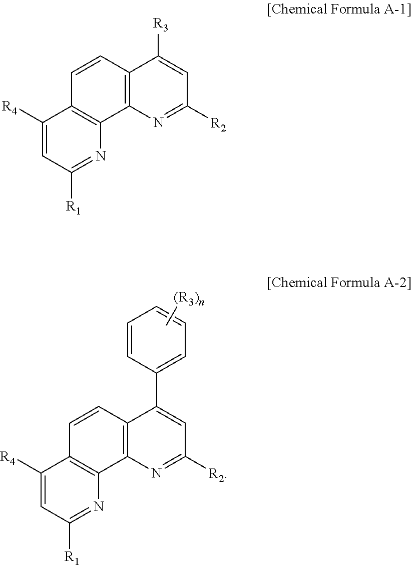

In Chemical Formula A-2, n may be an integer from 0 to 5. When n is 2 or more, two or more of R₃ may be the same, or at least one R₃ may be different from the remainder. In Chemical Formula A-1 and Chemical Formula A-2. R₁ to R₄ may be the same as described in Chemical Formula A.

In an embodiment, in Chemical Formula A-2. R₃ may be a group represented by one of S1 to S25:

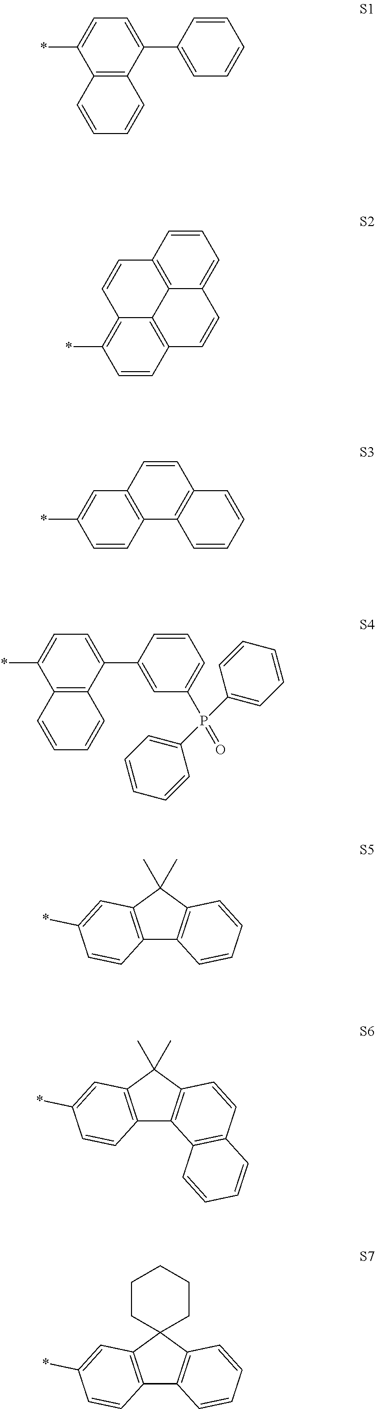

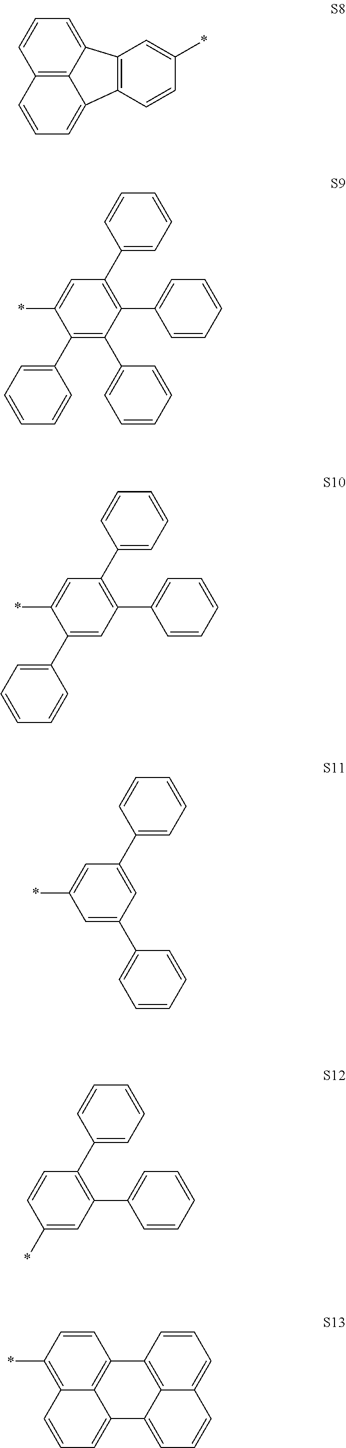 [SMILES: *c1ccc2c(c1)-c1cccc3cccc-2c13 ; *c1cc(-c2ccccc2)c(-c2ccccc2)c(-c2ccccc2)c1-c1ccccc1 ; *c1cc(-c2ccccc2)c(-c2ccccc2)cc1-c1ccccc1 ; *c1cc(-c2ccccc2)cc(-c2ccccc2)c1 ; *c1ccc(-c2ccccc2)c(-c2ccccc2)c1 ; *c1ccc2c3cccc4cccc(c5cccc1c52)c43]

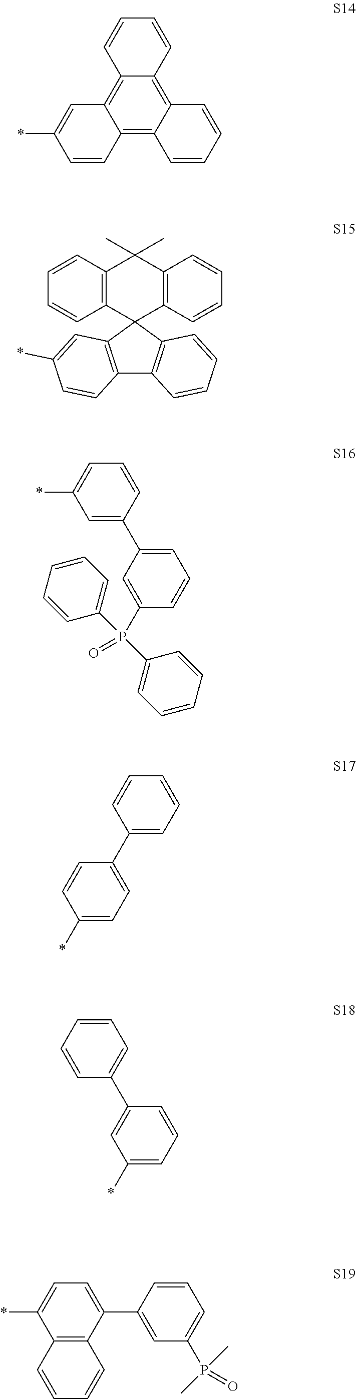 [SMILES: *c1ccc2c3ccccc3c3ccccc3c2c1 ; *c1ccc2c(c1)C1(c3ccccc3-2)c2ccccc2C(C)(C)c2ccccc21 ; *c1cccc(-c2cccc(P(=O)(c3ccccc3)c3ccccc3)c2)c1 ; *c1ccc(-c2ccccc2)cc1 ; *c1cccc(-c2ccccc2)c1 ; *c1ccc(-c2cccc(P(C)(C)=O)c2)c2ccccc12]

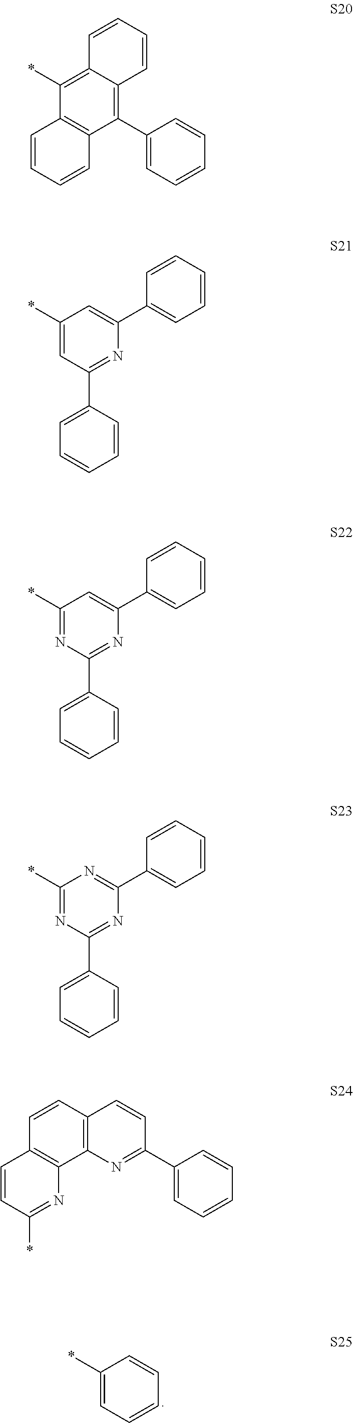 [SMILES: *c1c2ccccc2c(-c2ccccc2)c2ccccc12 ; *c1cc(-c2ccccc2)nc(-c2ccccc2)c1 ; *c1cc(-c2ccccc2)nc(-c2ccccc2)n1 ; *c1nc(-c2ccccc2)nc(-c2ccccc2)n1 ; *c1ccc2ccc3ccc(-c4ccccc4)nc3c2n1 ; *c1ccccc1]

In embodiments, the organic host of the first electron injection layer 142a may include at least one compound selected from Compound Group 1. For example, the organic host of the first electron injection layer 142a may include one compound, or two or more compounds selected from Compound Group 1:

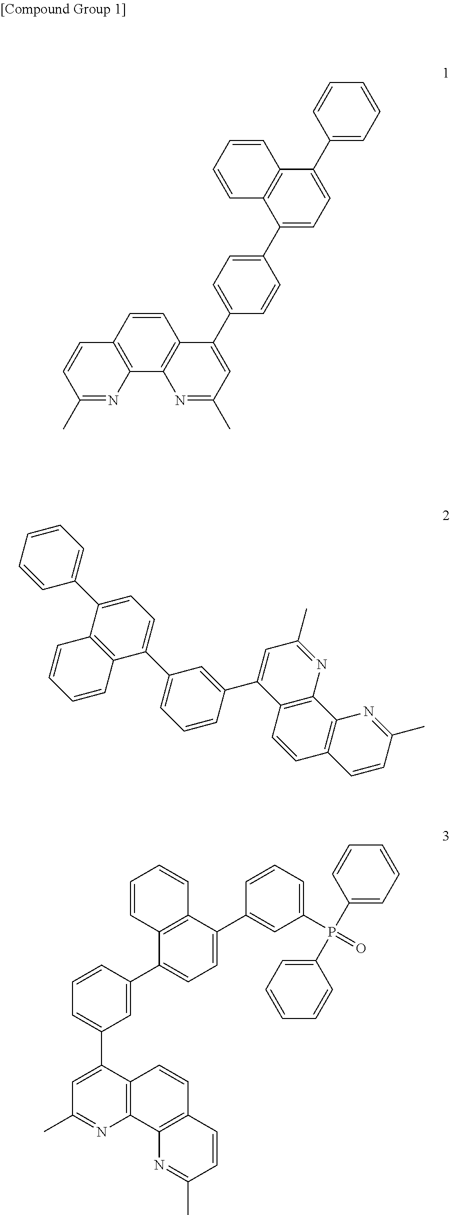

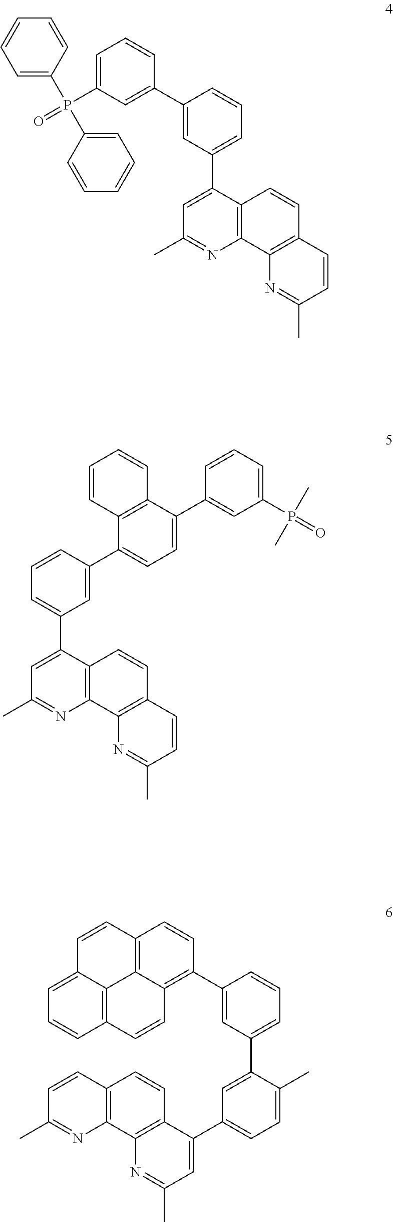

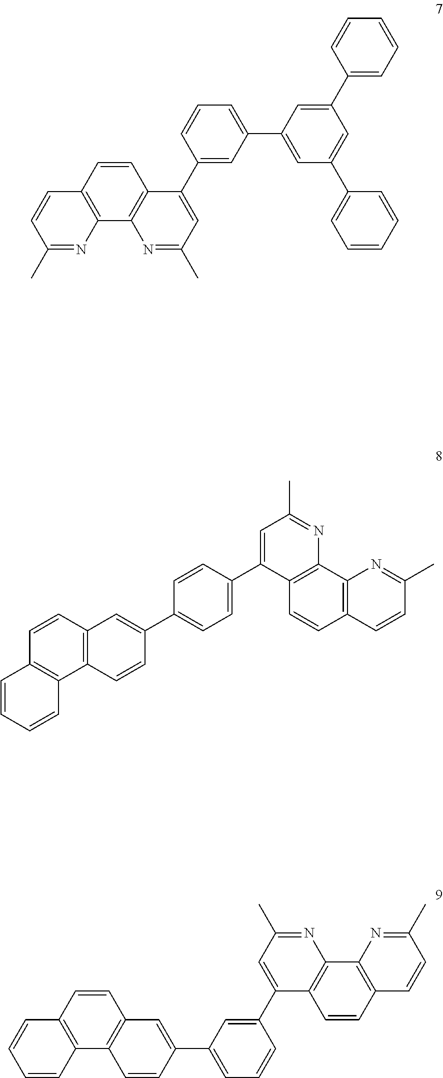 [SMILES: Cc1ccc2ccc3c(-c4cccc(-c5cc(-c6ccccc6)cc(-c6ccccc6)c5)c4)cc(C)nc3c2n1 ; Cc1ccc2ccc3c(-c4ccc(-c5ccc6c(ccc7ccccc76)c5)cc4)cc(C)nc3c2n1 ; Cc1ccc2ccc3c(-c4cccc(-c5ccc6c(ccc7ccccc76)c5)c4)cc(C)nc3c2n1]

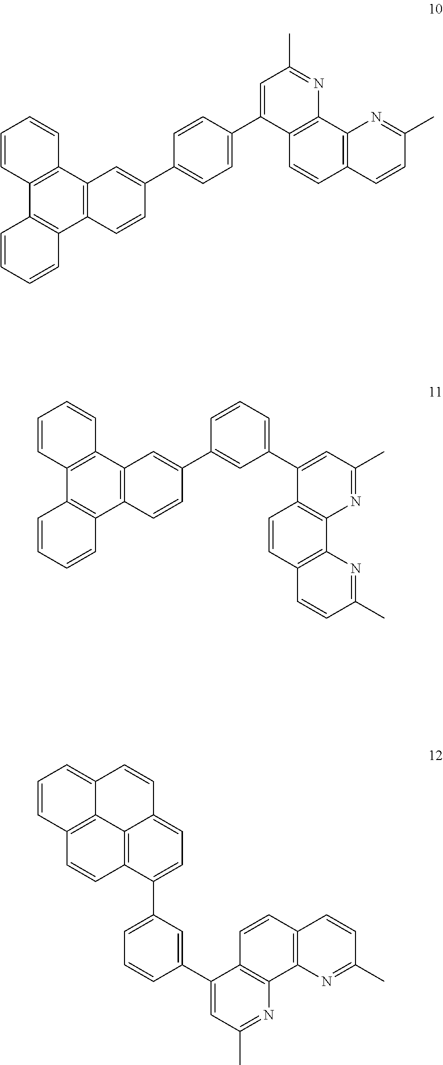 [SMILES: Cc1ccc2ccc3c(-c4ccc(-c5ccc6c7ccccc7c7ccccc7c6c5)cc4)cc(C)nc3c2n1 ; Cc1ccc2ccc3c(-c4cccc(-c5ccc6c7ccccc7c7ccccc7c6c5)c4)cc(C)nc3c2n1 ; Cc1ccc2ccc3c(-c4cccc(-c5ccc6ccc7cccc8ccc5c6c78)c4)cc(C)nc3c2n1]

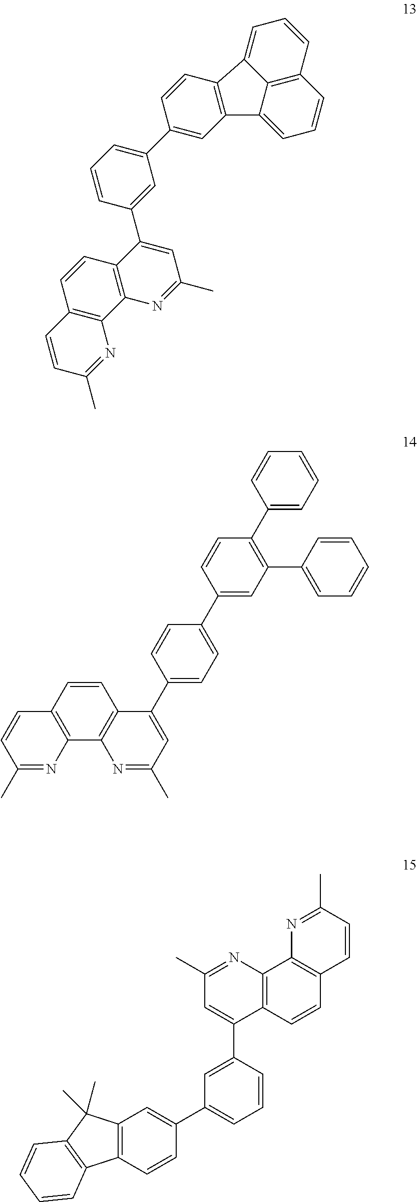 [SMILES: Cc1ccc2ccc3c(-c4cccc(-c5ccc6c(c5)-c5cccc7cccc-6c57)c4)cc(C)nc3c2n1 ; Cc1ccc2ccc3c(-c4ccc(-c5ccc(-c6ccccc6)c(-c6ccccc6)c5)cc4)cc(C)nc3c2n1 ; Cc1ccc2ccc3c(-c4cccc(-c5ccc6c(c5)C(C)(C)c5ccccc5-6)c4)cc(C)nc3c2n1]

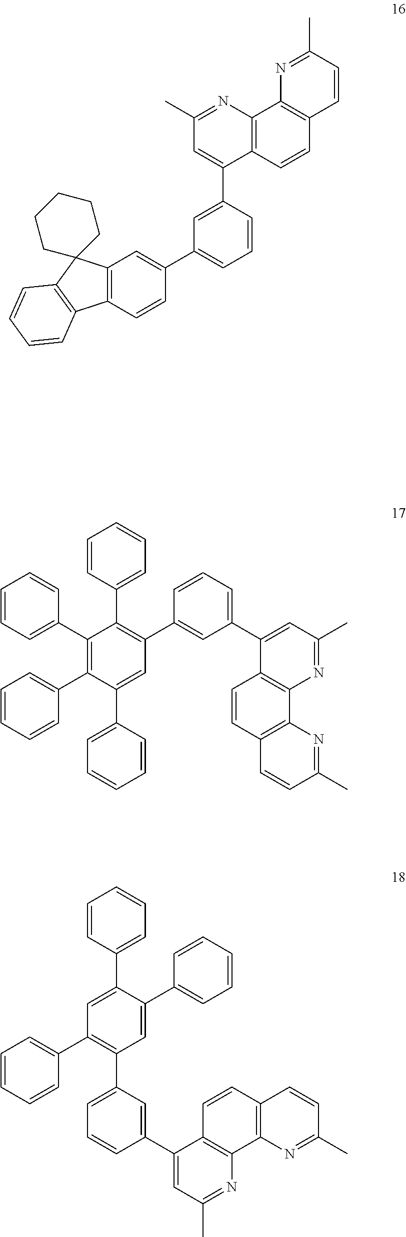 [SMILES: Cc1ccc2ccc3c(-c4cccc(-c5ccc6c(c5)C5(CCCCC5)c5ccccc5-6)c4)cc(C)nc3c2n1 ; Cc1ccc2ccc3c(-c4cccc(-c5cc(-c6ccccc6)c(-c6ccccc6)c(-c6ccccc6)c5-c5ccccc5)c4)cc(C)nc3c2n1 ; Cc1ccc2ccc3c(-c4cccc(-c5cc(-c6ccccc6)c(-c6ccccc6)cc5-c5ccccc5)c4)cc(C)nc3c2n1]

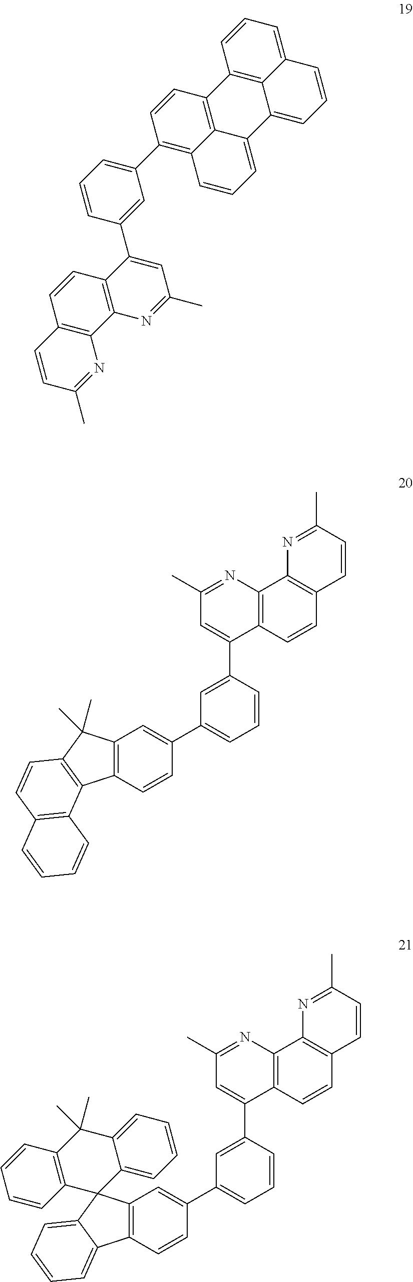 [SMILES: Cc1ccc2ccc3c(-c4cccc(-c5ccc6c7cccc8cccc(c9cccc5c96)c87)c4)cc(C)nc3c2n1 ; Cc1ccc2ccc3c(-c4cccc(-c5ccc6c(c5)C(C)(C)c5ccc7ccccc7c5-6)c4)cc(C)nc3c2n1 ; Cc1ccc2ccc3c(-c4cccc(-c5ccc6c(c5)C5(c7ccccc7-6)c6ccccc6C(C)(C)c6ccccc65)c4)cc(C)nc3c2n1]

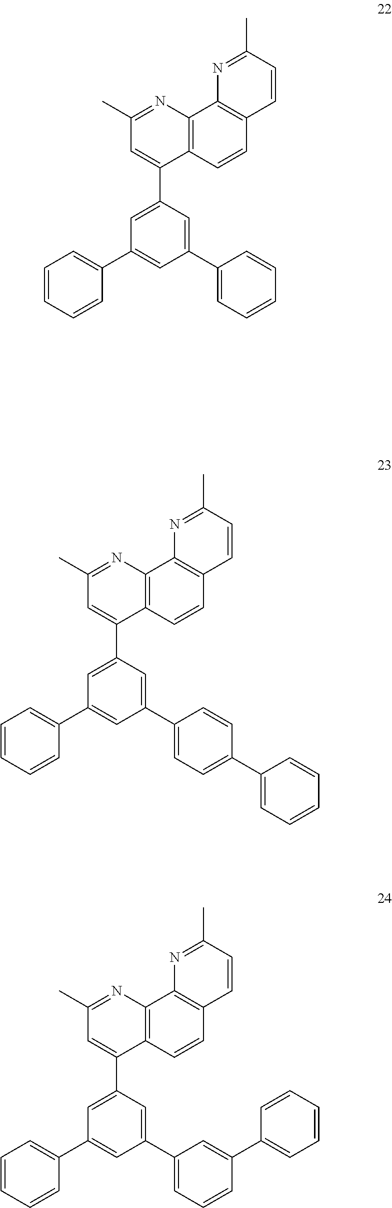 [SMILES: Cc1ccc2ccc3c(-c4cc(-c5ccccc5)cc(-c5ccccc5)c4)cc(C)nc3c2n1 ; Cc1ccc2ccc3c(-c4cc(-c5ccccc5)cc(-c5ccc(-c6ccccc6)cc5)c4)cc(C)nc3c2n1 ; Cc1ccc2ccc3c(-c4cc(-c5ccccc5)cc(-c5cccc(-c6ccccc6)c5)c4)cc(C)nc3c2n1]

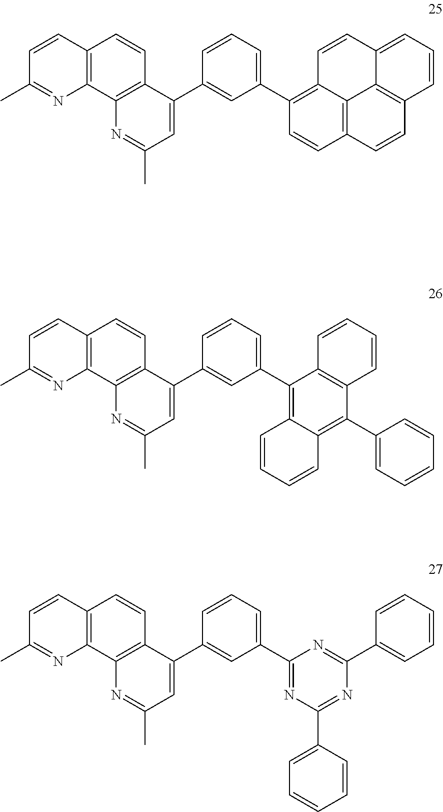 [SMILES: Cc1ccc2ccc3c(-c4cccc(-c5ccc6ccc7cccc8ccc5c6c78)c4)cc(C)nc3c2n1 ; Cc1ccc2ccc3c(-c4cccc(-c5c6ccccc6c(-c6ccccc6)c6ccccc56)c4)cc(C)nc3c2n1 ; Cc1ccc2ccc3c(-c4cccc(-c5nc(-c6ccccc6)nc(-c6ccccc6)n5)c4)cc(C)nc3c2n1]

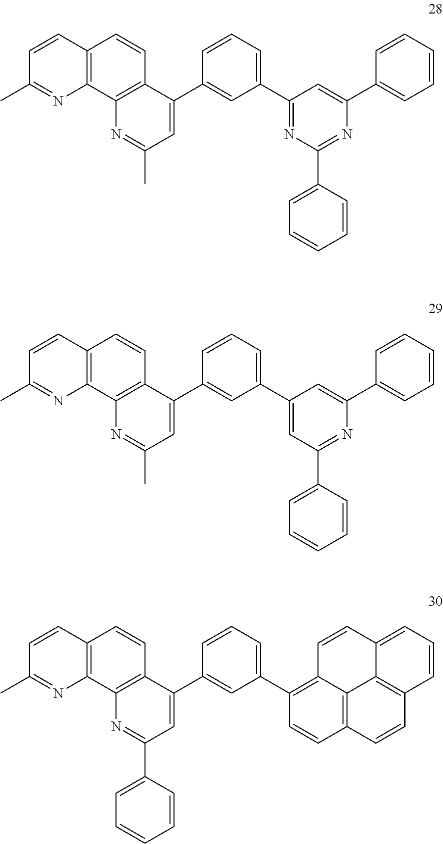 [SMILES: Cc1ccc2ccc3c(-c4cccc(-c5cc(-c6ccccc6)nc(-c6ccccc6)n5)c4)cc(C)nc3c2n1 ; Cc1ccc2ccc3c(-c4cccc(-c5cc(-c6ccccc6)nc(-c6ccccc6)c5)c4)cc(C)nc3c2n1 ; Cc1ccc2ccc3c(-c4cccc(-c5ccc6ccc7cccc8ccc5c6c78)c4)cc(-c4ccccc4)nc3c2n1]

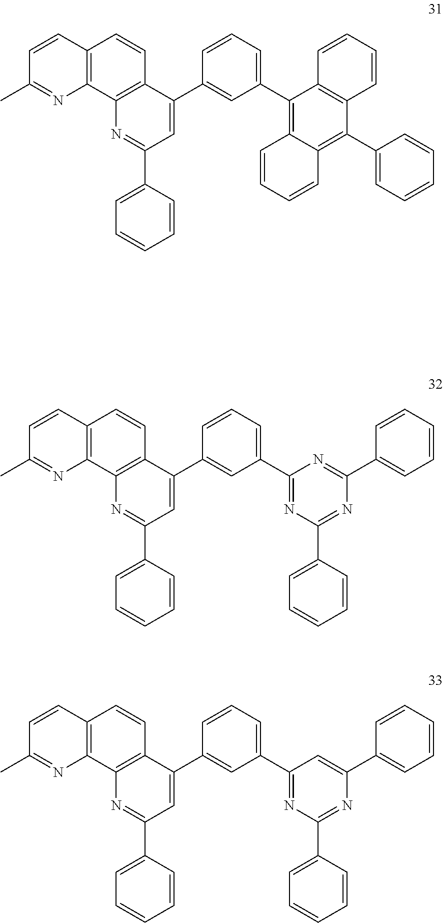 [SMILES: Cc1ccc2ccc3c(-c4cccc(-c5c6ccccc6c(-c6ccccc6)c6ccccc56)c4)cc(-c4ccccc4)nc3c2n1 ; Cc1ccc2ccc3c(-c4cccc(-c5nc(-c6ccccc6)nc(-c6ccccc6)n5)c4)cc(-c4ccccc4)nc3c2n1 ; Cc1ccc2ccc3c(-c4cccc(-c5cc(-c6ccccc6)nc(-c6ccccc6)n5)c4)cc(-c4ccccc4)nc3c2n1]

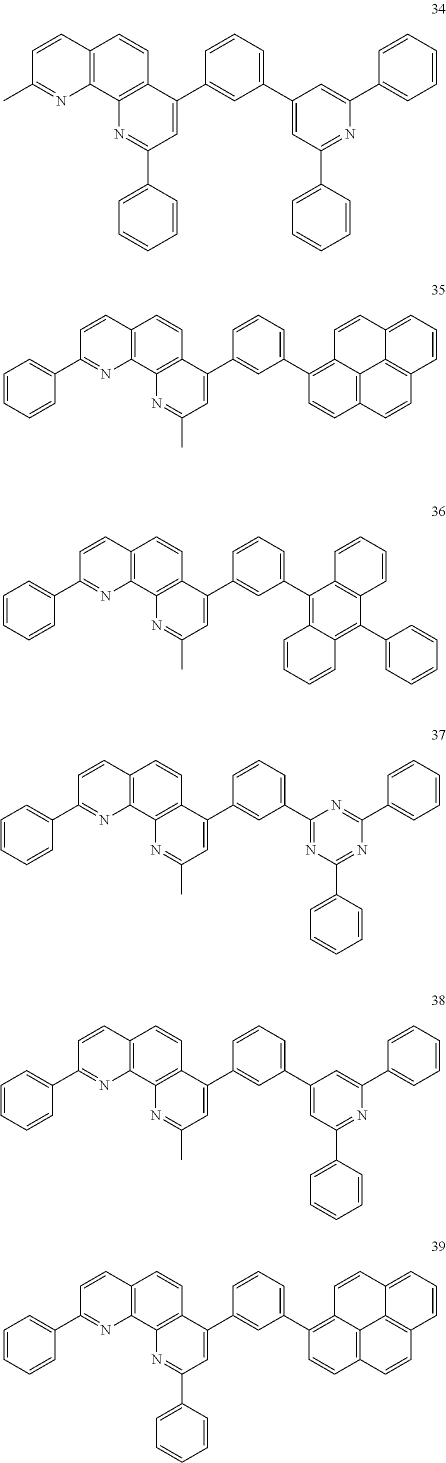 [SMILES: Cc1ccc2ccc3c(-c4cccc(-c5cc(-c6ccccc6)nc(-c6ccccc6)c5)c4)cc(-c4ccccc4)nc3c2n1 ; Cc1cc(-c2cccc(-c3ccc4ccc5cccc6ccc3c4c56)c2)c2ccc3ccc(-c4ccccc4)nc3c2n1 ; Cc1cc(-c2cccc(-c3c4ccccc4c(-c4ccccc4)c4ccccc34)c2)c2ccc3ccc(-c4ccccc4)nc3c2n1 ; Cc1cc(-c2cccc(-c3nc(-c4ccccc4)nc(-c4ccccc4)n3)c2)c2ccc3ccc(-c4ccccc4)nc3c2n1 ; Cc1cc(-c2cccc(-c3cc(-c4ccccc4)nc(-c4ccccc4)c3)c2)c2ccc3ccc(-c4ccccc4)nc3c2n1 ; c1ccc(-c2ccc3ccc4c(-c5cccc(-c6ccc7ccc8cccc9ccc6c7c89)c5)cc(-c5ccccc5)nc4c3n2)cc1]

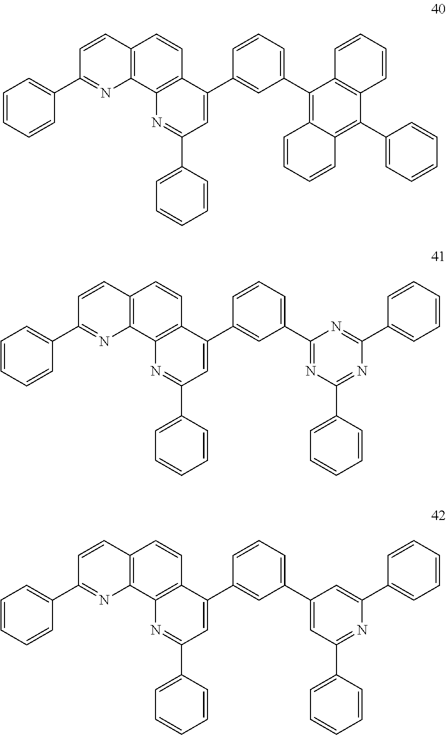 [SMILES: c1ccc(-c2ccc3ccc4c(-c5cccc(-c6c7ccccc7c(-c7ccccc7)c7ccccc67)c5)cc(-c5ccccc5)nc4c3n2)cc1 ; c1ccc(-c2ccc3ccc4c(-c5cccc(-c6nc(-c7ccccc7)nc(-c7ccccc7)n6)c5)cc(-c5ccccc5)nc4c3n2)cc1 ; c1ccc(-c2cc(-c3cccc(-c4cc(-c5ccccc5)nc5c4ccc4ccc(-c6ccccc6)nc45)c3)cc(-c3ccccc3)n2)cc1]

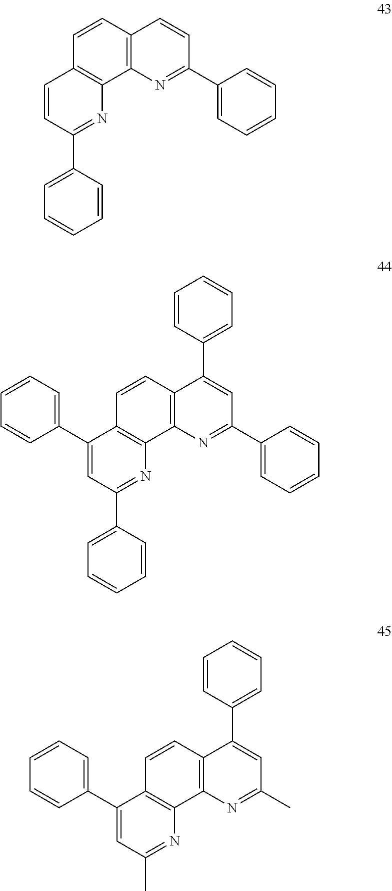 [SMILES: c1ccc(-c2ccc3ccc4ccc(-c5ccccc5)nc4c3n2)cc1 ; c1ccc(-c2cc(-c3ccccc3)c3ccc4c(-c5ccccc5)cc(-c5ccccc5)nc4c3n2)cc1 ; Cc1cc(-c2ccccc2)c2ccc3c(-c4ccccc4)cc(C)nc3c2n1]

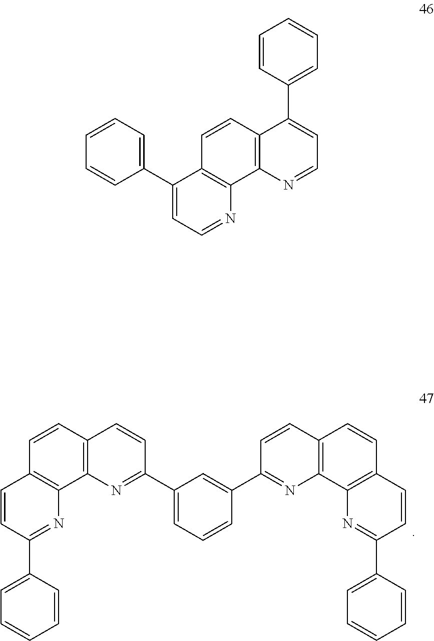 [SMILES: c1ccc(-c2ccnc3c2ccc2c(-c4ccccc4)ccnc23)cc1 ; c1ccc(-c2ccc3ccc4ccc(-c5cccc(-c6ccc7ccc8ccc(-c9ccccc9)nc8c7n6)c5)nc4c3n2)cc1]

In an embodiment. Chemical Formula B may be represented by Chemical Formula B-1 or Chemical Formula B-2. Chemical Formula B-1 represents a case where Rₐ and R_{b} in Chemical Formula B are each an unsubstituted methyl group, and Chemical Formula B-2 represents the case where R. and R; in Chemical Formula B are each an unsubstituted phenyl group.

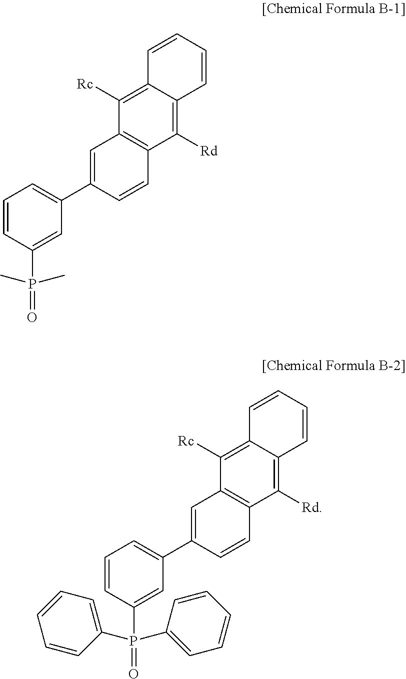

In Chemical Formulae B-1 and B-2, R_{c} and Rₐ may each be the same as described in Chemical Formula B.

In an embodiment, in Chemical Formula B, R_{c} and Rₐ may independently be a group represented by one of T1 to T4:

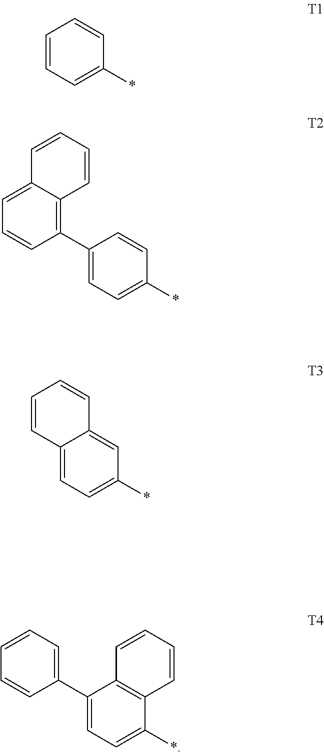

In embodiments, the organic host of the first electron injection layer 142a may include at least one compound selected from Compound Group 2:

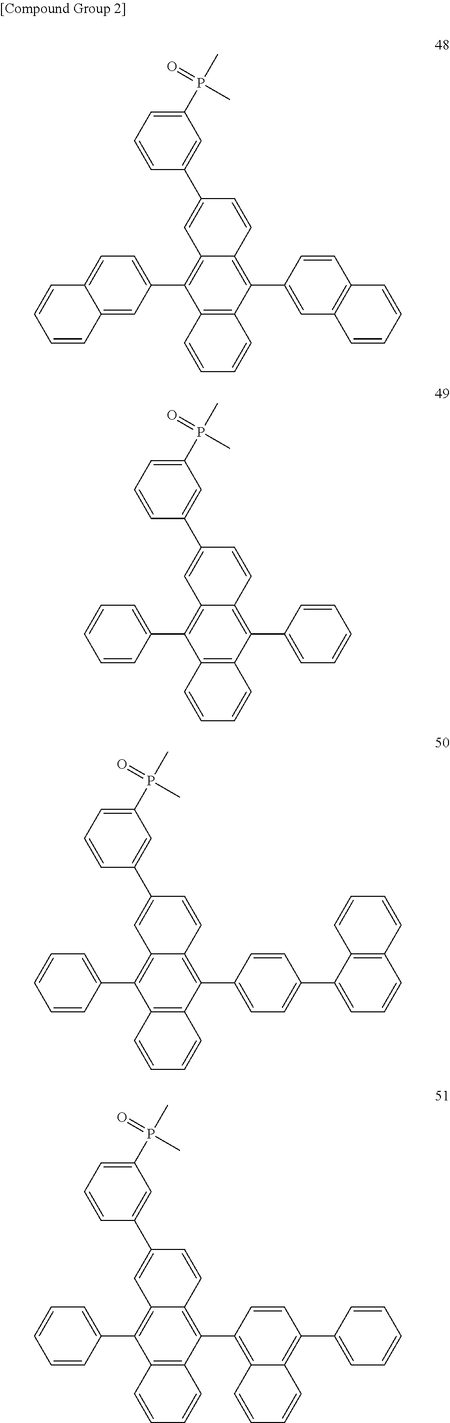

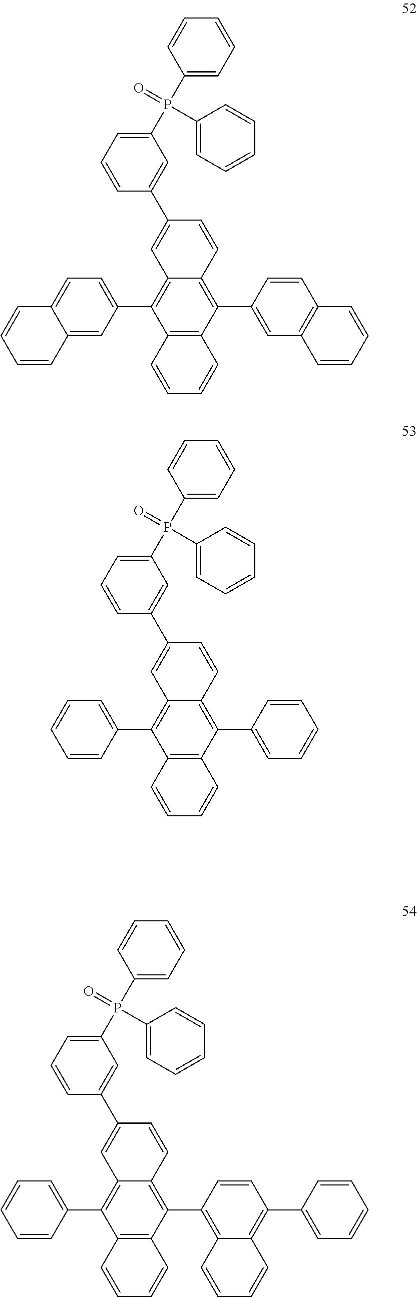 [SMILES: O=P(c1ccccc1)(c1ccccc1)c1cccc(-c2ccc3c(-c4ccc5ccccc5c4)c4ccccc4c(-c4ccc5ccccc5c4)c3c2)c1 ; O=P(c1ccccc1)(c1ccccc1)c1cccc(-c2ccc3c(-c4ccccc4)c4ccccc4c(-c4ccccc4)c3c2)c1 ; O=P(c1ccccc1)(c1ccccc1)c1cccc(-c2ccc3c(-c4ccc(-c5ccccc5)c5ccccc45)c4ccccc4c(-c4ccccc4)c3c2)c1]

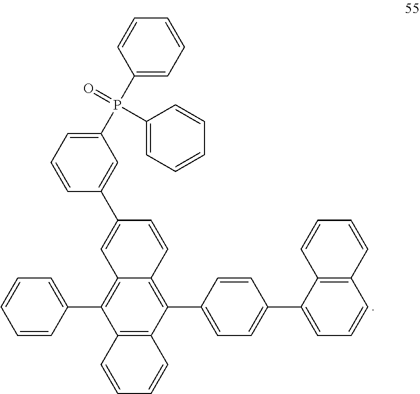 [SMILES: O=P(c1ccccc1)(c1ccccc1)c1cccc(-c2ccc3c(-c4ccc(-c5cccc6ccccc56)cc4)c4ccccc4c(-c4ccccc4)c3c2)c1]

In an embodiment, an absolute value of a difference between a lowest unoccupied molecular orbital (LUMO) energy level of the organic host doped with the first metal dopant and an energy level of a work function of the second electrode 150 may be less than or equal to about 0.2 eV. An energy level difference between the first electron injection layer 142a and the second electrode 150 may be reduced, so that the electron injection properties from the second electrode 150 to the first electron injection layer 142a may be enhanced.

In an embodiment, the first electron injection layer 142a including the first metal dopant and the organic host may have a lower metal content than a metal content of an electron injection layer that includes only the metal, so that a relatively smaller light absorption may occur. Thus, the light-emitting efficiency of the light-emitting device including the first electron injection layer 142a including the first metal dopant and the organic host may be improved.

In an embodiment, in the first electron injection layer 142a, a volume ratio of the first metal dopant to a total volume of the organic host and the first metal dopant may be in a range of about 0.1 volume % (vol %) to about 10 vol %.

In an embodiment, a binding energy of the organic host and the first metal dopant included in the first electron injection layer 142a may be greater than or equal to about 2.0 eV. When the binding energy of the organic host and the first metal dopant is greater than or equal to about 2.0 eV, stability of the organic host doped with the first metal dopant may become enhanced. Accordingly, change in a driving voltage of the light-emitting device ED over time may be reduced, so that the light-emitting device ED may have an extended life-span.

The second electron injection layer 142b may include an inorganic metal compound. The second electron injection layer 142b may be between the first electron injection layer 142a and the second electrode 150, and the second electron injection layer 142b may contact (e.g., directly contact) the second electrode 150 and may serve as a seed layer.

Accordingly, the second electrode 150 may be stably formed during the fabrication of the light-emitting device ED, a layer quality of the second electrode 150 may be improved, and electron injection efficiency may be increased.

In an embodiment, a band gap of the inorganic metal compound may be greater than or equal to about 2.8 eV. For example, the band gap of the inorganic metal compound may be greater than or equal to about 3 eV. For example, the band gap of the inorganic metal compound may be greater than or equal to about 4 eV.

In any of the above ranges, reduction of an electron injection barrier by the first electron injection layer 142a may be promoted, and luminous efficiency of the light-emitting device may be increased. In an embodiment, the inorganic metal compound may have relatively high thermal stability to prevent or reduce a pixel shrinkage phenomenon of the first electron injection layer 142a including the organic-inorganic hybrid material in a high temperature environment.

The inorganic metal compound may be a compound that includes a metal and a non-metal. The metal element included in the inorganic metal compound is not particularly limited, and may include Li, Na, K, R_{b}, Cs, Cₐ, Ma, Al, Si, Zn, Mo, etc.

In an embodiment, the inorganic metal compound may include at least one of a metal halide, a metal oxide, a metal nitride, and a metal sulfide.

The metal halide may include a metal fluoride, a metal chloride, a metal iodide, a metal bromide, etc. For example, the metal halide may include LiI, NaI, KI, RbI, CsI, LiF, NaF, KF, RbF, CsF, etc.

The metal oxide may include Li₂O, Na₂O, Rb₂O, Cs₂O, ZnO, MoO₃, MgO, CaO, Al₂O₃, SiO₂, etc.

The metal nitride may include Li₃N, Na₃N, K₃N, Rb₃N, Si₃N₄, etc.

The metal sulfide may include, e.g., ZnS.

The above-mentioned materials may be used alone or in any combination thereof.

In an embodiment, the metal element of the first metal dopant and the inorganic metal compound may be the same. For example, the metal element of the first metal dopant and the inorganic metal compound may each be Li.

In an embodiment, the second electron injection layer 142b may further include a second metal dopant. Accordingly, electrical characteristics of the second electron injection layer 142b may be improved.

In an embodiment, the second metal dopant may include at least one of Ag, Bi, Mg, Li, Yb, Cu, La, Pr, Nd, Pm, Sm, Eu, Gd, Tb, Dy, Ho, Er, Tm, and Lu. These may be used alone or in any combination thereof.

The electron transfer region 140 may further include an electron transport material in at least one of the first electron injection layer 142a, the electron transport layer 144, and the electron blocking layer 146.

In an embodiment, the electron transport material may include a compound represented by Chemical Formula ET.

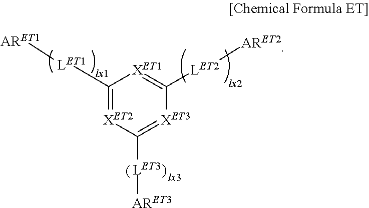

In Chemical Formula ET, at least one of X^{ET1} to X^{ET3} may be N, and the remainder of X^{ET1} to X^{ET3} may each independently be C(RET). In Chemical Formula ET, RET may be a hydrogen atom, a deuterium atom, a substituted or unsubstituted C₁-C₂₀ alkyl group, a substituted or unsubstituted C₆-C₆₀ aryl group, or a substituted or unsubstituted C₂-C₆₀ heteroaryl group.

When one of X^{ET1} to X^{ET3} is N, the compound represented by Chemical Formula ET may include a pyridine group. When two of X^{ET1} to X^{ET3} are N, the compound represented by Chemical Formula ET may include a pyrimidine group. When X^{ET1} to X^{ET3} are each N, the compound represented by Chemical Formula ET may include a triazine group.

In Chemical Formula ET, 1×1 to 1×3 may each independently be an integer from 0 to 10. In Chemical Formula ET, L^{ET1} to L^{ET3} may each independently be a direct linkage, a substituted or unsubstituted C₆-C₃₀ arylene group, or a substituted or unsubstituted C₂-C₃₀ heteroarylene group.

When 1×1, 1×2, or 1×3 is 2 or more, two or more of each of L^{ET1}, L^{ET2}, or L^{ET3}, respectively, may be directly linked together, e.g., by carbon atoms of each aryl ring (e.g., sp2 carbons), to form a substituted or unsubstituted C₆-C₃₀ arylene group, or a substituted or unsubstituted C₂-C₃₀ heteroarylene group.

In Chemical Formula ET, Ar^{ET1} to Ar^{ET3} may each independently be a hydrogen atom, a deuterium atom, a substituted or unsubstituted C₁-C₂₀ alkyl group, a substituted or unsubstituted C₆-C₃₀ aryl group, or a substituted or unsubstituted C₂-C₃₀ heteroaryl group. For example, Ar^{ET1} to Ar^{ET3} may each independently be a substituted or unsubstituted phenyl group, a substituted or unsubstituted carbazole group, a substituted or unsubstituted fluorene group, or a substituted or unsubstituted silyl group. The silyl group may be represented by —Si(R^{sa})(R^{sb})(R^{sc}), as explained above.

For example, the electron transfer region 140 may include an anthracene compound, Alq3 (tris(8-hydroxyquinolinato)aluminum), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzoimidazol-1-yl)phenyl)-9,10-dinaphthylanthracene, TPBi (1,3,5-tri (1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,08)-(1,1′-biphenyl-4-olato)aluminum), Bebq2 (beryllium bis(benzoquinolin-10-olate)), ADN (9,10-di(naphthalene-2-yl) anthracene), BmPyPhB(1,3-bis[3,5-di(pyridin-3-yl)phenyl]benzene), etc. The electron transfer region 140 may include one of the electron transfer materials described above, or any combination thereof.

The electron transfer materials as described above may be included in at least one of the electron injection layer 142, the electron transport layer 144, and the hole blocking layer 146.

The electron transfer region 140 may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof. In an embodiment, the above-mentioned material may be included in the electron injection layer 142.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include an oxide, a halide (e.g., a fluoride, a chloride, a bromide, an iodide, etc.), a telluride, or a combination thereof of the alkali metal, the alkaline earth metal, and the rare earth metal, respectively.

The alkali metal complex, the alkaline earth metal complex, and the rare earth metal complex may include a metal ion such as an alkali metal ion, an alkaline earth metal ion, a rare earth metal ion, and a ligand bonded to the metal ion. The ligand may include, e.g., a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzoimidazole, a hydroxyphenylbenzothiazole, a bipyridine, a phenanthroline, a cyclopentadiene, or any combination thereof.

A thickness of the electron transfer region 140 may be in a range of about 100 Å to about 1,000 Å. For example, the thickness of the electron transfer region 140 may be in a range of about 150 Å to about 500 Å.

In an embodiment, the first electron injection layer 142a including the first metal dopant and the organic host may have a smaller thickness than an electron injection layer that includes only the metal, and the first electron injection layer 142a may be formed as a thin layer.

In an embodiment, a thickness of the first electron injection layer 142a may be in a range of about 10 Å to about 50 Å. For example, a thickness of the first electron injection layer 142a may be in a range of about 15 Å to about 45 Å. For example, a thickness of the first electron injection layer 142a may be in a range of about 20 Å to about 40 Å.

In an embodiment, a thickness of the second electron injection layer 142b may be in a range of about 1 Å to about 20 Å. For example, a thickness of the second electron injection layer 142b may be in a range of about 1 Å to about 15 Å. For example, a thickness of the second electron injection layer 142b may be in a range of about 1 Å to about 10 Å.

In any of the above thickness ranges, electron injection properties and electron transport properties may be further improved without causing excessive increase in the driving voltage, and stability of the electron transfer region 140 may be improved.

A thickness of the electron transport layer 144 may be in a range from about 10 Å to about 900 Å. For example, a thickness of the electron transport layer 144 may be in a range of about 10 Å to about 500 Å. For example, a thickness of the electron transport layer 144 may be in a range of about 100 Å to about 400 Å.

In embodiments, as illustrated in FIG. 2, the electron transfer region 140 may include the second electron injection layer 142b, the first electron injection layer 142a, the electron transport layer 144, and the hole blocking layer 146 stacked from the second electrode 150. Injection of holes from the hole transfer region 120 may be suppressed or blocked by the hole blocking layer 146. Thus, emission energy and luminous efficiency in the emission layer 130 may be further improved.

Each layer of the electron transfer region 140 may be formed by a process such as a vacuum deposition, a spin coating, an inkjet printing, a laser printing, a casting, a laser thermal transfer, etc.

The light-emitting device ED may further include a capping layer. Light emission efficiency to outside the light-emitting device ED may be improved through the capping layer.

As illustrated in FIG. 3, a second capping layer 160b may be formed on an outer surface of the second electrode 150. In embodiments, a first capping layer 160a may be formed on an outer surface of the first electrode 110.

A refractive index of the first capping layer 160a and/or the second capping layer 160b may each independently be greater than or equal to about 1.6. For example, the refractive index of the first capping layer 160a and/or the second capping layer 160b may each independently be greater than or equal to about 1.6 for a light in a wavelength range of 550 nm to 660 nm. For example, the refractive index of the first capping layer 160a and/or the second capping layer 160b may each independently be greater than or equal to about 1.8 for a light in a wavelength range of 550 nm to 660 nm. For example, the refractive index of the first capping layer 160a and/or the second capping layer 160b may each independently be greater than or equal to about 2.0 for a light in a wavelength range of 550 nm to 660 nm.

The first capping layer 160a and the second capping layer 160b may each be formed as an organic capping layer including an organic material, an inorganic capping layer including an inorganic material, or an organic-inorganic composite capping layer including both the organic and inorganic materials.

The first capping layer 160a and/or the second capping layer 160b may each have a single-layered structure or a multi-layered structure including different materials.

In embodiments, the first capping layer 160a and the second capping layer 160b may each independently include a carbocyclic compound, a heterocyclic compound, an amine group-containing compound, a porphine derivative, a phthalocyanine derivative, a naphthalocyanine derivative, an alkaline metal complex, an alkaline earth metal complex, etc. The first capping layer 160a and the second capping layer 160b may each independently include one of the aforementioned materials, or any combination thereof.

In an embodiment, the first capping layer 160a and/or the second capping layer 160b may each independently include an amine group-containing compound.

Referring to FIG. 4, the light-emitting device ED may include multiple light-emitting structures (e.g., the light-emitting structures ES1, ES2, and ES3). The light-emitting structures ES1, ES2, and ES3 may each include a stacked structure of the hole transfer region 120, the emission layer 130, and the electron transfer region 140, as described with reference to FIGS. 1 to 3. In an embodiment, the light-emitting device ED of FIG. 4 may be a light-emitting device having a tandem structure.

Charge generation layers CGL1 and CGL2 may each be disposed between adjacent structures among the light-emitting structures ES1, ES2 and ES3. Charge generation layers CGL1 and CGL2 may each independently include a p-type charge generation layer and/or an n-type charge generation layer.

The p-type charge generation layer may include a hole transport host compound, such as NPB. For example, the p-type charge generation layer may include a compound represented by Chemical Formula HT as described above. The p-type charge generation layer may further include a p-dopant, such as TCNQ.

The n-type charge generation layer may include an electron transport host compound. For example, the n-type charge generation layer may include a compound represented by Chemical Formula ET as described above. In an embodiment, the n-type charge generation layer may include a phenanthroline-based compound.

In an embodiment, a first charge generation layer CGL1 may be disposed between the first light-emitting structure ES1 and the second light-emitting structure ES2, and a second charge generation layer CGL2 may be disposed between the second light-emitting structure ES2 and the third-light emitting structure ES3.

In embodiments, the first light-emitting structure ES1, the first charge generation layer CGL1, the second light-emitting structure ES2, the second charge generation layer CGL2, the third light-emitting structure ES3, and the second electrode 150 may be stacked on a top surface of the first electrode 110.

Colors emitted from the first light-emitting structure ES1, the second light-emitting structure ES2, and the third light-emitting structure ES3 may be the same as or different from each other. In embodiments, the first light-emitting structure ES1, the second light-emitting structure ES2, and the third light-emitting structure ES3 may respectively include a red light-emitting layer, a green light-emitting layer and a blue light-emitting layer, and a white light-emitting device may be implemented through the tandem structure, but embodiments are not limited thereto.

In FIG. 4, the tandem structure in which three light-emitting structures are stacked is illustrated only as an example, and the tandem structure of the light-emitting device is not limited to the structure illustrated in FIG. 4. For example, 2-stack structure, a 4-stack structure, a 5-stack structure, or more stacked structure as will be described with reference FIG. 5 may also be implemented.

Referring to FIG. 5, as described with reference to FIG. 4, a tandem structure in which the light-emitting structure and a charge generation layer may be repeatedly stacked, may be disposed between the first electrode 110 and the second electrode 150.

In embodiments, first to m-th light-emitting structures ES1 to ESm may be stacked from the top surface of the first electrode 110 with a charge generation layer disposed between each pair of adjacent light-emitting structures. The charge generation layer may include a first charge generation layer CGL1 to an (m-1)th charge generation layer CGLm-1 stacked from the top surface of the first electrode 110.

As illustrated in FIG. 5, the first light-emitting structure ES1, the first charge generation layer CGL1, the second light-emitting structure ES2, the second charge generation layer CGL2, . . . ,an (m-1)th light-emitting structure ESm-1, an (m-1)th charge generation layer CGLm-1, an m-th light-emitting structure ESm, and a second electrode 150 may be stacked from the top surface of the first electrode 110.

In embodiments, when m is 4, the light-emitting device may have a 4-stack tandem structure, and may include first to fourth light-emitting structures ES1, ES2, ES3, and ES4, and first to third charge generation layers CGL1, CGL2, and CGL3. Colors of light generated from the first to fourth light-emitting structures ES1, ES2, ES3, and ES4 may be the same as or different from each other.

In an embodiment, the first to fourth light emitting structures ES1, ES2, ES3, and ES4 may include at least one blue light-emitting structure and at least one green-light emitting structure. As a non-limiting example, the first to third light emitting structures ES1, ES2, and ES3 may each be a blue light-emitting structure, and the fourth light emitting structure ES4 may be a green-light emitting structure.

In embodiments, when m is 5, the light-emitting device may have a 5-stack tandem structure, and may include first to fifth light-emitting structures ES1, ES2, ES3, ES4, and ES5, and first to fourth charge generation layers CGL1, CGL2, CGL3, and CGL4. Colors of light generated from the first to fifth light-emitting structures ES1, ES2, ES3, ES4, and ES5 may be the same as or different from each other.

In an embodiment, the first to fifth light-emitting structures ES1, ES2, ES3, ES4, and ES5 may include at least one blue light emitting structure and at least one green light emitting structure. As a non-limiting example, the first to fifth light-emitting structures ES1, ES2, ES3,

ES4, and ES5 may include three blue light-emitting structures and two green light-emitting structures. For example, the first, third, and fifth light-emitting structures ES1, ES3, and ES5 may each be blue light-emitting structure, and the second and fourth light-emitting structures ES2 and ES4 may each be a green light-emitting structure.

### [Electronic Device]

In an embodiment, the above-described light-emitting device ED may be applied to an electronic device and may be provided as a light-emitting portion or a light-emitting unit of the electronic device.

Examples of an electronic device may include a display device, a billboard, a signboard, a light source, a lighting device, a personal computer such as a laptop computer or a desktop computer, a mobile phone, an electronic book, an electronic dictionary, an electronic notebook, a medical diagnostic device, a biometric sensor, and a display for an automobile, an aircraft, a ship, or a train.

In embodiments, the light-emitting device ED may be applied to an organic light emitting diode (OLED) display device or a quantum dot (QD)-OLED display device.

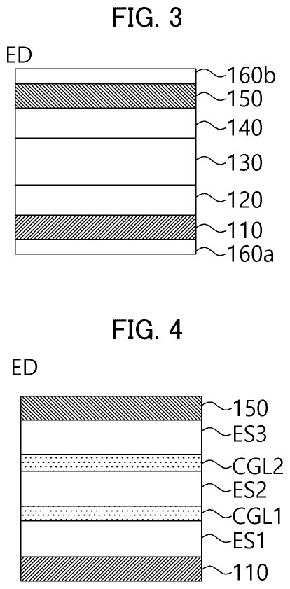

FIG. 6 is a schematic cross-sectional view illustrating a display device according to an embodiment.

Referring to FIG. 6, the display device may include a circuit layer CL disposed on a base substrate 200, and light-emitting devices ED1, ED2, and ED3 disposed on the circuit layer CL.

The base substrate 200 may serve as a supporting substrate or as a back-plane substrate of a display device. The base substrate 100 may be a glass substrate or a plastic substrate.

In embodiments, the base substrate 200 may include a polymer material having transparent and flexible properties. When the base substrate 200 includes a polymer material, the base substrate 200 may be used in a transparent flexible display device. In an embodiment, the base substrate 200 may include a polymer material such as polyimide, polysiloxane, an epoxy resin, an acrylic resin, polyester, etc. For example, the base substrate 200 may include polyimide.

The circuit layer CL may include transistors TR1, TR2, and TR3. The circuit layer CL may include wiring layers and insulating layers that form a thin film transistor array (TFT-Array)(not shown).

The circuit layer CL may further include a buffer layer 205 on a top surface of the base substrate 200. The buffer layer 205 may block the penetration of moisture through the base substrate 200, and may also block the diffusion of impurities between the base substrate 200 and the structures formed thereon.

The buffer layer 205 may include, e.g., silicon oxide, silicon nitride, or silicon oxynitride. The buffer layer 205 may include one of the aforementioned materials, or any combination thereof. In embodiments, the buffer layer 205 may have a stacked structure that includes a silicon oxide layer and a silicon nitride layer.

The transistors TR1, TR2, and TR3 may be disposed on the buffer layer 205. A first transistor TR1, a second transistor TR2, and a third transistor TR3 may be respectively electrically connected to a first light-emitting device ED1, a second light-emitting device ED2, and a third light-emitting device ED3.

The transistors TR1, TR2, and TR3 may each include an active layer 210, a gate insulation layer 220, and a gate electrode 230.

The active layer 210 may be disposed on the buffer layer 205, and may be patterned for each pixel. The active layer 210 may include a silicon compound such as amorphous silicon or polysilicon. A p-type dopant or an n-type dopant may be doped in a region of the active layer 210, and the active layer 210 may include a source region, a drain region, and a channel region.

The active layer 210 may include an oxide semiconductor, such as indium gallium zinc oxide (IGZO), zinc tin oxide (ZTO), or indium tin zinc oxide (ITZO).

The gate insulation layer 220 may be formed on the active layer 210, and the gate electrode 230 may be stacked on the gate insulation layer 220. As illustrated in FIG. 6, the gate insulation layer 220 may be patterned to partially cover each active layer 210. In another embodiment, the gate insulation layer 220 may extend continuously over multiple pixels or light-emitting regions, and may be provided as a common layer for the first, second, and third transistors TR1, TR2, and TR3.

The gate electrode 230 may overlap the channel region of the active layer 210 in a thickness direction.

An insulating interlayer 240 may be formed on the active layer 210 to cover the gate electrode 230 and the gate insulation layer 220. Connection electrodes 250 and 260 may contact or may be electrically connected to the active layer 210. Connection electrodes 250 and 260 may each be disposed on the insulating interlayer 240.

The connection electrodes 250 and 260 may extend through the insulting interlayer 240 to contact the active layer 210 or to be electrically connected to the active layer 210. When the gate insulation layer 220 is provided as a common layer for multiple light-emitting regions, the connection electrodes 250 and 260 may also extend through the gate insulation layer 220.

The connection electrodes 250 and 260 may include a source electrode 250 that may contact or be electrically connected to the source region of the active layer 210, and a drain electrode 260 that may contact or be electrically connected to the drain region of the active layer 210.

The gate insulation layer 220 and the insulating interlayer 240 may each independently include silicon oxide, silicon nitride, or silicon oxynitride, and may each have a stacked structure that includes a silicon oxide layer and a silicon nitride layer.

The gate electrode 230 and the connection electrodes 250 and 260 may each independently include a metal such as Ag, Mg, Al, W, Cu, Ni, Cr, Mo, Ti, Pt, Ta, Nd, Sc, an alloy thereof, or a nitride thereof.

A via insulation layer 270 may be formed on the insulating interlayer 240 to cover the connection electrodes 250 and 260.

The via insulation layer 270 may accommodate a via structure electrically connecting the first electrode 110 and the drain electrode 260. The via insulation layer 270 may serve as a planarization layer of the circuit layer CL. In embodiments, the via insulation layer 270 may include an organic material such as polyimide, an epoxy resin, an acrylic resin, polyester, etc.

The light-emitting devices ED1, ED2, and ED3 may be disposed on the via insulation layer 270. For example, as described with reference to FIGS. 1 to 3, the light-emitting devices ED1, ED2, and ED3 may include the first electrode 110, the hole transfer region 120, the emission layer 130, the electron transfer region 140, and the second electrode 150 which are stacked from the via insulation layer 270.

The first electrode 110 may be electrically connected to the transistors TR1, TR2, and TR3 or to the connection electrodes 250 and 260 in the circuit layer CL through the via structure. As illustrated in FIG. 6, the first electrode 110 may contact or may be electrically connected to the drain electrode 260 to serve as a pixel electrode patterned for each light-emitting region or pixel.

A pixel defining layer 280 may be formed on the via insulation layer 270 to define each light-emitting region or pixel. A blue light-emitting region, a red light-emitting region, and a green light-emitting region may be separated and defined by the pixel defining layer 280, and the light-emitting devices ED1, ED2, and ED3 may respectively correspond to a blue light-emitting device, a red light-emitting device, and a green light-emitting device.

The pixel defining layer 280 may partially cover the first electrode 110 of each light-emitting region.

As illustrated in FIG. 6, the hole transfer region 120 and the electron transfer region 140 may each be provided as a common layer that continuously extends over the pixel defining layer 280 and the first electrodes 110. The emission layer 130 may be formed within each light emitting-region or pixel, and may be separated by the pixel defining layer 280.

In embodiments, the emission layer 130 may also be provided as a common layer that continuously extends over the light emitting-regions or pixels. In embodiments, the hole transfer region 120, the emission layer 130, and the electron transfer region 140 may each be patterned and separately formed for each light-emitting region or pixel.

The second electrode 150 may be provided as a common electrode that continuously extends over the light-emitting regions or the pixels.

An encapsulation layer 290 may be disposed on the pixel defining layer 280 and the light emitting devices ED1, ED2, and ED3 to protect the light-emitting devices ED1, ED2, and ED3 from moisture and/or oxygen. The encapsulation layer 290 may be a thin film encapsulation (TFE) layer having a single-layered structure or multi-layered structure.

The encapsulation layer 290 may include: an inorganic layer that includes silicon nitride (SiNₓ), silicon oxide (SiOₓ), indium tin oxide, indium zinc oxide, or any combination thereof; an organic layer that includes polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., an aliphatic glycidyl ether (AGE)) or any combination thereof; or any combination of the inorganic layer and the organic layer.

The display device may further include a functional layer 300 disposed on the encapsulation layer 290. The functional layer 300 may include a sensor layer such as a touch sensor layer, an optical layer such as a polarizing layer, a color conversion layer, a color filter layer, a window film, or any combination thereof.

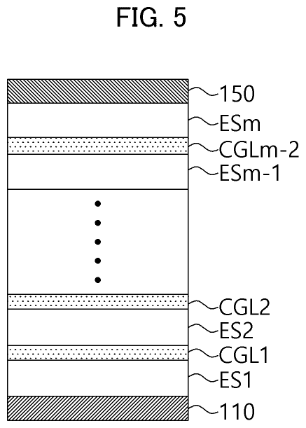

FIG. 7 is a schematic cross-sectional view of a display device according to embodiments.

Referring to FIG. 7, the light-emitting devices ED1, ED2, and ED3 may each have a tandem structure, e.g., a 2-stack tandem structure.

In embodiments, the hole transfer region 120 and the electron transfer region 140 may be continuously and commonly formed and included in an intermediate layer of each light-emitting structure. A charge generation layer CGL may continuously extend across multiple pixels and may be commonly included in the intermediate layer of each light-emitting structure.

The first light-emitting device EDI may include a first lower emission layer 130-1a disposed between the hole transfer region 120 and the charge generation layer CGL, and a first upper emission layer 130-1b disposed between the charge generation layer CGL and the electron transfer region 140.

The second light-emitting device ED2 may include a second lower emission layer 130-2a disposed between the hole transfer region 120 and the charge generation layer CGL, and a second upper emission layer 130-2b disposed between the charge generation layer CGL and the electron transfer region 140.

The third light-emitting device ED3 may include a third lower emission layer 130-3a disposed between the hole transfer region 120 and the charge generation layer CGL, and a third upper emission layer 130-3b disposed between the charge generation layer CGL and the electron transfer region 140.

The lower and upper emission layers included in each light-emitting structure may generate light of a same color. In an embodiment, the first lower emission layer 130-1a and the first upper emission layer 130-1b included in the first light-emitting device EDI may each be a red emission layer. The second lower emission layer 130-2a and the second upper emission layer 130-2b included in the second light-emitting device ED2 may each be a green emission layer. The third lower emission layer 130-3a and the third upper emission layer 130-3b included in the third light-emitting device ED3 may each be a blue emission layer.

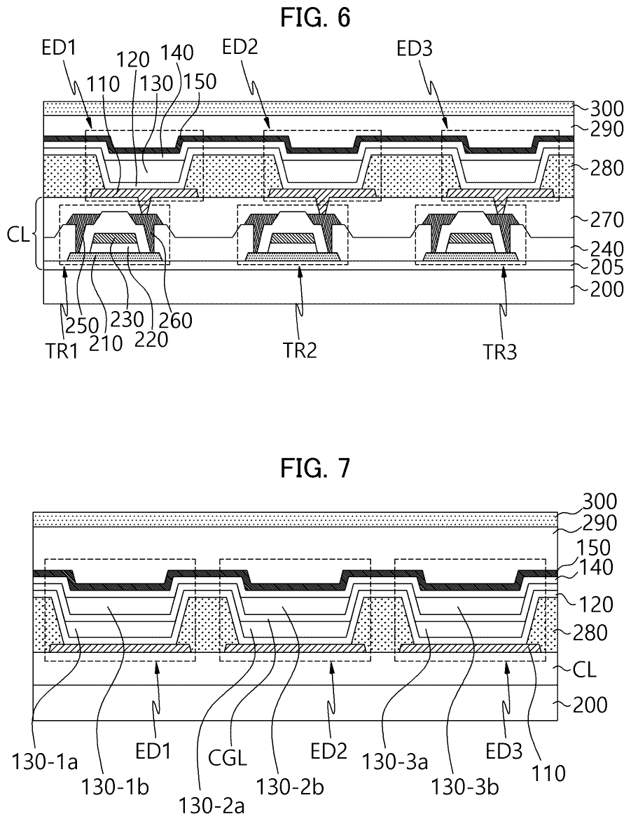

FIG. 8 is a schematic cross-sectional view of a stack construction of light-emitting structure in a display device according to embodiments. For convenience of illustration and description, illustration of the circuit layer, the base substrate, the pixel defining layer, etc., is omitted from FIG. 8, and a shape of each layer or element in the light-emitting structure is shown as a rectangle.

Referring to FIG. 8, at least one of the light-emitting devices ED1, ED2, ED3 or the pixel areas PA1, PA2, and PA3 may have a tandem structure including multiple emission layers, and at least one of the remainder of the light-emitting devices ED1, ED2, ED3 or the pixel areas PA1, PA2, and PA3 may have a single emission layer structure.

In embodiments, one of the light-emitting devices EDI, ED2, ED3 or the pixel areas PA1, PA2, and PA3 may have a tandem structure, and the remainder of the light-emitting devices EDI, ED2, ED3 or the pixel areas PA1, PA2, and PA3 may have a single emission layer structure.

As illustrated in FIG. 8, the first light-emitting device EDI, the second light-emitting device ED2, and the third light-emitting device ED3 may be respectively included in the first pixel area PA1, the second pixel area PA2, and the third pixel area PA3. In embodiments, the first pixel area PA1, the second pixel area PA2, and the third pixel area PA3 may respectively correspond to a red pixel area, a green pixel area, and a blue pixel area.

The hole transfer region 120, the electron transfer region 140, and the second electrode 150 may each be provided as a common layer continuously extending over the first pixel area PA1, the second pixel area PA2, and the third pixel area PA3.

The first-light emitting device EDI included in the first pixel area PA1 may include a first emission layer 130-1, and the second light-emitting device ED2 included in the second pixel area PA2 may include a second emission layer 130-2. The first emission layer 130-1 and the second emission layer 130-2 may each be a single-layered emission layer. The third light-emitting device ED3 included in the third pixel area PA3 may have, e.g., a 2-stack tandem structure. The third light-emitting device ED3 may include a third lower emission layer 130-3a and a third upper emission layer 130-3b, and the charge generation layer CGL may be disposed between the third emission layers 130-3a and 130-3b. The third lower emission layer 130-3a and the third upper emission layer 130-3b may each be a blue emission layer.

A lower electron transfer region 140a may be disposed between the charge generation layer CGL and the third lower emission layer 130-3a. An upper hole transfer region 120b may be disposed between the charge generation layer CGL and the third upper emission layer 130-3b

Accordingly, a tandem light-emitting structure in which the first electrode 110, the hole transfer region 120, the third lower emission layer 130-3a, the lower electron transfer region 140a, the charge generation layer CGL, the upper hole transfer region 120b, the third upper emission layer 130-3b, the electron transfer region 140, and the second electrode 150 are stacked may be disposed in the third pixel area PA3.

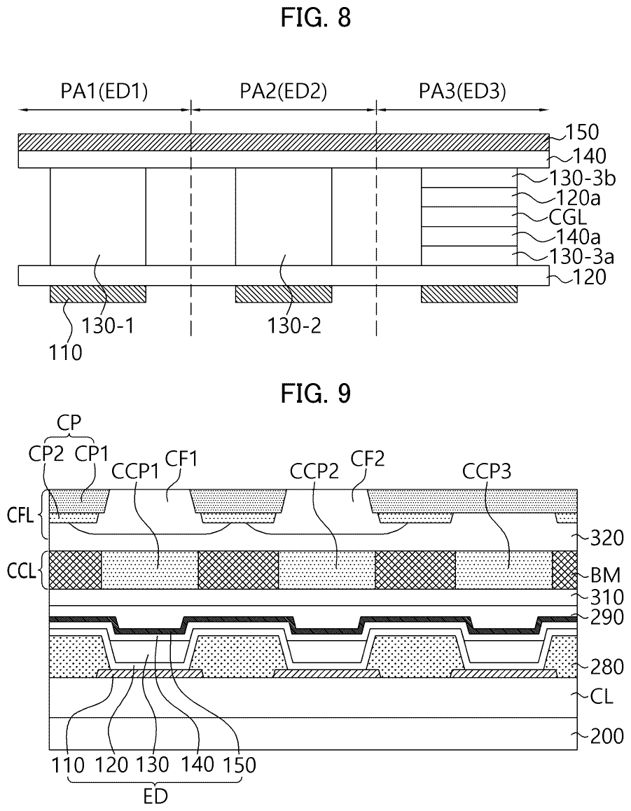

FIG. 9 is a schematic cross-sectional view of a display device according to an embodiment.

FIG. 9 illustrates a display device having a QD-OLED structure according to embodiments. Detailed descriptions regarding elements and structures that are the same as or substantially similar to what has been described above with respect to FIG. 6 will not be repeated here.

Referring to FIG. 9, the pixel defining layer 280 and the light-emitting device ED may be disposed on the circuit layer CL, as described above with respect to FIG. 6. In embodiments, each pixel may emit light in a same wavelength region. In an embodiment, each light-emitting device ED may emit blue light.

In an embodiment, each light-emitting region may include a light-emitting device having a tandem structure, as described above with respect to FIG. 4. For example, when each light-emitting device (ED) has a tandem structure, the intermediate layer of each light-emitting device ED may be provided as a common layer that continuously extends over the light-emitting regions.

A color control layer CCL may be disposed on the encapsulation layer 290, and the color control layer CCL may include color control portions CCP1, CCP2, and CCP3.

The color control portions CCP1, CCP2, and CCP3 may each include a light transformer such as a quantum dot or a phosphor. In each of the color control portions CCP1, CCP2, and CCP3, the light transformer may convert a wavelength of a provided light and emit a resulting light.

The color control portions CCP1, CCP2, and CCP3 may be separated or spaced apart from each other by a bank BM. The bank BM may substantially overlap the pixel defining layer 280, and the color control portions CCP1, CCP2, and CCP3 may substantially overlap each of the emission layers 130.

The color control layer CCL may include a first color control portion CCP1 including a first quantum dot that converts a first color light provided from the light-emitting device ED into a second color light, a second color control portion CCP2 including a second quantum dot that converts the first color light into a third color light, and a third color control portion CCP3 that transmits the first color light.

In embodiments, the first color light, the second color light, and the third color light may respectively be a blue light, a red light, and a green light. The first quantum dot and the second quantum dot may respectively be a red quantum dot and a green quantum dot.

The color control portions CCP1, CCP2, and CCP3 may each further include a scattering material such as inorganic particles. The third color control portion CCP3 may not include quantum dots and may include the scattering material. The scattering material may include TiO₂, ZnO, Al₂O₃, SiO₂, hollow silica, etc. The scattering material may be one of the aforementioned materials or a combination thereof.

The color control portions CCP1, CCP2, and CCP3 may each further include a binder resin that disperses the quantum dot and the scattering material. The binder resin may include an acrylic resin, a urethane resin, a silicone resin, an epoxy resin, etc.

A color filter layer CFL that includes color filters CF1 and CF2 and a light-shielding portion CP may be disposed on the color control layer CCL.

The color filter layer CFL may include a first filter CF1 that transmits the second color light, a second filter CF2 that transmits the third color light, and a third filter that transmits the first color light. For example, the first filter CF1 may be a red filter, the second filter CF2 may be a green filter, and the third filter may be a blue filter.

The color filters CF1 and CF2 may each include a photosensitive binder resin and a colorant including a pigment and/or a dye. The first filter CF1 may include a red pigment or dye, and the second filter CF2 may include a green pigment or dye.

The light-shielding portion CP may be disposed between the color filters. In embodiments, the light-shielding portion may include a first light-shielding portion CP1 and a second light-shielding portion CP2 that includes colorants of different colors.

In embodiments, the first light-shielding portion CP1 may include a blue colorant, and the second light-shielding portion CP2 may include a red colorant or a black colorant. In an embodiment, in the blue light-emitting region, a portion of the first light-shielding portion CP1 may be provided as a blue color filter and may be exposed between the second light-shielding portions CP2, so that an additional color filter (e.g., a third filter) may be omitted.

A first barrier layer 310 may be disposed between the color control layer CCL and the light-emitting device ED (or the encapsulation layer 290). A second barrier layer 320 may be disposed between the color control layer CCL and the color filter layer CFL.

The barrier layers 310 and 320 may each include at least one inorganic layer. For example, the barrier layers 310 and 320 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, etc.

In an embodiment, the barrier layers 310 and 320 may each have a multi-layered structure that further includes an organic layer.

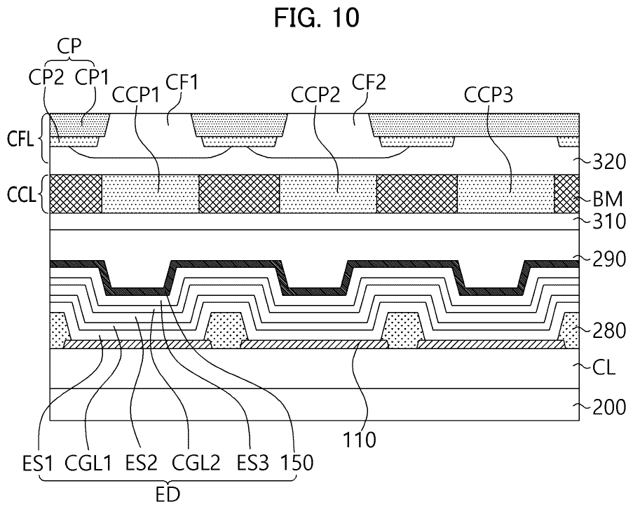

FIG. 10 is a schematic cross-sectional view of a display device according to an embodiment. Detailed descriptions regarding elements and structures that are the same as or substantially similar to what has been described above with respect to FIG. 9 will not be repeated here.

Referring to FIG. 10, the light-emitting device ED corresponding to the color control portions CCP1, CCP2, and CCP3 may be disposed on the first electrode 110 serving as the pixel electrode, and the light-emitting device ED may have a tandem structure.

In an embodiment, as described with reference to FIG. 4, the first light-emitting structure ES1, the first charge generation layer CGL1, the second light-emitting structure ES2, the second charge generation layer CGL2, and the third light-emitting structure ES3 may be stacked between the first electrode 110 and the second electrode 150. The first light-emitting structure ES1, the first charge generation layer CGL1, the second light-emitting structure ES2, the second charge generation layer CGL2, and the third light-emitting structure ES3 may be continuously and commonly formed in multiple pixel areas or light-emitting regions.

In an embodiment, the first light-emitting structure ES1, the second light-emitting structure ES2, and the third light-emitting structure ES3 may generate different color lights, and the light-emitting device ED may generate a white light. In an embodiment, the first light-emitting structure ES1, the second light-emitting structure ES2, and the third light-emitting structure ES3 may all generate blue light.

In embodiments, as described with respect to FIG. 5, the light-emitting device ED may include a tandem structure of 4-stack, 5-stack, or more of the stacked number.

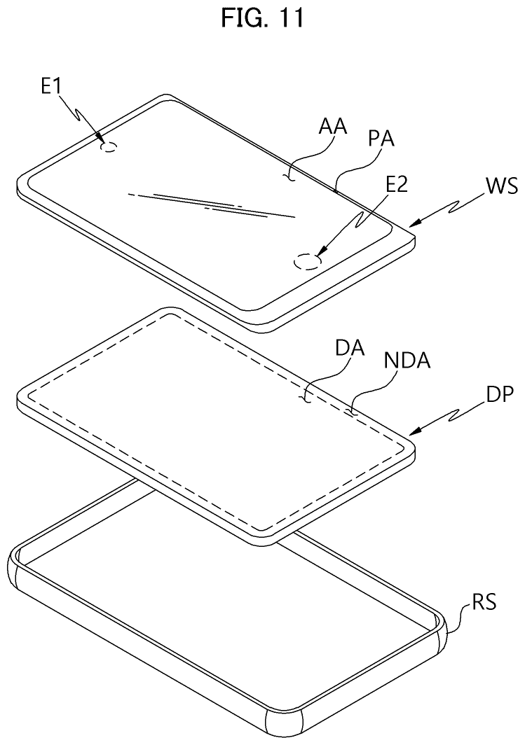

FIG. 11 is an exploded perspective view of an electronic device according to an embodiment.

According to example embodiments, the electronic device may be implemented in the form of a mobile phone (e.g., a smart phone), a tablet computer, a personal computer (PC), or the like, including the above-described display device.

Referring to FIG. 11, the electronic device may include a window structure WS, a display panel DP, and a rear structure RS.

The window structure WS may provide an external display surface recognized by a user, such as a viewing surface of a mobile phone, and may include a transparent material film. For example, the window structure WS may include glass (e.g., ultra-thin glass (UTG), a hard coating film, a plastic film, or the like.

An outer surface of the window structure WS may include an active area AA and a peripheral area PA. The active area AA may provide a surface from which an image of the display panel DP is substantially displayed and to which a user's touch/command is input. The peripheral area PA may substantially correspond to a bezel area of the display device.

The display panel DP may include the above-described display device and may have a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

In embodiments, functional device areas E1 and E2 may be included in the active area AA of the window structure WS. For example, a first functional device area E1 may be included at an end portion of the active area AA and may be implemented, e.g., in the form of a camera hole. The second functional device area E2 may serve as a fingerprint sensing area.

For example, a sensor structure for a touch sensing or a fingerprint sensing may be disposed in the display panel DP or between the window structure WS and the display panel DP.

The rear structure RS may serve as a frame structure or a housing of the display device or the electronic device. A cover panel (not shown) may be disposed between the rear structure RS and the display panel DP.

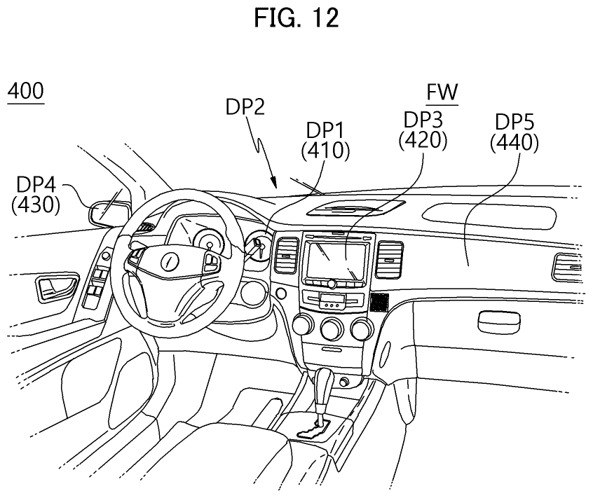

FIG. 12 is a schematic diagram of a vehicle in which an electronic device is disposed according to an embodiment.

The electronic device may be installed in, embedded in, attached to, or integrated with a vehicle 400. However, the vehicle 400 is not limited to the embodiment illustrated in FIG. 12. Further examples of the vehicle 400 may include a transportation means such as a three-wheeled or four-wheeled vehicle, a construction machine, a two-wheeled vehicle, a motor vehicle, a bicycle, a train, etc. Other examples of the vehicle 400 may include an electric vehicle, a hybrid vehicle, etc.

Referring to FIG. 12, at least one of first to fifth display devices DP1, DP2, DP3, DP4, and DP5 may be applied to the vehicle 400.

In embodiments, a first display device DP1 may be disposed in a cluster area 410. Driving information such as a driving distance and speed, and various warning lights may be displayed in the cluster area 410.

A second display device DP2 may be disposed on a front window FW of the vehicle 400. For example, the second display device DP2 may be installed as a head-up display (HUD).

A third display device DP3 may be disposed on a center fascia 420 of the vehicle 400. In the center fascia 420, a button or a switch for controlling an image display or a music player, an air conditioner, a heater, etc., may be displayed, and vehicle information may be displayed thereon.

A fourth display device DP4 may be applied to side mirrors 430 of the vehicle 400. A side mirror 430 may be installed at either side of an exterior of the vehicle 400, and the fourth display device DP4 may be applied to at least one of the side mirrors 430 installed at either side.

A fifth display device DP5 may be disposed on a passenger seat dashboard 440. Information (e.g., an image) that is identical to or different from information displayed on the cluster area 410 and/or the center fascia 420 may be displayed at the passenger seat dashboard 440.

Hereinafter, a light-emitting device according to an embodiment will be described in detail with reference to the Examples and the Comparative Examples. The Examples are provided to assist in understanding the disclosure, but they are provided as non-limiting examples, and the scope of the disclosure is not limited thereto. It will be clear to those skilled in the art that various changes and modifications to disclosed examples can be made within the scope of the disclosure.

### Example 1

A first glass substrate (Corning) having a sheet resistance of 15 Ω/cm² and including ITO (thickness: of 100 Å) coated thereon, a second glass substrate including Ag (thickness: 1,000 Å) coated thereon, and a third glass substrate (Corning) having a sheet resistance of 15 Ω/cm² and including ITO (thickness: of 100 Å) coated thereon were each cut into a size of 50 mm×50 mm×0.7 mm, and ultrasonically cleaned using isopropyl alcohol and pure water for 5 minutes. An ultraviolet ray was irradiated and cleaned by an exposure to ozone for 30 minutes, and the first to third glass substrates were stacked on a vacuum deposition apparatus to form a first electrode of a thickness of 1200 Å.

N,N′-di(1-naphthyl)-N,N′-diphenylbenzidine (NPB) was vacuum-deposited on the first electrode to form a hole injection layer having a thickness of 300 Å. TCTA was vacuum-deposited on the hole injection layer to form a hole transport layer having a thickness of 200 Å.

A host and a dopant as shown in the chemical formulae below were co-deposited at a weight ratio of 99:1 on the hole transport layer to form an emission layer having a thickness of 200 Å.

T2T and TPM-TAZ were deposited on the emission to form an electron transport layer having a thickness of 200 Å. Compound 46 as an organic host and L₁ as a metal dopant were co-deposited on the electron transport layer to form a first electron injection layer having a thickness of 36 Å. A volume ratio of Compound 46 to L₁ was 98.5:1.5.

LiF was vacuum-deposited on the first electron injection layer to form a second electron injection layer having a thickness of 10 Å.

Ag and Mg were co-deposited on the second electron injection layer in a weight ratio of 9:1 to form a second electrode having a thickness of 100 Å, and Compound P4 was deposited on the second electrode to form a capping layer having a thickness of 500 Å, thereby manufacturing a light-emitting device.

Structural formulae of the compounds used in the device fabrication are as follows.

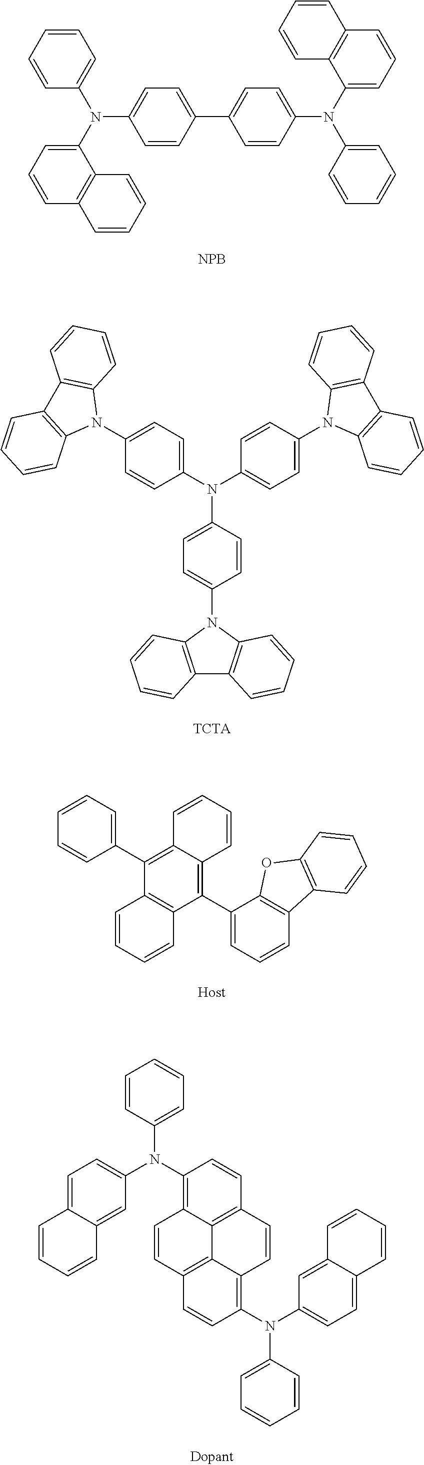 [SMILES: c1ccc(N(c2ccc(-c3ccc(N(c4ccccc4)c4cccc5ccccc45)cc3)cc2)c2cccc3ccccc23)cc1 ; "NPB" ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; c1ccc(-c2c3ccccc3c(-c3cccc4c3oc3ccccc34)c3ccccc23)cc1 ; c1ccc(N(c2ccc3ccccc3c2)c2ccc3ccc4c(N(c5ccccc5)c5ccc6ccccc6c5)ccc5ccc2c3c54)cc1]

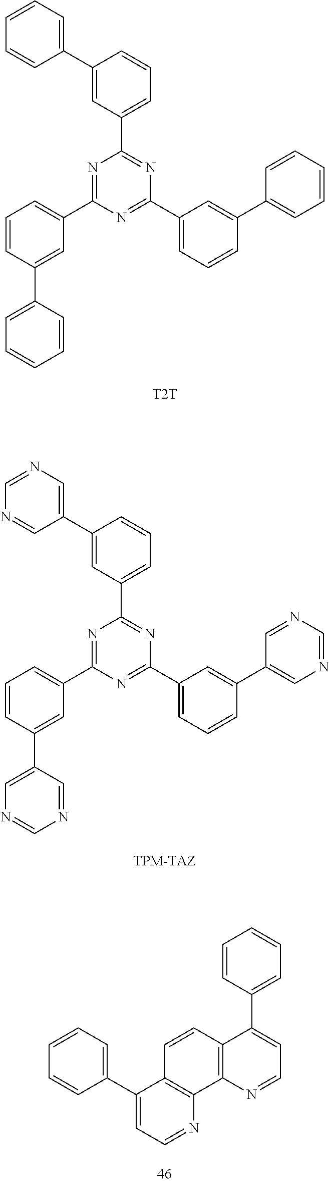 [SMILES: c1ccc(-c2cccc(-c3nc(-c4cccc(-c5ccccc5)c4)nc(-c4cccc(-c5ccccc5)c4)n3)c2)cc1 ; "T2T" ; c1cc(-c2cncnc2)cc(-c2nc(-c3cccc(-c4cncnc4)c3)nc(-c3cccc(-c4cncnc4)c3)n2)c1 ; "TPM-TAZ" ; c1ccc(-c2ccnc3c2ccc2c(-c4ccccc4)ccnc23)cc1]

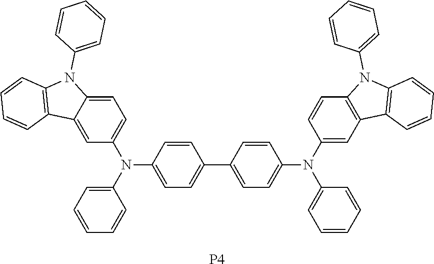 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; "P4"]

### Example 2

A light-emitting device was manufactured by the same method as that described in Example 1, except that Compound 53 was used instead of Compound 46 to form the first electron injection layer.

### Example 3

A light-emitting device was manufactured by the same method as that described in Example 1, except that CuI was deposited instead of LiF to form the second electron injection layer.

### Comparative Example 1

A light-emitting device was manufactured by the same method as that described in Example 1, except that a Yb metal layer was deposited on the electron transport layer to form a single electron injection layer having a thickness of 10 Å, and a second electrode was formed on the single electron injection layer.

### Comparative Example 2

A light-emitting device was manufactured by the same method as that described in Example 1, except that the second electron injection layer was not formed and the second electrode was formed on the first electron injection layer.

### Comparative Example 3

A light-emitting device was manufactured by the same method as that described in Example 1, except that the first electron injection layer was not formed and the second electron injection layer was formed on the second electron transport layer.

### Comparative Example 4

A light-emitting device was manufactured by the same method as that described in Example 1, except that Compound 46, and L₁ and LiF as metal dopants were co-deposited on the electron transport layer to form a single electron injection layer having a thickness of 46 Å, and the second electrode was formed on the single electron injection layer. A volume ratio of Compound 46 to L₁ to LiF was 80:1.5:18.5.

### Comparative Example 5

A light-emitting device was manufactured by the same method as that described in Example 1, except that LiF was vacuum-deposited on the electron transport layer to form a first electron injection layer having a thickness of 10 Å, Compound 46 and L₁ as a metal dopant were co-deposited on the first electron injection layer to form a second electron injection layer having a thickness of 36 Å, and a second electrode was formed on the second electron injection layer. A volume ratio of Compound 46 to L₁ was 98.5:1.5.

### Comparative Example 6

A light-emitting device was manufactured by the same method as that described in Example 1, except that BiI₃ (band gap: 1.57 eV or less) was deposited instead of LiF to form the second electron injection layer.

### Experimental Example

Properties of the light-emitting devices according to the Examples and the Comparative Examples were evaluated as follows, and the results are shown in Table 1.

### (1) Evaluation on Luminous Efficiency

When setting each of a driving voltage and an efficiency of the light-emitting device of Comparative Example 1 as 100%, a driving voltage and an efficiency of each light-emitting device of the Examples and the other Comparative Examples were expressed as relative values (%) to the driving voltage and the efficiency of the light-emitting device of Comparative Example 1.

For example, in Table 1, the driving voltage or efficiency greater than 100% indicates that the driving voltage or efficiency was greater than that of Comparative Example 1. The driving voltage or efficiency less than 100% indicates that the driving voltage or efficiency was less than that of Comparative Example 1.

### (2) Evaluation on Pixel Shrinkage

The light-emitting devices of Examples and Comparative Examples were cut into a size of 2 mm*2 mm, and driven in an oven at 60° C. for 100 hours at 2000 nit. A distance between an initial outer line of a pixel and an outer line after the driving was measured to evaluate a pixel shrinkage.

### (3) Transmittance Evaluation

For the light-emitting devices of the Examples and the Comparative Examples, transmittances for a light having a wavelength of 380 nm to 780 nm were continuously measured.

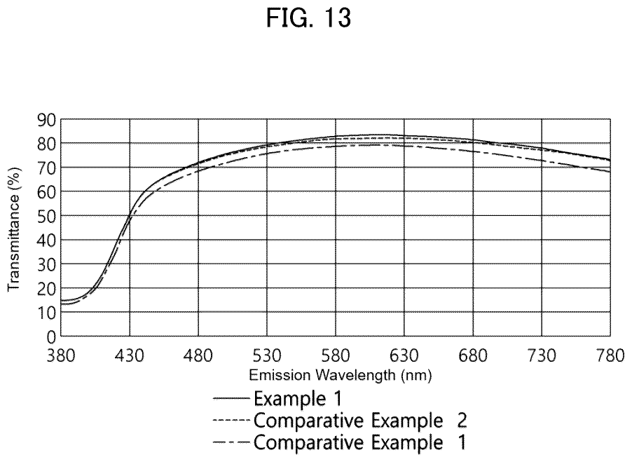

FIG. 13 is a graph showing transmittances of light-emitting device according to Example 1, Comparative Example 1, and Comparative Example 2.

TABLE 1

| | Driving | Luminous Efficiency (%) | | | | Pixel |
|---|---|---|---|---|---|---|
| | Voltage | R | G | B | W | Shrinkage |
| | (%) | efficiency | efficiency | efficiency | efficiency | (μm) |
| Comparative | 100 | 100 | 100 | 100 | 100 | 50 |
| Example 1 | | | | | | |
| Comparative | 98.7 | 112.4 | 112.8 | 107.2 | 110.7 | 96 |
| Example 2 | | | | | | |
| Comparative | 99.1 | 112.9 | 113.1 | 107.4 | 111.0 | 71 |
| Example 3 | | | | | | |
| Comparative | 113 | 89.5 | 90.2 | 90.5 | 90.1 | 113 |
| Example 4 | | | | | | |
| Comparative | 115 | 88.4 | 87.2 | 88.2 | 88.2 | 111 |
| Example 5 | | | | | | |
| Comparative | 101.1 | 95.4 | 95.3 | 94.9 | 95.1 | 37 |
| Example 6 | | | | | | |
| Example 1 | 98.7 | 119.5 | 109.4 | 108.4 | 112.8 | 34 |
| Example 2 | 99.8 | 118.5 | 108.2 | 108.1 | 111.8 | 38 |
| Example 3 | 98.9 | 118.5 | 109.1 | 108.2 | 112.7 | 35 |

Referring to Table 1 and FIG. 13, the light-emitting devices of Examples were capable of being driven by a lower driving voltage, provided improved luminous efficiency, and had relatively small pixel shrinkage even when exposed to high temperature for a long period.

The light-emitting devices of the Comparative Examples had lower luminous efficiencies than those of the Examples, or had excessive pixel shrinkage, and driving stability in harsh environments were degraded.

The light-emitting device of Comparative Example 1 including the single-layered electron injection layer (EIL) formed of a metallic material had lower W efficiency than those of the light-emitting devices of the Examples, and the light-emitting devices of Comparative Examples 2 and 3 including a single-layered EIL formed of an organic-inorganic hybrid material or an inorganic metal compound material had increased pixel shrinkage.

In the light-emitting device of Comparative Example 4 including a single-layered EIL formed by co-deposition of an organic-inorganic hybrid material and an inorganic metal compound material, the electron injection properties were deteriorated, and the driving voltage increased. Further, a cathode seed layer could not be provided, and thus the pixel shrinkage was explicitly increased.

In the light-emitting device of Comparative Example 5 including a double-layered EIL formed by depositing an inorganic metal compound material and an organic-inorganic hybrid material on the electron transport layer, the electron injection properties were deteriorated, and the driving voltage was increased. Further, the cathode seed layer could not be provided, and thus the pixel shrinkage was explicitly increased.

In the light-emitting device of Comparative Example 6 including the second electron injection layer formed of an inorganic metal compound having a band gap less than 2.8 eV, the luminescence efficiency was deteriorated due to a light absorption of the inorganic metal compound.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A light-emitting device, comprising:
a first electrode;
a hole transfer region on the first electrode;
an emission layer on the hole transfer region;
an electron transfer region on the emission layer; and
a second electrode on the electron transfer region, wherein
the electron transfer region includes:
an electron transport layer;
a first electron injection layer on the electron transport layer; and
a second electron injection layer on the first electron injection layer,
the first electron injection layer includes an organic host and a first metal dopant, and
the second electron injection layer includes an inorganic metal compound having a band gap greater than or equal to about 2.8 eV.

2. The light-emitting device of claim 1, wherein the organic host includes a compound represented by Chemical Formula A or Chemical Formula B: 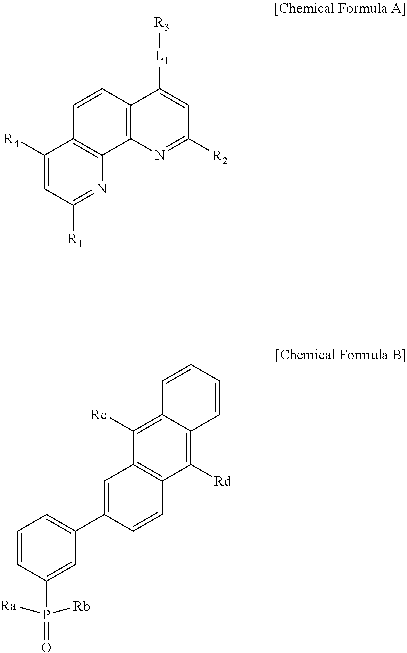
wherein in Chemical Formula A,
L₁ is a direct linkage, or a substituted or unsubstituted phenylene group,
R₁ and R₂ are each independently a hydrogen atom, a substituted or unsubstituted methyl group, or a substituted or unsubstituted phenyl group, and
R₃ and R₄ are each independently a hydrogen atom, a substituted or unsubstituted C₆-C₃₀ aryl group, or a substituted or unsubstituted C₂-C₃₀ heteroaryl group, and
wherein in Chemical Formula B,
Rₐ and R_{b} are each independently a substituted or unsubstituted C₁-C₂₀ alkyl group, or a substituted or unsubstituted C₆-C₃₀ aryl group, and
R_{c} and Rₐ are each independently a substituted or unsubstituted C₆-C₃₀ aryl group.

3. The light-emitting device of claim 2, wherein Chemical Formula A is represented by Chemical Formula A-1 or Chemical Formula A-2: 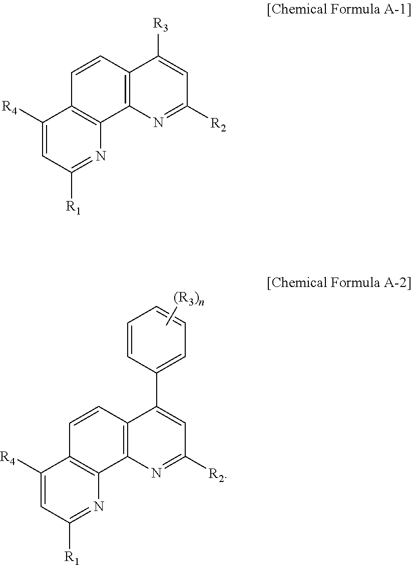
wherein in Chemical Formulae A-1 and A-2,
R₁ and R₂ are each independently a hydrogen atom, a substituted or unsubstituted methyl group, or a substituted or unsubstituted phenyl group, and
R₃ and R₄ are each independently a hydrogen atom, a substituted or unsubstituted C₆-C₃₀ aryl group, or a substituted or unsubstituted C₂-C₃₀ heteroaryl group, and
wherein in Chemical Formula A-2,
n is an integer from 0 to 5.

4. The light-emitting device of claim 3, wherein in Chemical Formula A-2,
R₃ is a group represented by one of S1 to S25:

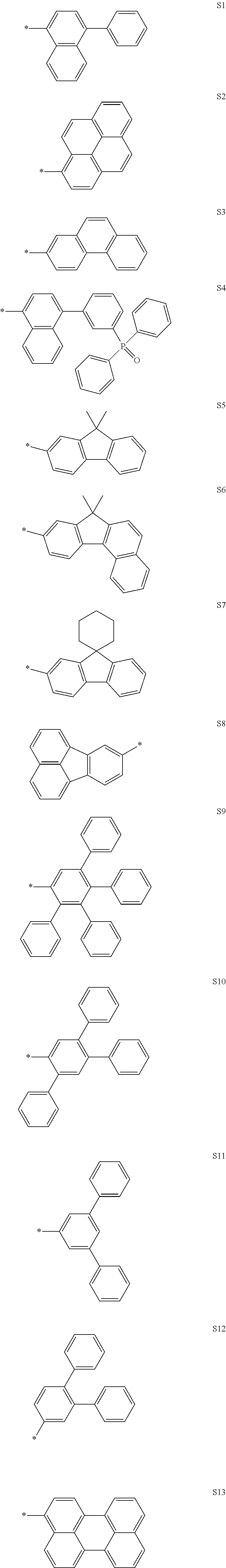

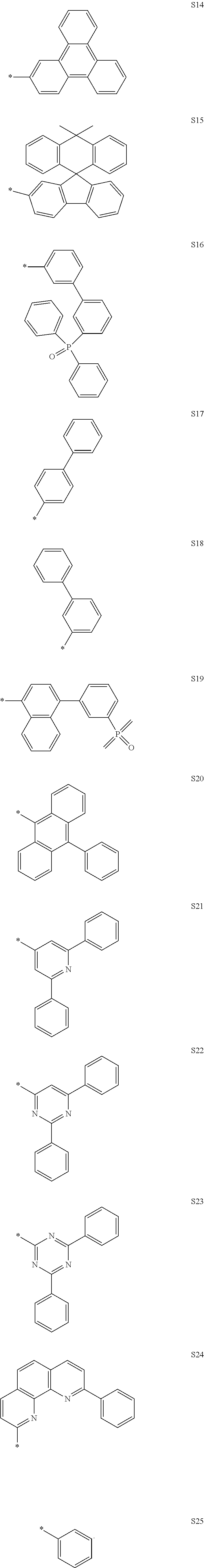

5. The light-emitting device of claim 2, wherein the organic host includes at least one compound selected from Compound Group 1:

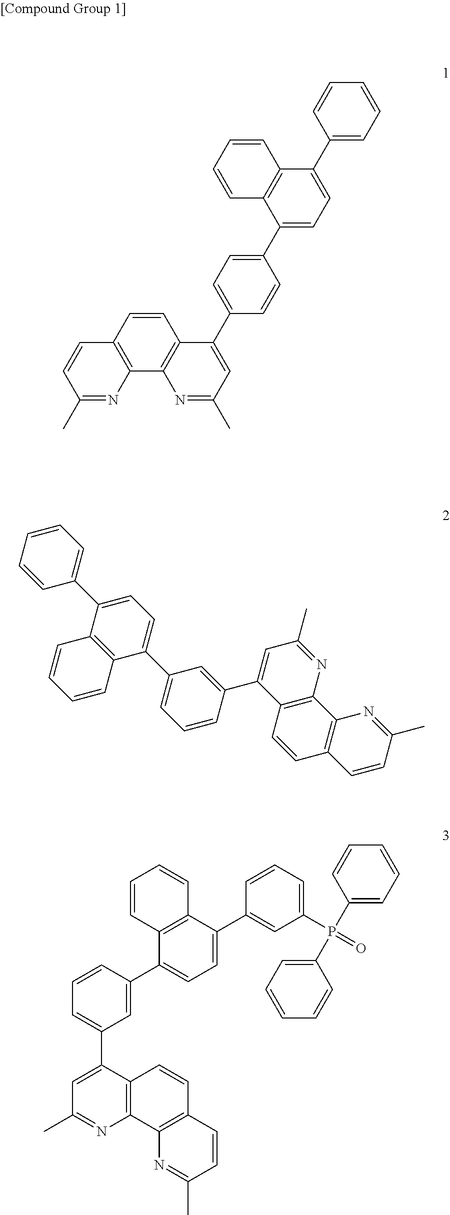

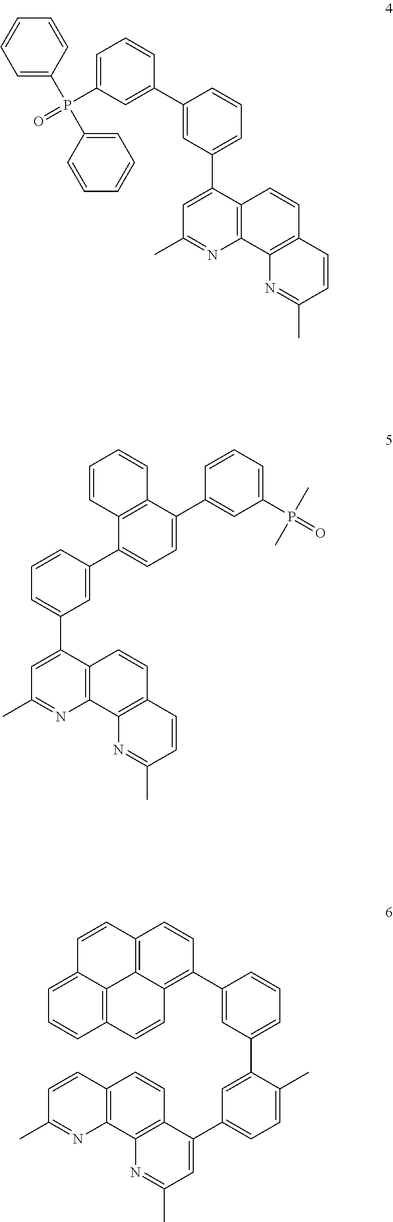

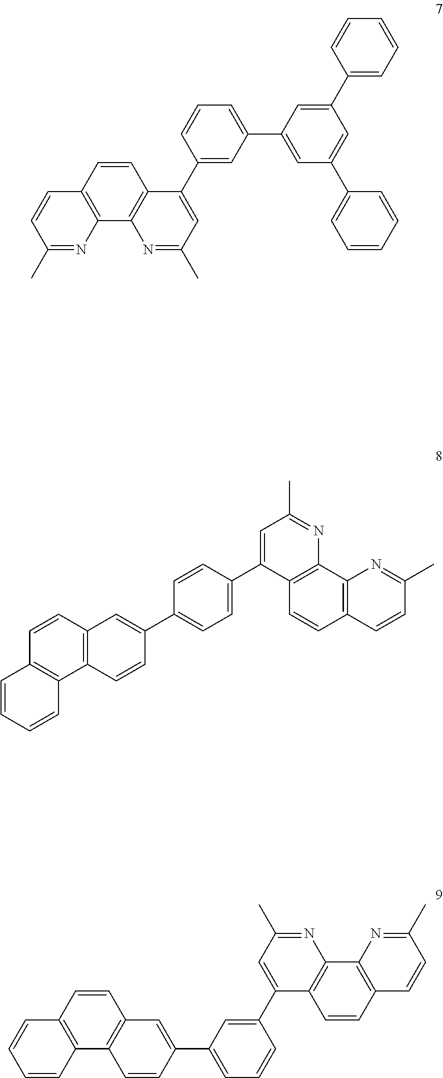 [SMILES: Cc1ccc2ccc3c(-c4cccc(-c5cc(-c6ccccc6)cc(-c6ccccc6)c5)c4)cc(C)nc3c2n1 ; Cc1ccc2ccc3c(-c4ccc(-c5ccc6c(ccc7ccccc76)c5)cc4)cc(C)nc3c2n1 ; Cc1ccc2ccc3c(-c4cccc(-c5ccc6c(ccc7ccccc76)c5)c4)cc(C)nc3c2n1]

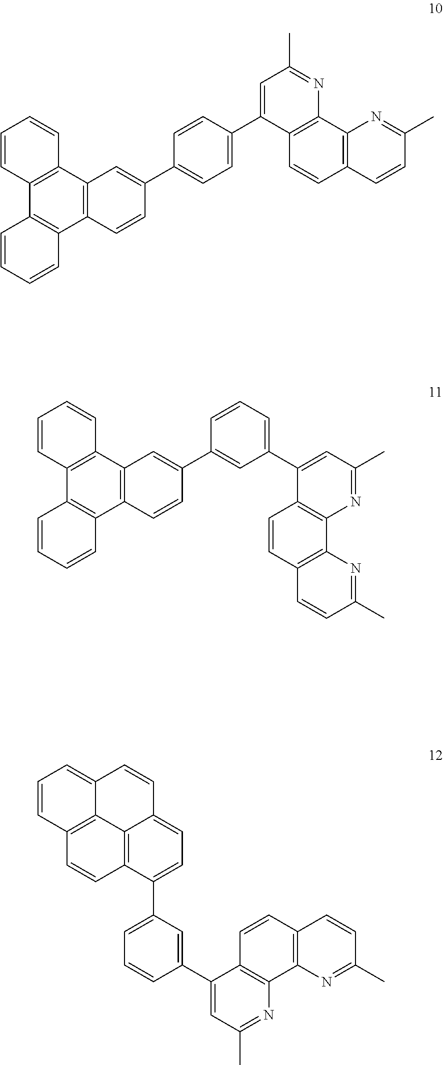 [SMILES: Cc1ccc2ccc3c(-c4ccc(-c5ccc6c7ccccc7c7ccccc7c6c5)cc4)cc(C)nc3c2n1 ; Cc1ccc2ccc3c(-c4cccc(-c5ccc6c7ccccc7c7ccccc7c6c5)c4)cc(C)nc3c2n1 ; Cc1ccc2ccc3c(-c4cccc(-c5ccc6ccc7cccc8ccc5c6c78)c4)cc(C)nc3c2n1]

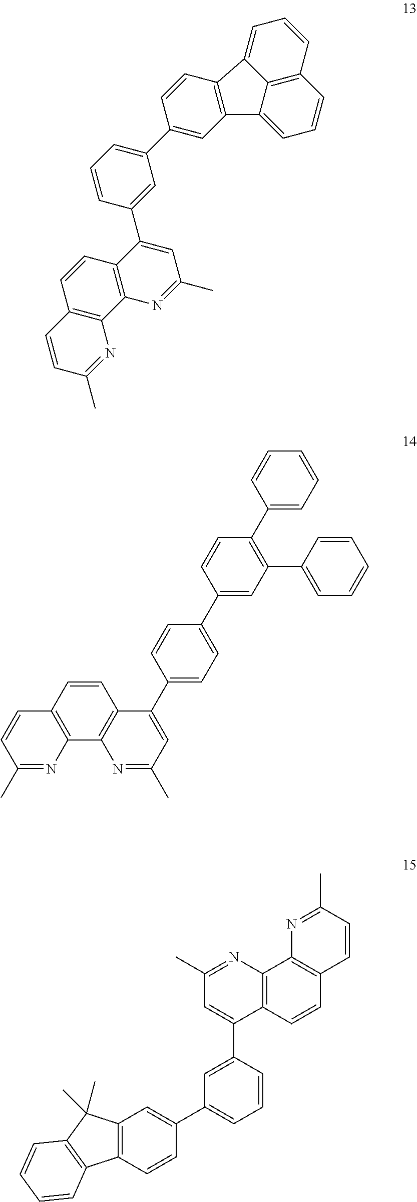 [SMILES: Cc1ccc2ccc3c(-c4cccc(-c5ccc6c(c5)-c5cccc7cccc-6c57)c4)cc(C)nc3c2n1 ; Cc1ccc2ccc3c(-c4ccc(-c5ccc(-c6ccccc6)c(-c6ccccc6)c5)cc4)cc(C)nc3c2n1 ; Cc1ccc2ccc3c(-c4cccc(-c5ccc6c(c5)C(C)(C)c5ccccc5-6)c4)cc(C)nc3c2n1]

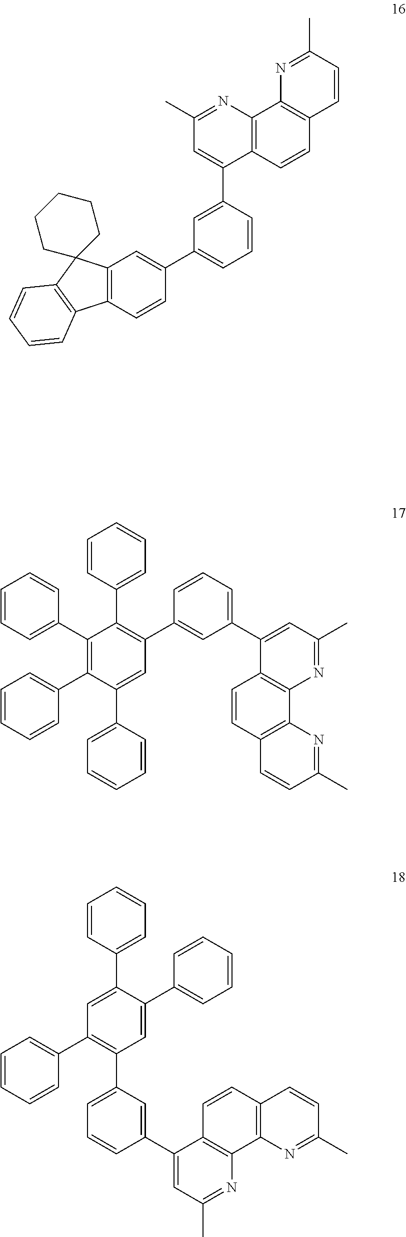 [SMILES: Cc1ccc2ccc3c(-c4cccc(-c5ccc6c(c5)C5(CCCCC5)c5ccccc5-6)c4)cc(C)nc3c2n1 ; Cc1ccc2ccc3c(-c4cccc(-c5cc(-c6ccccc6)c(-c6ccccc6)c(-c6ccccc6)c5-c5ccccc5)c4)cc(C)nc3c2n1 ; Cc1ccc2ccc3c(-c4cccc(-c5cc(-c6ccccc6)c(-c6ccccc6)cc5-c5ccccc5)c4)cc(C)nc3c2n1]

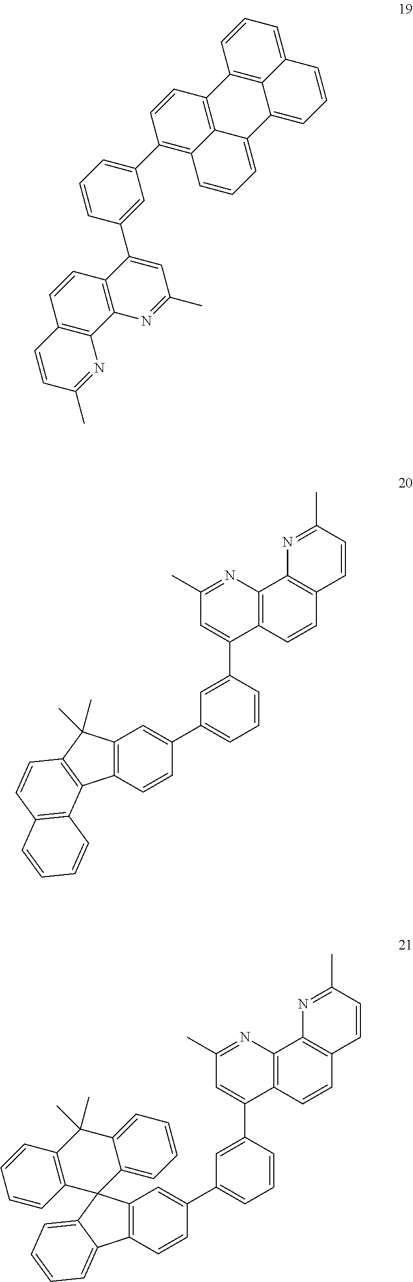 [SMILES: Cc1ccc2ccc3c(-c4cccc(-c5ccc6c7cccc8cccc(c9cccc5c96)c87)c4)cc(C)nc3c2n1 ; Cc1ccc2ccc3c(-c4cccc(-c5ccc6c(c5)C(C)(C)c5ccc7ccccc7c5-6)c4)cc(C)nc3c2n1 ; Cc1ccc2ccc3c(-c4cccc(-c5ccc6c(c5)C5(c7ccccc7-6)c6ccccc6C(C)(C)c6ccccc65)c4)cc(C)nc3c2n1]

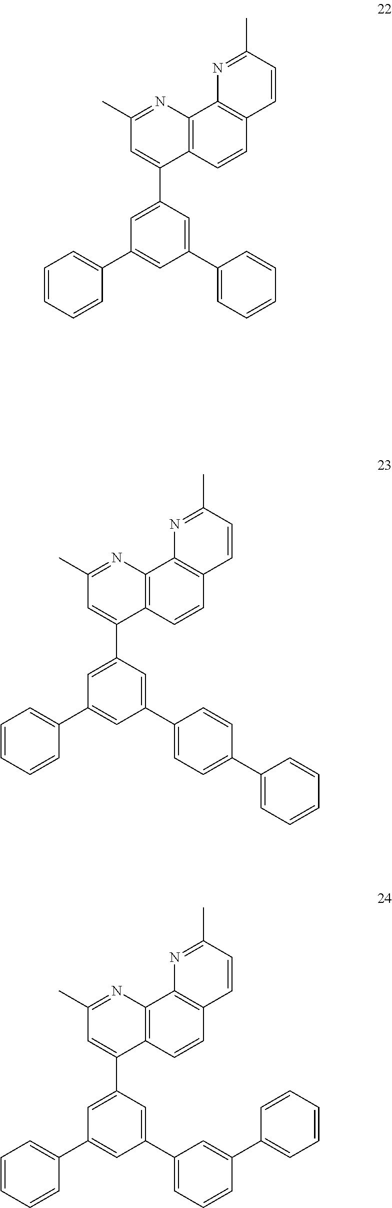 [SMILES: Cc1ccc2ccc3c(-c4cc(-c5ccccc5)cc(-c5ccccc5)c4)cc(C)nc3c2n1 ; Cc1ccc2ccc3c(-c4cc(-c5ccccc5)cc(-c5ccc(-c6ccccc6)cc5)c4)cc(C)nc3c2n1 ; Cc1ccc2ccc3c(-c4cc(-c5ccccc5)cc(-c5cccc(-c6ccccc6)c5)c4)cc(C)nc3c2n1]

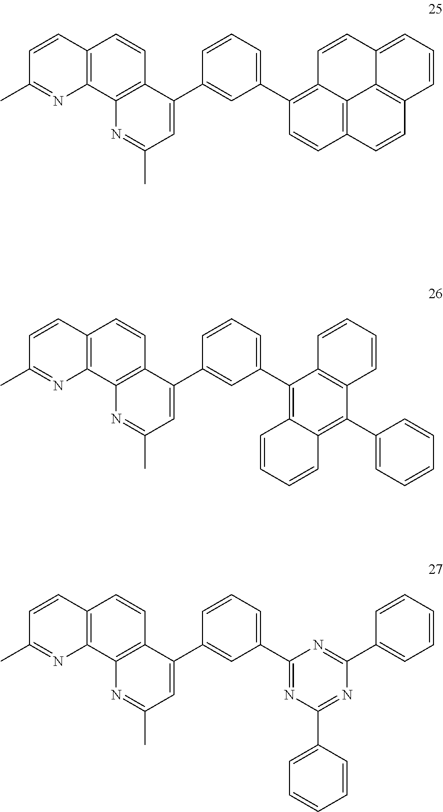 [SMILES: Cc1ccc2ccc3c(-c4cccc(-c5ccc6ccc7cccc8ccc5c6c78)c4)cc(C)nc3c2n1 ; Cc1ccc2ccc3c(-c4cccc(-c5c6ccccc6c(-c6ccccc6)c6ccccc56)c4)cc(C)nc3c2n1 ; Cc1ccc2ccc3c(-c4cccc(-c5nc(-c6ccccc6)nc(-c6ccccc6)n5)c4)cc(C)nc3c2n1]

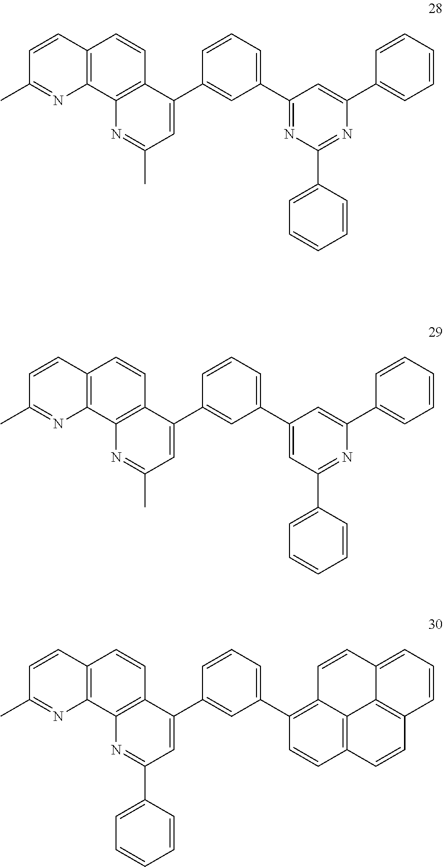 [SMILES: Cc1ccc2ccc3c(-c4cccc(-c5cc(-c6ccccc6)nc(-c6ccccc6)n5)c4)cc(C)nc3c2n1 ; Cc1ccc2ccc3c(-c4cccc(-c5cc(-c6ccccc6)nc(-c6ccccc6)c5)c4)cc(C)nc3c2n1 ; Cc1ccc2ccc3c(-c4cccc(-c5ccc6ccc7cccc8ccc5c6c78)c4)cc(-c4ccccc4)nc3c2n1]

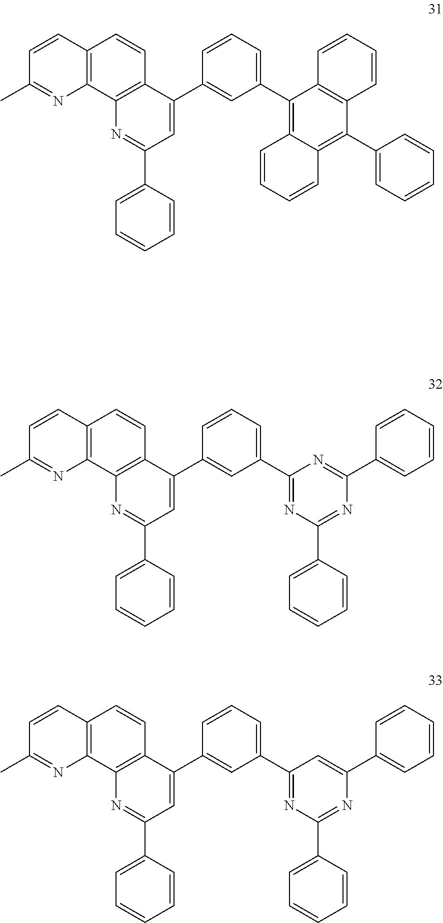 [SMILES: Cc1ccc2ccc3c(-c4cccc(-c5c6ccccc6c(-c6ccccc6)c6ccccc56)c4)cc(-c4ccccc4)nc3c2n1 ; Cc1ccc2ccc3c(-c4cccc(-c5nc(-c6ccccc6)nc(-c6ccccc6)n5)c4)cc(-c4ccccc4)nc3c2n1 ; Cc1ccc2ccc3c(-c4cccc(-c5cc(-c6ccccc6)nc(-c6ccccc6)n5)c4)cc(-c4ccccc4)nc3c2n1]

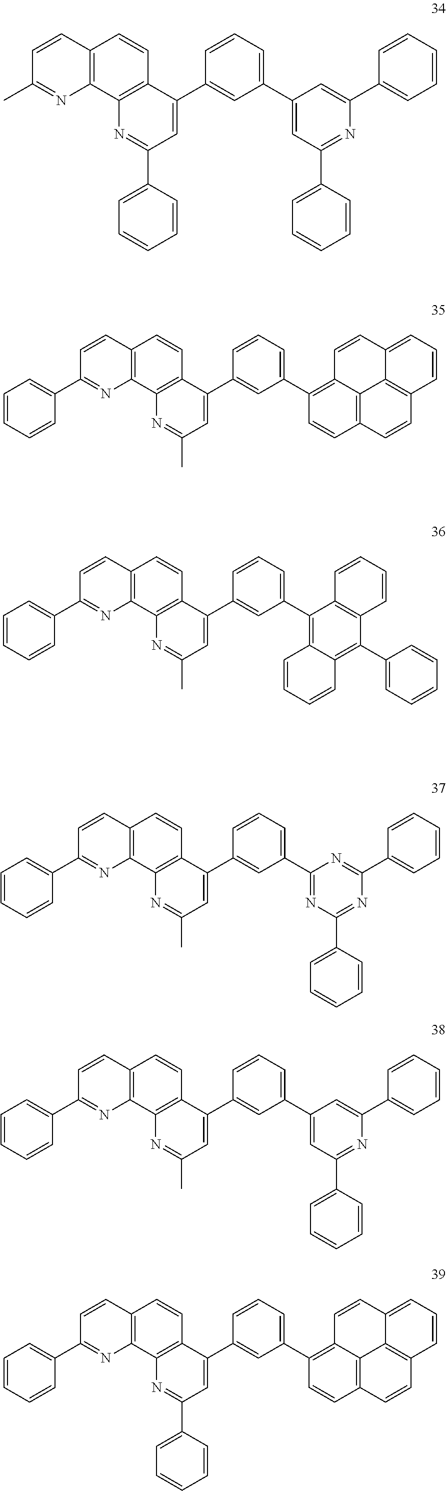 [SMILES: Cc1ccc2ccc3c(-c4cccc(-c5cc(-c6ccccc6)nc(-c6ccccc6)c5)c4)cc(-c4ccccc4)nc3c2n1 ; Cc1cc(-c2cccc(-c3ccc4ccc5cccc6ccc3c4c56)c2)c2ccc3ccc(-c4ccccc4)nc3c2n1 ; Cc1cc(-c2cccc(-c3c4ccccc4c(-c4ccccc4)c4ccccc34)c2)c2ccc3ccc(-c4ccccc4)nc3c2n1 ; Cc1cc(-c2cccc(-c3nc(-c4ccccc4)nc(-c4ccccc4)n3)c2)c2ccc3ccc(-c4ccccc4)nc3c2n1 ; Cc1cc(-c2cccc(-c3cc(-c4ccccc4)nc(-c4ccccc4)c3)c2)c2ccc3ccc(-c4ccccc4)nc3c2n1 ; c1ccc(-c2ccc3ccc4c(-c5cccc(-c6ccc7ccc8cccc9ccc6c7c89)c5)cc(-c5ccccc5)nc4c3n2)cc1]

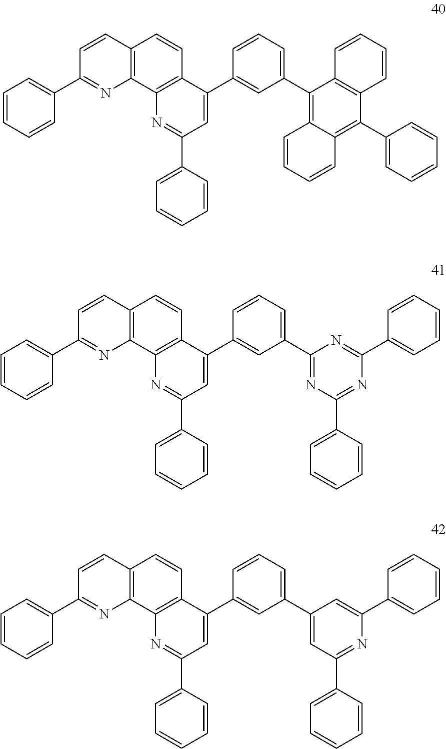 [SMILES: c1ccc(-c2ccc3ccc4c(-c5cccc(-c6c7ccccc7c(-c7ccccc7)c7ccccc67)c5)cc(-c5ccccc5)nc4c3n2)cc1 ; c1ccc(-c2ccc3ccc4c(-c5cccc(-c6nc(-c7ccccc7)nc(-c7ccccc7)n6)c5)cc(-c5ccccc5)nc4c3n2)cc1 ; c1ccc(-c2cc(-c3cccc(-c4cc(-c5ccccc5)nc5c4ccc4ccc(-c6ccccc6)nc45)c3)cc(-c3ccccc3)n2)cc1]

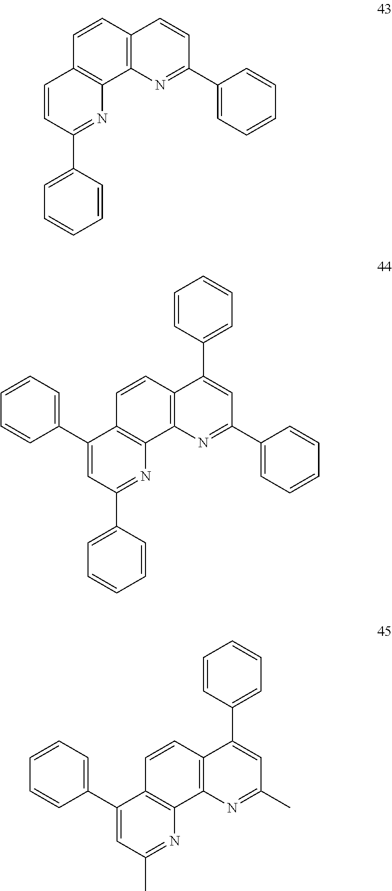 [SMILES: c1ccc(-c2ccc3ccc4ccc(-c5ccccc5)nc4c3n2)cc1 ; c1ccc(-c2cc(-c3ccccc3)c3ccc4c(-c5ccccc5)cc(-c5ccccc5)nc4c3n2)cc1 ; Cc1cc(-c2ccccc2)c2ccc3c(-c4ccccc4)cc(C)nc3c2n1]

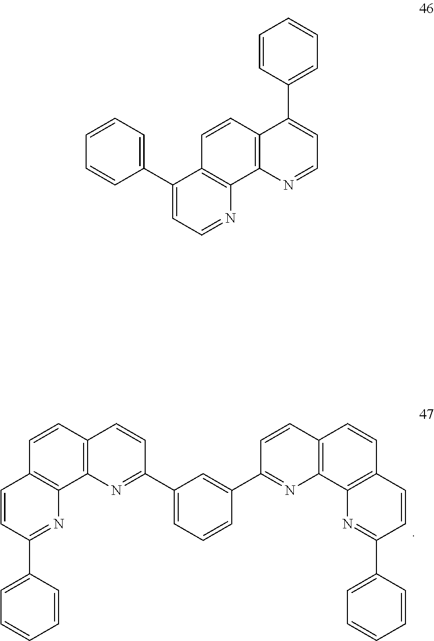 [SMILES: c1ccc(-c2ccnc3c2ccc2c(-c4ccccc4)ccnc23)cc1 ; c1ccc(-c2ccc3ccc4ccc(-c5cccc(-c6ccc7ccc8ccc(-c9ccccc9)nc8c7n6)c5)nc4c3n2)cc1]

6. The light-emitting device of claim 2, wherein Chemical Formula B is represented by Chemical Formula B-1 or Chemical Formula B-2: 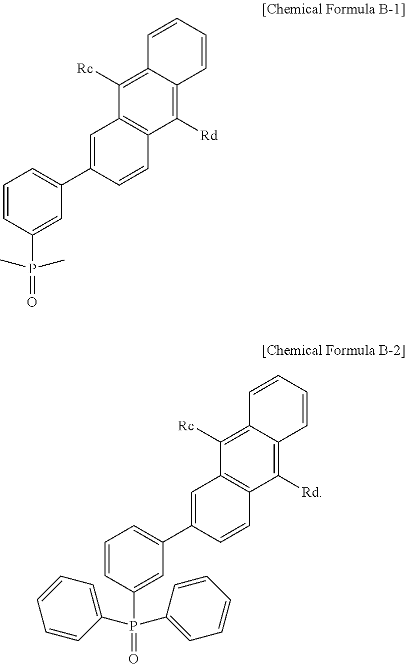
wherein in Chemical Formulae B-1 and B-2,
R_{c} and R_{d} are each independently a substituted or unsubstituted C₆-C₃₀ aryl group.

7. The light-emitting device of claim 2, wherein in Chemical Formula B,
R_{c} and R_{d} are each independently a group represented by one of T1 to T4:

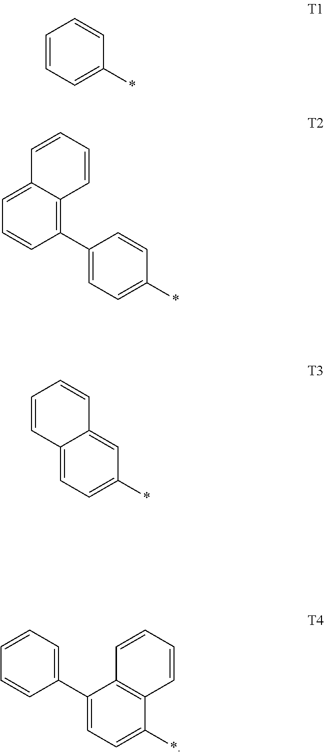

8. The light-emitting device of claim 1, wherein the organic host includes at least one compound selected from Compound Group 2:

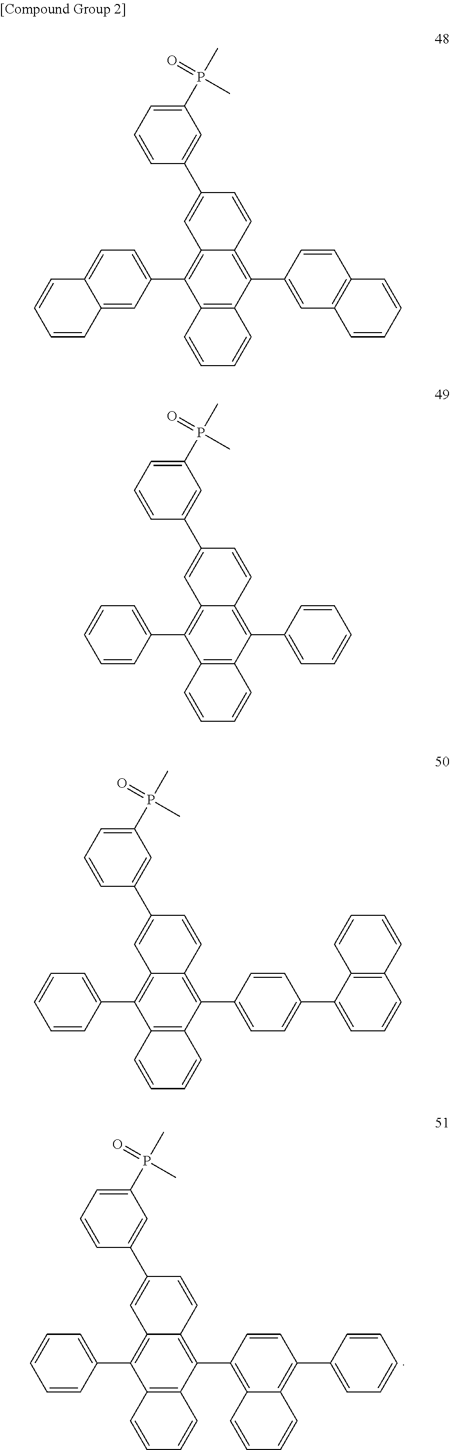

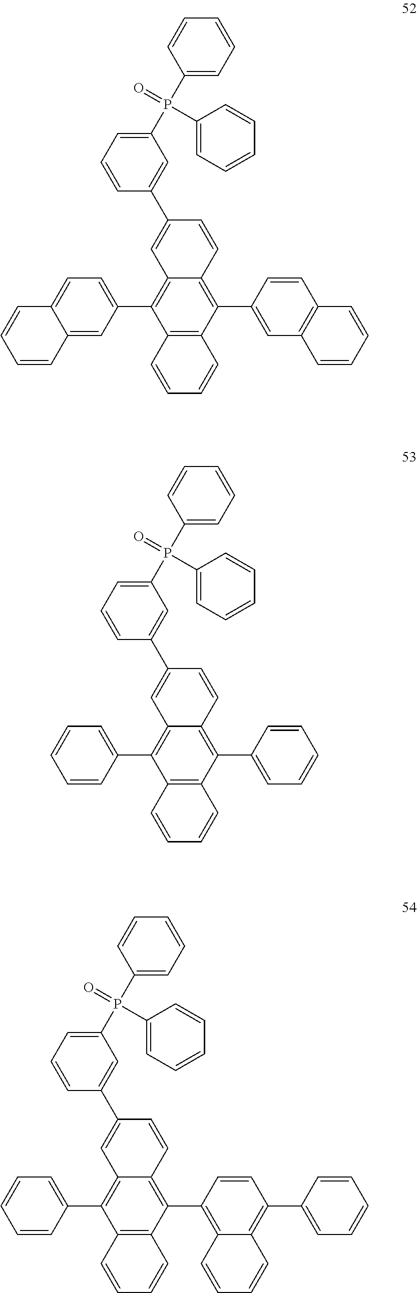 [SMILES: O=P(c1ccccc1)(c1ccccc1)c1cccc(-c2ccc3c(-c4ccc5ccccc5c4)c4ccccc4c(-c4ccc5ccccc5c4)c3c2)c1 ; O=P(c1ccccc1)(c1ccccc1)c1cccc(-c2ccc3c(-c4ccccc4)c4ccccc4c(-c4ccccc4)c3c2)c1 ; O=P(c1ccccc1)(c1ccccc1)c1cccc(-c2ccc3c(-c4ccc(-c5ccccc5)c5ccccc45)c4ccccc4c(-c4ccccc4)c3c2)c1]

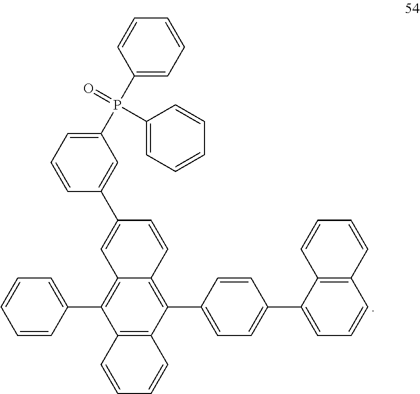 [SMILES: O=P(c1ccccc1)(c1ccccc1)c1cccc(-c2ccc3c(-c4ccc(-c5cccc6ccccc56)cc4)c4ccccc4c(-c4ccccc4)c3c2)c1]

9. The light-emitting device of claim 1, wherein the inorganic metal compound includes at least one of a metal halide, a metal oxide, a metal nitride, and a metal sulfide.

10. The light-emitting device of claim 1, wherein the inorganic metal compound includes at least one of LiI, NaI, KI, RbI, CsI, LiF, NaF, KF, RbF, CsF, Li₂O, Na₂O, Rb₂O, Cs₂O, ZnO, MoO₃, MgO, CaO, Al₂O₃, SiO₂, Li₃N, Na₃N, K₃N, Rb₃N, Si₃N₄, and ZnS.

11. The light-emitting device of claim 1, wherein the second electron injection layer directly contacts the second electrode.

12. The light-emitting device of claim 1, wherein an absolute value of a difference between a lowest unoccupied molecular orbital (LUMO) energy level of the organic host doped with the first metal dopant and an energy level of a work function of the second electrode is less than or equal to about 0.2 eV.

13. The light-emitting device of claim 1, wherein a binding energy of the organic host and the first metal dopant is greater than or equal to about 2.0 eV.

14. The light-emitting device of claim 1, wherein the first metal dopant includes at least one of Ag, Bi, Mg, Li, Yb, Cu, La, Pr, Nd, Pm, Sm, Eu, Gd, Tb, Dy, Ho, Er, Tm, and Lu.

15. The light-emitting device of claim 1, wherein a volume ratio of the first metal dopant to a total volume of the organic host and the first metal dopant in the first electron injection layer is in a range of about 0.1 vol % to about 10 vol %.

16. The light-emitting device of claim 1, wherein the second electron injection layer further includes a second metal dopant.

17. The light-emitting device of claim 16, wherein the second metal dopant includes at least one of Ag, Bi, Mg, Li, Yb, Cu, La, Pr, Nd, Pm, Sm, Eu, Gd, Tb, Dy, Ho, Er, Tm and Lu.

18. The light-emitting device of claim 1, wherein
a thickness of the first electron injection layer is in a range of about 10 Å to about 50 Å, and
a thickness of the second electron injection layer is in a range of about 1 Å to about 20 Å.

19. An electronic device comprising the light-emitting device of claim 1.

20. The electronic device of claim 19, wherein the electronic device includes a display device; a billboard; a signboard; a light source; a lighting device; a personal computer including a laptop computer or a desktop computer; a mobile phone; an electronic book; an electronic dictionary; an electronic notebook; a health-care device including a diagnostic device and a sensor; or a display part for transportation means including automobile, aircraft, ship or train.
